(19) United States
(12) Patent Application Publication
(10) Pub. No.: US 2025/0280566 A1
(43) Pub. Date: Sep. 4, 2025

(54) SEMICONDUCTOR DEVICE, MEMORY DEVICE, AND METHOD FOR MANUFACTURING SEMICONDUCTOR DEVICE

(71) Applicant: Semiconductor Energy Laboratory Co., Ltd., Atsugi-shi, Kanagawa-ken (JP)

(72) Inventors: Shinya SASAGAWA, Isehara (JP); Ryota HODO, Atsugi (JP); Kentaro SUGAYA, Isehara (JP)

(21) Appl. No.: 18/869,874

(22) PCT Filed: May 30, 2023
(86) PCT No.: PCT/IB2023/055500

§ 371 Date: Nov. 27, 2024

(30) Foreign Application Priority Data
Jun. 10, 2022 (JP) 2022-094220
Jan. 31, 2023 (JP) 2023-013371

(51) Int. Cl. H10D 30/67; H10B 12/00; H10D 30/01; H10D 64/66; H10D 64/68

(52) U.S. Cl. CPC H10D 30/6734; H10B 12/31; H10D 30/0312; H10D 30/6736; H10D 30/6737; H10D 64/675; H10D 64/685

(57) ABSTRACT

A semiconductor device (200) includes an oxide (230) over a substrate: a first conductor (242a1) and a second conductor (242b1) that are over the oxide and separated from each other; a third conductor (242a2) in contact with a part of a top surface of the first conductor; a fourth conductor (242b2) in contact with a part of a top surface of the second conductor; a first insulator (271a, 271b) that is positioned over the third conductor and the fourth conductor and has an opening overlapping with a region between the third conductor and the fourth conductor; a second insulator (255) that is positioned in the opening of the first insulator and in contact with another part of the top surface of the first conductor, another part of the top surface of the second conductor, a side surface of the third conductor, and a side surface of the fourth conductor; a third insulator (250) that is positioned in the opening of the first insulator and in contact with a top surface of the oxide, a side surface of the first conductor, a side surface of the second conductor, and a side surface of the second conductor; and a fifth conductor that is positioned over the third insulator in the opening of the first insulator and includes a region overlapping with the oxide with the third insulator therebetween. A distance (L2) between the first conductor and the second conductor is smaller than a distance (L1) between the third conductor and the fourth conductor.

### TECHNICAL FIELD

One embodiment of the present invention relates to a semiconductor device using an oxide semiconductor, a memory device, and an electronic device. Another embodiment of the present invention relates to a method for manufacturing the semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method for manufacturing any of them.

Note that in this specification and the like, a semiconductor device refers to a general device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

In recent years, the development of semiconductor devices has progressed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

semiconductor circuit (IC chip) of an LSI, a CPU, a memory, or the like is mounted on a circuit board, for example, a printed wiring board, to be used as one of components of a variety of electronic devices.

technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor and further, an oxide semiconductor has been attracting attention as another material.

It is known that a transistor using an oxide semiconductor has an extremely low leakage current in a non-conduction state. For example, Patent Document 1 discloses a low-power-consumption CPU utilizing a characteristically low leakage current of the transistor using an oxide semiconductor. As another example, Patent Document 2 discloses a memory device that can retain stored contents for a long time by utilizing a feature of a low leakage current of the transistor using an oxide semiconductor.

Patent Document 3 discloses a transistor having a minute structure in which a source electrode layer and a drain electrode layer are provided in contact with the top surface of an oxide semiconductor layer.

### REFERENCE

### Patent Document

[Patent Document 1] Japanese Published Patent Application No. 2012-257187
[Patent Document 2] Japanese Published Patent Application No. 2011-151383
[Patent Document 3] PCT International Publication No. 2016/125052

### SUMMARY OF THE INVENTION

### Problems to be Solved by the Invention

An object of one embodiment of the present invention is to provide a semiconductor device that can be miniaturized or highly integrated. Another object of one embodiment of the present invention is to provide a semiconductor device with high operating speed. Another object of one embodiment of the present invention is to provide a semiconductor device with favorable electrical characteristics. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device with a high on-state current. Another object of one embodiment of the present invention is to provide a semiconductor device with low power consumption. Another object of one embodiment of the present invention is to provide a novel semiconductor device. Another object of one embodiment of the present invention is to provide a method for manufacturing a semiconductor device with high productivity. Another object of one embodiment of the present invention is to provide a method for manufacturing a novel semiconductor device.

Another object of one embodiment of the present invention is to provide a memory device with large memory capacity. Another object of one embodiment of the present invention is to provide a memory device with high operating speed. Another object of one embodiment of the present invention is to provide a memory device with low power consumption. Another object of one embodiment of the present invention is to provide a novel memory device.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device including an oxide over a substrate; a first conductor and a second conductor that are over the oxide and separated from each other; a third conductor in contact with a part of a top surface of the first conductor; a fourth conductor in contact with a part of a top surface of the second conductor; a first insulator that is positioned over the third conductor and the fourth conductor and has an opening overlapping with a region between the third conductor and the fourth conductor; a second insulator that is positioned in the opening of the first insulator and in contact with another part of the top surface of the first conductor, another part of the top surface of the second conductor, a side surface of the third conductor, and a side surface of the fourth conductor; a third insulator that is positioned in the opening of the first insulator and in contact with a top surface of the oxide, a side surface of the first conductor, a side surface of the second conductor, and a side surface of the second insulator; and a fifth conductor that is positioned over the third insulator in the opening of the first insulator and includes a region overlapping with the oxide with the third insulator therebetween. A distance between the first conductor and the second conductor is smaller than a distance between the third conductor and the fourth conductor.

In the above, the first conductor and the second conductor preferably include a metal nitride. In the above, the first conductor and the second conductor preferably include tantalum nitride. In the above, the first conductor and the second conductor preferably include tantalum nitride, and the third conductor and the fourth conductor preferably include tungsten.

In the above, the second insulator preferably includes a nitride. In the above, the second insulator preferably includes silicon nitride.

In the above, the second insulator preferably contains oxygen.

In the above, the second insulator is preferably in contact with a side surface of the first insulator.

In the above, an upper portion of the second insulator preferably has a tapered shape.

In the above, a difference between the distance between the third conductor and the fourth conductor and the distance between the first conductor and the second conductor is preferably equal to or substantially equal to twice a thickness of the second insulator.

In the above, the side surface of the third conductor and the side surface of the fourth conductor preferably have a recess.

In the above, a side surface of the opening of the first insulator is preferably aligned or substantially aligned with the side surface of the third conductor and the side surface of the fourth conductor in a top view.

In the above, the third insulator preferably includes an aluminum oxide film, a silicon oxide film over the aluminum oxide film, and a silicon nitride film over the silicon oxide film.

In the above, a fourth insulator to an eighth insulator are preferably included; the fourth insulator is preferably positioned below the oxide; the fifth insulator is preferably positioned in contact with a top surface of the fourth insulator; the sixth insulator is preferably positioned between the first insulator and each of the first conductor to the fourth conductor, the oxide, and the fifth insulator; the seventh insulator is preferably positioned over the first insulator, the second insulator, the third insulator, and the fifth conductor; the eighth insulator is preferably positioned in contact with a top surface of the seventh insulator; and the sixth insulator is preferably in contact with the side surface of the second insulator and the top surface of the fourth insulator. The second insulator, the fourth insulator, the sixth insulator, and the eighth insulator each preferably include a silicon nitride film, the fifth insulator preferably includes a hafnium oxide film, and the seventh insulator preferably includes an aluminum oxide film.

In the above, a sixth conductor is preferably included below the fourth insulator, and the sixth conductor preferably includes a region overlapping with the fifth conductor and the oxide.

Another embodiment of the present invention is a memory device including the above semiconductor device and a capacitor, in which one electrode of the capacitor is electrically connected to the third conductor of the semiconductor device.

Another embodiment of the present invention is a method for manufacturing a semiconductor device, including the steps of: forming an oxide over a substrate; forming a first conductor over the oxide; forming a second conductor over the first conductor; forming a first insulator to cover the oxide, the first conductor, and the second conductor; forming an opening in the first insulator; removing a region of the second conductor overlapping with the opening to divide the second conductor into a third conductor and a fourth conductor; forming a second insulator to cover the oxide and the first insulator; processing the second insulator by an anisotropic dry etching method to form a third insulator in contact with a side surface of the first insulator, a side surface of the third conductor, and a side surface of the fourth conductor; processing the first conductor by an anisotropic dry etching method with use of the third insulator as a mask to divide the first conductor into a fifth conductor and a sixth conductor; performing heat treatment on the oxide in an atmosphere containing oxygen; forming a fourth insulator to cover the oxide, the first insulator, and the third insulator; forming a seventh conductor over the fourth insulator; and processing the fourth insulator and the seventh conductor with CMP treatment to form a fifth insulator and an eighth conductor in the opening. As the formation of the second insulator, silicon nitride is formed by a PEALD method.

### Effect of the Invention

One embodiment of the present invention can provide a semiconductor device that can be miniaturized or highly integrated. Another embodiment of the present invention can provide a semiconductor device with high operating speed. Another embodiment of the present invention can provide a semiconductor device with favorable electrical characteristics. Another embodiment of the present invention can provide a semiconductor device with a small variation in electrical characteristics of transistors. Another embodiment of the present invention can provide a highly reliable semiconductor device. Another embodiment of the present invention can provide a semiconductor device with a high on-state current. Another embodiment of the present invention can provide a semiconductor device with low power consumption. Another embodiment of the present invention can provide a novel semiconductor device. Another embodiment of the present invention can provide a manufacturing method of a semiconductor device with high productivity. Another embodiment of the present invention can provide a method for manufacturing a novel semiconductor device.

Another embodiment of the present invention can provide a memory device with large memory capacity. Another embodiment of the present invention can provide a memory device with high operating speed. Another embodiment of the present invention can provide a memory device with low power consumption. Another embodiment of the present invention can provide a novel memory device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a semiconductor device. FIG. 1B to FIG. 1D are cross-sectional views illustrating an example of the semiconductor device.

FIG. 2A and FIG. 2B are cross-sectional views illustrating an example of a semiconductor device.

FIG. 3A to FIG. 3D are cross-sectional views each illustrating an example of a semiconductor device.

FIG. 4A to FIG. 4C are cross-sectional views each illustrating an example of a semiconductor device.

FIG. 5A and FIG. 5B are cross-sectional views each illustrating an example of a semiconductor device.

FIG. 6A is a plan view illustrating an example of a method for manufacturing a semiconductor device. FIG. 6B to FIG. 6D are cross-sectional views illustrating the example of a method for manufacturing a semiconductor device.

FIG. 7A is a plan view illustrating an example of a method for manufacturing a semiconductor device. FIG. 7B to FIG. 7D are cross-sectional views illustrating the example of a method for manufacturing a semiconductor device.

FIG. 8A is a plan view illustrating an example of a method for manufacturing a semiconductor device. FIG. 8B to FIG. 8D are cross-sectional views illustrating the example of a method for manufacturing a semiconductor device.

FIG. 9A is a plan view illustrating an example of a method for manufacturing a semiconductor device. FIG. 9B to FIG. 9D are cross-sectional views illustrating the example of a method for manufacturing a semiconductor device.

FIG. 10A is a plan view illustrating an example of a method for manufacturing a semiconductor device. FIG. 10B to FIG. 10D are cross-sectional views illustrating the example of a method for manufacturing a semiconductor device.

FIG. 11A is a plan view illustrating an example of a method for manufacturing a semiconductor device. FIG. 11B to FIG. 11D are cross-sectional views illustrating the example of a method for manufacturing a semiconductor device.

FIG. 12A is a plan view illustrating an example of a method for manufacturing a semiconductor device. FIG. 12B to FIG. 12D are cross-sectional views illustrating the example of a method for manufacturing a semiconductor device.

FIG. 13A and FIG. 13B are cross-sectional views illustrating an example of a method for manufacturing a semiconductor device.

FIG. 14A is a plan view illustrating an example of a method for manufacturing a semiconductor device. FIG. 14B to FIG. 14D are cross-sectional views illustrating the example of a method for manufacturing a semiconductor device.

FIG. 15A is a plan view illustrating an example of a method for manufacturing a semiconductor device. FIG. 15B to FIG. 15D are cross-sectional views illustrating the example of a method for manufacturing a semiconductor device.

FIG. 16A to FIG. 16C are cross-sectional views illustrating an example of a method for manufacturing a semiconductor device.

FIG. 17A is a plan view illustrating an example of a method for manufacturing a semiconductor device. FIG. 17B to FIG. 17D are cross-sectional views illustrating the example of a method for manufacturing a semiconductor device.

FIG. 18A is a plan view illustrating an example of a method for manufacturing a semiconductor device. FIG. 18B to FIG. 18D are cross-sectional views illustrating the example of a method for manufacturing a semiconductor device.

FIG. 19 is a block diagram illustrating an example of a memory device.

FIG. 20A and FIG. 20B are a schematic view and a circuit diagram, respectively, illustrating an example of a memory device.

FIG. 21A and FIG. 21B are schematic views illustrating an example of a memory device.

FIG. 22 is a circuit diagram illustrating an example of a memory device.

FIG. 23 is a cross-sectional view illustrating an example of a memory device.

FIG. 24 is a cross-sectional view illustrating an example of a memory device.

FIG. 25A to FIG. 25C are circuit diagrams each illustrating an example of a memory device.

FIG. 26A and FIG. 26B are diagrams illustrating an example of a semiconductor device.

FIG. 27A and FIG. 27B are diagrams each illustrating an example of an electronic component.

FIG. 28A and FIG. 28B are diagrams each illustrating an example of an electronic device, and FIG. 28C to FIG. 28E are diagrams each illustrating an example of a large computer.

FIG. 29 is a diagram illustrating an example of space equipment.

FIG. 30 illustrates an example of a storage system applicable to a data center.

FIG. 31 shows measurement results of the surface oxide-film thickness of Example.

FIG. 32A and FIG. 32B each show SIMS analysis results of Example.

FIG. 33A and FIG. 33B each show SIMS analysis results of Example.

FIG. 34 is a cross-sectional STEM image of Example.

FIG. 35 is a cross-sectional STEM image of Example.

FIG. 36A and FIG. 36B each show electrical characteristics of Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, or the like disclosed in the drawings.

Note that in this specification and the like, ordinal numbers such as “first” and “second” are used for convenience and do not limit the number of components or the order of components (e.g., the order of steps or the stacking order of layers). The ordinal number added to a component in a part of this specification may be different from the ordinal number added to the component in another part of this specification or the scope of claims.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”. The term “conductor” can be replaced with the term “conductive layer” or the term “conductive film” depending on the case or the circumstances. The term “insulator” can be replaced with the term “insulating layer” or the term “insulating film” depending on the case or the circumstances.

The term “opening” includes a groove and a slit, for example. A region where an opening is formed is referred to as an opening portion in some cases.

In the drawings used in embodiments of this specification, a sidewall of an insulator in an opening portion in the insulator is illustrated as being perpendicular or substantially perpendicular to a substrate surface or a formation surface, but the sidewall may have a tapered shape.

Note that in this specification and the like, a tapered shape refers to a shape such that at least part of a side surface of a component is inclined to a substrate surface or a formation surface. For example, the tapered shape refers to a shape including a region where the angle formed by the inclined side surface and the substrate surface or the formation surface (hereinafter, such an angle is also referred to as a taper angle in some cases) is less than 90°. Note that the side surface of the component and the substrate surface are not necessarily completely flat and may be substantially flat with a slight curvature or substantially flat with slight unevenness.

### Embodiment 1

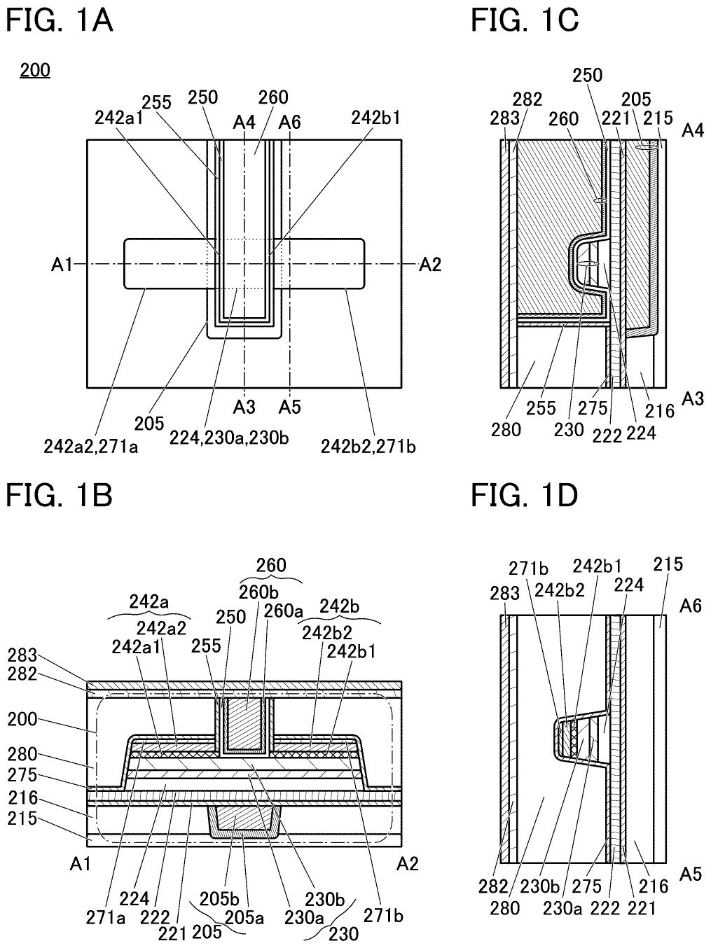

In this embodiment, a semiconductor device including an oxide semiconductor and a method for manufacturing the semiconductor device will be described with reference to FIG. 1 to FIG. 18.

### <Structure Example of Semiconductor Device>

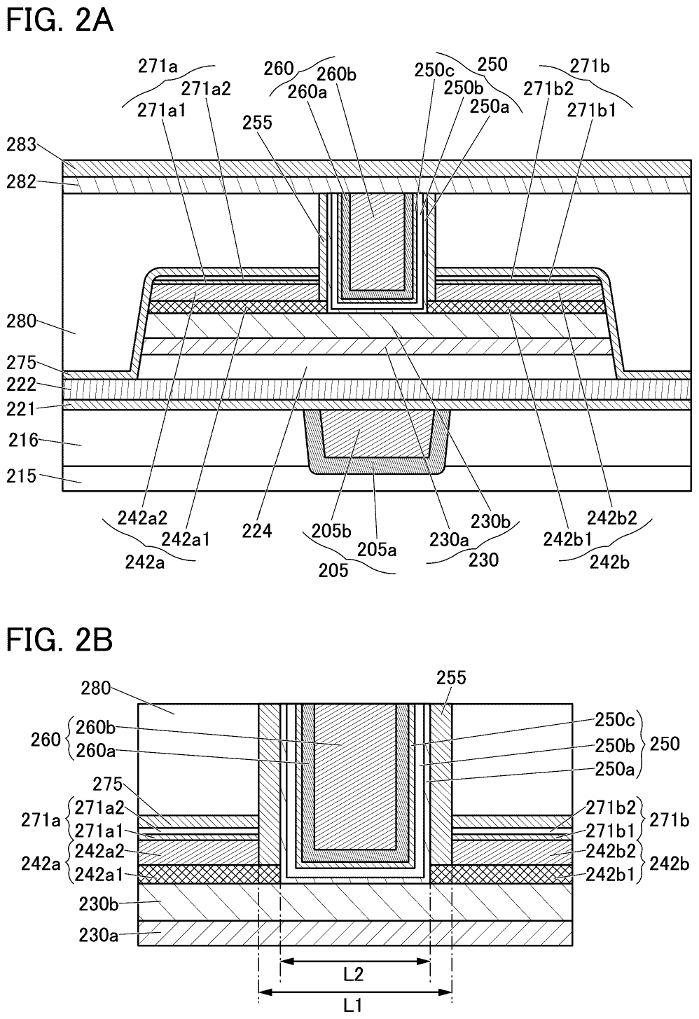

A structure example of a semiconductor device is described with reference to FIG. 1 to FIG. 5. FIG. 1A to FIG. 1D are a plan view and cross-sectional views of a semiconductor device (a transistor 200). FIG. 1A is a plan view of the semiconductor device. FIG. 1B to FIG. 1D are cross-sectional views of the semiconductor device. Here, FIG. 1B is a cross-sectional view of a portion indicated by dashed-dotted line A1-A2 in FIG. 1A, and is a cross-sectional view of the transistor 200 in the channel length direction. FIG. 1C is a cross-sectional view of a portion indicated by the dashed-dotted line A3-A4 in FIG. 1A, and is a cross-sectional view of the transistor 200 in a channel width direction. FIG. 1D is a cross-sectional view of a portion indicated by dashed-dotted line A5-A6 in FIG. 1A, and is also a cross-sectional view of the transistor 200 in the channel width direction. Note that for clarity of the drawing, some components are omitted in the plan view of FIG. 1A. FIG. 2A to FIG. 5B are enlarged cross-sectional views of the transistor 200 in the channel length direction.

The transistor 200 includes a conductor 205 (a conductor 205a and a conductor 205b) provided to be embedded in an insulator 216; an insulator 221 over the insulator 216 and the conductor 205; an insulator 222 over the insulator 221; an insulator 224 over the insulator 222; an oxide 230 (an oxide 230a and an oxide 230b) over the insulator 224; a conductor 242a (a conductor 242a1 and a conductor 242a2) and a conductor 242b (a conductor 242b1 and a conductor 242b2) over the oxide 230; an insulator 271a over the conductor 242a; an insulator 271b over the conductor 242b; an insulator 250 over the oxide 230; and a conductor 260 (a conductor 260a and a conductor 260b) over the insulator 250.

An insulator 275 is provided over the insulators 271a and 271b, and an insulator 280 is provided over the insulator 275. An insulator 255, the insulator 250, and the conductor 260 are embedded in an opening provided in the insulator 280 and the insulator 275. An insulator 282 is provided over the insulator 280 and the conductor 260. An insulator 283 is provided over the insulator 282. An insulator 215 is provided below the insulator 216 and the conductor 205. The insulator 255 is provided between the insulator 250 and the conductor 242a2, the conductor 242b2, the insulator 271a, the insulator 271b, the insulator 275, and the insulator 280.

The oxide 230 includes a region functioning as a channel formation region of the transistor 200. The conductor 260 includes a region functioning as a first gate electrode (an upper gate electrode) of the transistor 200. The insulator 250 includes a region functioning as a first gate insulator of the transistor 200. The conductor 205 includes a region functioning as a second gate electrode (a lower gate electrode) of the transistor 200. The insulator 224, the insulator 222, and the insulator 221 each include a region functioning as a second gate insulator of the transistor 200.

The conductor 242a includes a region functioning as one of a source electrode and a drain electrode of the transistor 200. The conductor 242b includes a region functioning as the other of the source electrode and the drain electrode of the transistor 200.

The conductor 242a has a stacked structure of the conductor 242a1 and the conductor 242a2 over the conductor 242a1, and the conductor 242b has a stacked structure of the conductor 242b1 and the conductor 242b2 over the conductor 242b1. The conductor 242a1 and the conductor 242b1 in contact with the oxide 230b are preferably conductors that are not easily oxidized, such as metal nitride. In that case, the conductor 242a and the conductor 242b can be prevented from being oxidized excessively due to oxygen contained in the oxide 230b. The conductor 242a2 and the conductor 242b2 are preferably conductors having higher conductivity than the conductor 242a1 and the conductor 242b1, such as a metal layer. Accordingly, the conductor 242a and the conductor 242b can each function as a wiring or an electrode with high conductivity. In this manner, a semiconductor device in which the conductor 242a and the conductor 242b which function as a wiring or an electrode are provided in contact with a top surface of the oxide 230 functioning as an active layer can be provided.

As illustrated in FIG. 2B, in a cross-sectional view of the transistor 200 in the channel length direction, a distance L2 between the conductor 242a1 and the conductor 242b1 is preferably smaller than a distance L1 between the conductor 242a2 and the conductor 242b2. Specifically, the difference between L1 and L2 is equal to or substantially equal to twice the thickness of the insulator 255. Here, the thickness of the insulator 255 corresponds to the thickness in the A1-A2 direction of at least a portion of the insulator 255. With such a structure, the distance between the source and the drain can be shortened, and the channel length can be accordingly shortened. Thus, the frequency characteristics of the transistor 200 can be improved. In this manner, miniaturization of the semiconductor device enables the semiconductor device to have a higher operation speed.

The opening formed in the insulator 280 and the insulator 275 overlap with a region between the conductor 242a2 and the conductor 242b2. In a top view, the side surface of the insulator 280 in the opening is aligned or substantially aligned with a side surface of the conductor 242a2 and a side surface of the conductor 242b2. The conductor 242a1 and the conductor 242b1 are formed to partly extend in the opening. A part of a top surface of the conductor 242a1 is in contact with the conductor 242a2, and a part of a top surface of the conductor 242b1 is in contact with the conductor 242b2. Thus, the insulator 255 is in contact with another part of the top surface of the conductor 242a1, another part of the top surface of the conductor 242b1, and the side surface of the conductor 242a2, and the side surface of the conductor 242b2 in the opening. The insulator 250 is in contact with the top surface of the oxide 230, a side surface of the conductor 242a1, a side surface of the conductor 242b1, and a side surface of the insulator 255.

The insulator 255 is preferably an insulator that is not easily oxidized, such as nitride. By anisotropic etching, the insulator 255 is formed in a sidewall shape to be in contact with a sidewall of the opening formed in the insulator 280 and the like (here, the sidewall of the opening corresponds to, for example, a side surface of the insulator 280 or the like in the opening). The insulator 255 is formed in contact with the side surface of the conductor 242a2 and the side surface of the conductor 242b2 and has a function of protecting the conductor 242a2 and the conductor 242b2. Although the details will be described later, heat treatment in an atmosphere containing oxygen is preferably performed after the division of the conductor 242_1 into the conductor 242a1 and the conductor 242b1 and before the formation of the insulator 250. At this time, since the insulator 255 is formed in contact with the side surface of the conductor 242a2 and the side surface of the conductor 242b2, excessive oxidation of the conductor 242a2 and the conductor 242b2 can be prevented.

The oxide 230 preferably includes the oxide 230a over the insulator 224 and the oxide 230b over the oxide 230a. Including the oxide 230a under the oxide 230b makes it possible to inhibit diffusion of impurities into the oxide 230b from components formed below the oxide 230a.

Although an example in which the oxide 230 has a two-layer structure of the oxide 230a and the oxide 230b is described in this embodiment, one embodiment of the present invention is not limited thereto. The oxide 230 may have a single-layer structure of the oxide 230b or a stacked-layer structure of three or more layers, for example.

The oxide 230b includes a channel formation region of the transistor 200 and a source region and a drain region provided to sandwich the channel formation region. At least part of the channel formation region overlaps with the conductor 260. The source region overlaps with the conductor 242a, and the drain region overlaps with the conductor 242b. Note that the source region and the drain region can be interchanged with each other.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration in the oxide 230b, the impurity concentration in the oxide 230b is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration is sometimes referred to as a highly purified intrinsic or substantially highly purified intrinsic oxide semiconductor (or metal oxide).

In order to obtain stable electrical characteristics of the transistor 200, reducing the impurity concentration in the metal oxide 230b is effective. In order to reduce the impurity concentration in the oxide 230b, it is preferable that the impurity concentration in an adjacent film be also reduced. Examples of impurities include hydrogen, nitrogen, an alkali metal, an alkaline earth metal, iron, nickel, and silicon. Note that an impurity in the oxide 230b refers to, for example, an element other than the main components of the oxide 230b. For example, an element with a concentration lower than 0.1 atomic % can be regarded as an impurity.

Note that the channel formation region, the source region, and the drain region may each be formed not only in the oxide 230b but also in the oxide 230a.

In the oxide 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

A metal oxide functioning as a semiconductor (hereinafter also referred to as an oxide semiconductor) is preferably used for the oxide 230 (the oxide 230a and the oxide 230b).

The metal oxide functioning as a semiconductor preferably has a band gap higher than or equal to 2 eV, further preferably higher than or equal to 2.5 eV. With use of a metal oxide having a wide band gap, the off-state current of the transistor can be reduced. A transistor including a metal oxide in a channel formation region is referred to as an OS transistor. The off-state current of the OS transistor is low, so that power consumption of the semiconductor device can be adequately reduced. The OS transistor has excellent frequency characteristics, which enables the semiconductor device to operate at high speed.

The oxide 230 preferably includes a metal oxide (an oxide semiconductor). Examples of the metal oxide that can be used for the oxide 230 include indium oxide, gallium oxide, and zinc oxide. The metal oxide preferably contains at least indium (In) or zinc (Zn). The metal oxide preferably contains two or three kinds selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably any one or more kinds of the above elements, further preferably one or more kinds selected from aluminum, gallium, tin, and yttrium, still further preferably gallium. In this specification and the like, a metal element and a metalloid element may be collectively referred to as a “metal element”, and a “metal element” in this specification and the like may refer to a metalloid element.

For the oxide 230, it is possible to use, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), indium gallium aluminum zinc oxide (In—Ga—Al—Zn oxide, also referred to as IGAZO or IAGZO), or the like. Alternatively, it is possible to use indium tin oxide containing silicon, gallium tin oxide (Ga—Sn oxide), aluminum tin oxide (Al—Sn oxide), or the like.

When the proportion of the number of indium atoms in the total number of atoms of all the metal elements contained in the metal oxide is increased, the field-effect mobility of the transistor can be increased.

Note that the metal oxide may contain, instead of or in addition to indium, one or more kinds of metal elements with larger period numbers in the periodic table. The larger the overlap between orbits of metal elements is, the more likely it is that the metal oxide will have high carrier conductivity. Thus, a transistor containing a metal element with a larger period number in the periodic table can have high field-effect mobility in some cases. Examples of the metal element with a larger period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide including a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed, and the reliability of the transistor can be increased.

By increasing the proportion of the element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited and the reliability of the transistor can be improved.

As described above, electrical characteristics and reliability of a transistor vary depending on the composition of the metal oxide used for the oxide 230. Therefore, by determining the composition of the metal oxide in accordance with the electrical characteristics and reliability required for the transistor, the semiconductor device can have both good electrical characteristics and high reliability.

The oxide 230 preferably has a stacked-layer structure of a plurality of oxide layers with different chemical compositions. For example, the atomic ratio of the element M to a metal element that is a main component in the metal oxide used for the oxide 230a is preferably greater than the atomic ratio of the element M to a metal element that is a main component in the metal oxide used for the oxide 230b. Moreover, the atomic ratio of the element M to In in the metal oxide used for the oxide 230a is preferably greater than the atomic ratio of the element M to In in the metal oxide used for the oxide 230b. With this structure, impurities and oxygen can be inhibited from diffusing into the oxide 230b from the components formed below the oxide 230a.

Furthermore, the atomic ratio of In to the element M in the metal oxide used for the oxide 230b is preferably greater than the atomic ratio of In to the element M in the metal oxide used for the oxide 230a. With this structure, the transistor 200 can have a high on-state current and excellent frequency characteristics.

When the oxide 230a and the oxide 230b include a common element as the main component besides oxygen, the density of defect states at the interface between the oxide 230a and the oxide 230b can be decreased. Thus, the influence of interface scattering on carrier conduction is small, and the transistor 200 can have a high on-state current and excellent frequency characteristics.

Specifically, for the oxide 230a, a metal oxide with a composition of In:M:Zn=1:3:2 [atomic ratio] or in the neighborhood thereof, a composition of In:M:Zn=1:3:4 [atomic ratio] or in the neighborhood thereof, or a composition of In:M:Zn=1:1:0.5 [atomic ratio] or in the neighborhood thereof can be used. For the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of ±30% of an intended atomic ratio. Gallium is preferably used as the element M. In the case where a single layer of the oxide 230b is provided as the oxide 230, a metal oxide that can be used for the oxide 230a may be used for the oxide 230b. The compositions of the metal oxides that can be used for the oxide 230a and the oxide 230b are not limited to the above. For example, the composition of the metal oxide that can be used for the oxide 230a may be applied to the oxide 230b. Similarly, the composition of the metal oxide that can be used for the oxide 230b may be applied to the oxide 230a.

When the metal oxide is deposited by a sputtering method, the above atomic ratio is not limited to the atomic ratio of the deposited metal oxide and may be the atomic ratio of a sputtering target used for depositing the metal oxide.

The oxide 230b preferably has crystallinity. It is particularly preferable to use a CAAC-OS (c-axis aligned crystalline oxide semiconductor) for the oxide 230b.

The CAAC-OS is a metal oxide having a dense structure with high crystallinity and small amounts of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as a CAAC-OS, is used for the oxide 230b, oxygen extraction from the oxide 230b by the source electrode or the drain electrode can be inhibited. This can reduce oxygen extraction from the oxide 230b even when heat treatment is performed; thus, the transistor 200 is stable with respect to high temperatures in the manufacturing process (what is called thermal budget).

A transistor using an oxide semiconductor is likely to have its electrical characteristics changed by impurities and oxygen vacancies in a region where a channel is formed in the oxide semiconductor, which might reduce the reliability. In some cases, hydrogen in the vicinity of an oxygen vacancy forms a defect that is the oxygen vacancy into which hydrogen enters (hereinafter sometimes referred to as VoH), which generates an electron serving as a carrier. Therefore, when the channel formation region in the oxide semiconductor includes oxygen vacancies, the transistor is likely to have normally-on characteristics (characteristics with which, even when no voltage is applied to the gate electrode, the channel exists and current flows through the transistor). Therefore, the impurities, oxygen vacancies, and VoH are preferably reduced as much as possible in the channel formation region in the oxide semiconductor. In other words, it is preferable that the channel formation region of the oxide semiconductor have a reduced carrier concentration and be of an i-type (intrinsic) or substantially i-type.

As a countermeasure against the above, an insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor 200. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and VoH in the channel formation region of the oxide semiconductor are preferably reduced. Supply of an excess amount of oxygen to the source region and the drain region and excessive reduction in the amount of VoH in the source region and the drain region are preferably inhibited. In addition, a reduction in conductivity of the conductor 260, the conductor 242a, the conductor 242b, and the like is preferably inhibited. For example, oxidation of the conductor 260, the conductor 242a, the conductor 242b, and the like is preferably inhibited. Note that hydrogen in the oxide semiconductor can form VoH; thus, the hydrogen concentration needs to be reduced in order to reduce the amount of VoH.

The semiconductor device of this embodiment thus has a structure in which the hydrogen concentration in the channel formation region is reduced, oxidation of the conductor 242a, the conductor 242b, and the conductor 260 is inhibited, and a reduction in the hydrogen concentration in the source region and the drain region is inhibited.

The insulator 250 in contact with the channel formation region of the oxide 230b preferably has a function of capturing and fixing hydrogen. Thus, the hydrogen concentration in the channel formation region of the oxide 230b can be reduced. Accordingly, VoH in the channel formation region can be reduced, so that the channel formation region can be an i-type or substantially i-type region.

Here, as illustrated in FIG. 2A, the insulator 250 preferably has a stacked-layer structure of an insulator 250a in contact with the oxide 230, an insulator 250b over the insulator 250a, and an insulator 250c over the insulator 250b. In this case, the insulator 250a preferably has a function of capturing and fixing hydrogen.

An example of the insulator having a function of capturing or fixing hydrogen is a metal oxide having an amorphous structure. For the insulator 250a, for example, a metal oxide such as magnesium oxide or an oxide containing one or both of aluminum and hafnium is preferably used. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

A high dielectric constant (high-k) material is preferably used for the insulator 250a. An example of the high-k material is an oxide containing one or both of aluminum and hafnium. With use of the high-k material for the insulator 250a, a gate potential applied during the operation of the transistor can be reduced while the physical thickness of the gate insulator is maintained. In addition, the equivalent oxide thickness (EOT) of the insulator functioning as the gate insulator can be reduced.

As described above, for the insulator 250a, an oxide containing one or both of aluminum and hafnium is preferably used, and an oxide that has an amorphous structure and contains one or both of aluminum and hafnium is further preferably used. Since aluminum oxide can be formed as an amorphous film relatively easily by an ALD method, use of aluminum oxide having an amorphous structure is preferred. In this embodiment, an aluminum oxide film is used for the insulator 250a. In this case, the insulator 250a is an insulator that contains at least oxygen and aluminum. The aluminum oxide has an amorphous structure. In this case, the insulator 250a has an amorphous structure.

An insulator having a thermally stable structure, such as silicon oxide or silicon oxynitride, is preferably used for the insulator 250b. Note that in this specification and the like, an oxynitride refers to a material that contains more oxygen than nitrogen in its composition, and a nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

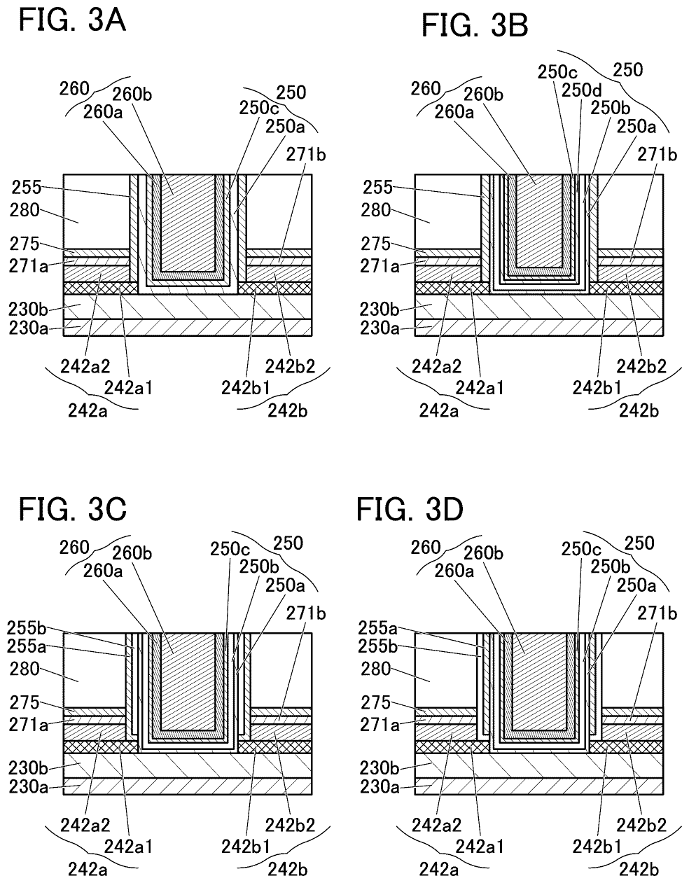

As illustrated in FIG. 3B, an insulator 250d may be provided over the insulator 250b. In this case, as the insulator 250d, an insulator that can be used for the insulator 250a can be provided. For the insulator 250d, hafnium oxide can be used, for example. Here, when the insulator 250d is provided between the insulator 250c and the insulator 250b, hydrogen contained in the insulator 250b and the like can be captured or fixed more effectively.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to the insulator 250a, the insulator 250c, the insulator 250d, the insulator 255, and the insulator 275, for example.

Note that in this specification and the like, a barrier insulator refers to an insulator having a barrier property. In this specification and the like, “having a barrier property” means having a property of hindering the permeation of a target substance (also referred to as having a low permeability). For example, an insulator having a barrier property hardly allows a target substance to diffuse into the insulator. As another example, an insulator having a barrier property has a function of capturing or fixing (also referred to as gettering) a target substance in the insulator.

Examples of the barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 250a, the insulator 250c, the insulator 250d, the insulator 255, and the insulator 275 preferably has a single-layer structure or a stacked-layer structure of the barrier insulator against oxygen. For example, having a stacked structure, the insulator 255 can have a two-layer structure of an aluminum oxide film and a silicon nitride film over the aluminum oxide film.

The insulator 250a and the insulator 255 each preferably have a barrier property against oxygen. It is preferable that oxygen be less likely to pass through the insulator 250a and the insulator 255 than at least the insulator 280. The insulator 250a includes a region in contact with a side surface of the conductor 242a1 and a region in contact with a side surface of the conductor 242b1. The insulator 255 includes a region in contact with the top surface of the conductor 242a1, the top surface of the conductor 242b1, the side surface of the conductor 242a2, and the side surface of the conductor 242b2. The insulator 250a is in contact with the side surface of the insulator 255. When the insulator 250a and the insulator 255 each have a barrier property against oxygen, oxidation of the side surfaces of the conductor 242a and the conductor 242b and formation of oxide films on the side surfaces can be inhibited. Accordingly, a decrease in the on-state current or field-effect mobility of the transistor 200 can be inhibited.

The insulator 250a is provided in contact with the top surface and a side surface of the oxide 230b, a side surface of the oxide 230a, a side surface of the insulator 224, and the top surface of the insulator 222. When the insulator 250a has a barrier property against oxygen, release of oxygen from the channel formation region of the oxide 230b caused by heat treatment or the like can be inhibited. This can reduce formation of oxygen vacancies in the oxide 230a and the oxide 230b.

By providing the insulator 250a and the insulator 255, even when the insulator 280 contains an excess amount of oxygen, excessive supply of oxygen to the oxide 230a and the oxide 230b can be inhibited and an appropriate amount of oxygen can be supplied to the oxide 230a and the oxide 230b. Thus, it is possible to inhibit excessive oxidation of the source region and the drain region and a decrease in the on-state current or field-effect mobility of the transistor 200.

The oxide containing one or both of aluminum and hafnium has a barrier property against oxygen and thus can be suitably used for the insulator 250a.

Silicon nitride also has a barrier property against oxygen and thus can be suitably used for the insulator 255. In this case, the insulator 255 is an insulator that contains at least nitrogen and silicon. The insulator 255 preferably has a barrier property against hydrogen. Accordingly, diffusion of impurities contained in the conductors 242a2 and 242b2, such as hydrogen, into the oxide 230b can be prevented.

The insulator 250c preferably has a barrier property against oxygen. The insulator 250c is provided between the conductor 260 and the channel formation region of the oxide 230 and between the insulator 280 and the conductor 260. Such a structure can inhibit diffusion of oxygen contained in the channel formation region of the oxide 230 into the conductor 260 and formation of oxygen vacancies in the channel formation region of the oxide 230. Moreover, oxygen contained in the oxide 230 and oxygen contained in the insulator 280 can be inhibited from diffusing into the conductor 260 and oxidizing the conductor 260. It is preferable that oxygen be less likely to pass through the insulator 250c than at least the insulator 280. For example, a silicon nitride film is preferably used for the insulator 250c. In this case, the insulator 250c is an insulator that contains at least nitrogen and silicon.

The insulator 250c preferably has a barrier property against hydrogen. Accordingly, diffusion of impurities contained in the conductor 260, such as hydrogen, into the oxide 230b can be prevented.

The insulator 275 preferably has a barrier property against oxygen. The insulator 275 is provided between the insulator 280 and the conductor 242a and between the insulator 280 and the conductor 242b. With this structure, oxygen contained in the insulator 280 can be inhibited from diffusing into the conductor 242a and the conductor 242b. Thus, the conductor 242a and the conductor 242b can be inhibited from being oxidized by oxygen contained in the insulator 280, so that an increase in resistivity and a reduction in on-state current can be inhibited. It is preferable that oxygen be less likely to pass through the insulator 275 than at least the insulator 280. For example, silicon nitride is preferably used for the insulator 275. In this case, the insulator 275 is an insulator that contains at least nitrogen and silicon.

In order to inhibit a reduction in hydrogen concentration in the source region and the drain region in the oxide 230, a barrier insulator against hydrogen is preferably provided in the vicinity of each of the source region and the drain region. In the semiconductor device described in this embodiment, the barrier insulator against hydrogen is, for example, the insulator 275.

Examples of the barrier insulator against hydrogen include oxides such as aluminum oxide, hafnium oxide, and tantalum oxide and nitrides such as silicon nitride. For example, the insulator 275 preferably has a single-layer structure or a stacked-layer structure of the barrier insulator against hydrogen.

Providing the insulator 275 as described above can inhibit hydrogen in the source region and the drain region from diffusing to the outside, so that a reduction in the hydrogen concentrations of the source region and the drain region can be inhibited. Thus, the source region and the drain region can be n-type regions.

With the above structure, the channel formation region can be an i-type or substantially i-type region, and the source region and the drain region can be n-type regions. Thus, a semiconductor device with favorable electrical characteristics can be provided. The semiconductor device with the above structure can have favorable electrical characteristics even when miniaturized or highly integrated. Miniaturization of the transistor 200 can improve the high frequency characteristics. Specifically, the cutoff frequency can be increased.

The insulator 250a to the insulator 250d function as part of the first gate insulator. The insulator 250a to the insulator 250d are provided in the opening formed in the insulator 280 and the like, together with the insulator 255 and the conductor 260. The thicknesses of the insulator 250a to the insulator 250d are preferably small for scaling down of the transistor 200. The thickness of each of the insulator 250a to the insulator 250d is preferably greater than or equal to 0.1 nm and less than or equal to 10 nm, further preferably greater than or equal to 0.1 nm and less than or equal to 5.0 nm, further preferably greater than or equal to 0.5 nm and less than or equal to 5.0 nm, still further preferably greater than or equal to 1.0 nm and less than 5.0 nm, yet still further preferably greater than or equal to 1.0 nm and less than or equal to 3.0 nm. Note that at least part of each of the insulator 250a to the insulator 250d includes a region having the above-described thickness.

To form the insulator 250a to the insulator 250d having a small thickness as described above, an atomic layer deposition (ALD) method is preferably used for deposition. Furthermore, in the case where the insulator 250a to the insulator 250d and the insulator 255 are provided in the opening in the insulator 280 and the like, an ALD method is preferably employed. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables deposition at a lower temperature.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. Therefore, the insulator 255 and the insulator 250 can be deposited on the side surface of the opening portion formed in the insulator 280 and the like, the side end portions of the conductors 242a and 242b, and the like, with a small thickness like the above-described thickness and favorable coverage.

Note that some of precursors used in an ALD method contain carbon or the like. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

Although the case where the insulator 250 has a three-layer structure of the insulator 250a to the insulator 250c or a four-layer structure of the insulator 250a to the insulator 250d is described above, the present invention is not limited thereto. The insulator 250 can have a structure including at least one of the insulator 250a to the insulator 250d. When the insulator 250 is formed of one, two, or three layer(s) of the insulator 250a to the insulator 250d, the manufacturing process of the semiconductor device can be simplified and the productivity can be increased.

For example, as illustrated in FIG. 3A, the insulator 250 may have a two-layer structure. In that case, the insulator 250 preferably has a stacked-layer structure of the insulator 250a and the insulator 250c over the insulator 250a. A high-k material can be used for at least one of the insulator 250a and the insulator 250c. Thus, the equivalent oxide thicknesses (EOT) of the insulator 250a and the insulator 250c can be reduced while the thicknesses thereof are kept large enough to prevent leakage current.

In addition to the above structure, the semiconductor device of this embodiment preferably has a structure that inhibits entry of hydrogen into the transistor 200 and the like. For example, an insulator having a function of inhibiting diffusion of hydrogen is preferably provided to cover one or both of the upper portion and the lower portion of the transistor 200 and the like. In the semiconductor device described in this embodiment, the insulator corresponds to the insulator 282, the insulator 283, the insulator 222, and the insulator 221, for example. The insulator 215 provided below the transistor 200 may have a structure similar to the structure of one or both of the insulator 282 and the insulator 283. In such a case, the insulator 215 may have a stacked-layer structure of the insulator 282 and the insulator 283; the insulator 282 may be the lower layer and the insulator 283 may be the upper layer, or the insulator 282 may be the upper layer and the insulator 283 may be the lower layer.

One or more of the insulator 283, the insulator 282, the insulator 222, and the insulator 221 preferably function as a barrier insulator that inhibits diffusion of impurities such as water or hydrogen into the transistor 200 and the like from the substrate side or from above the transistor 200 and the like. Thus, one or more of the insulator 283, the insulator 282, the insulator 222, and the insulator 221 preferably include an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (i.e., the insulating material through which the impurities are less likely to pass). Alternatively, it is preferable to include an insulating material having a function of inhibiting diffusion of oxygen (e.g., at least one of an oxygen atom, an oxygen molecule, and the like) (i.e., the insulating material through which the oxygen is less likely to pass).

Each of the insulator 283, the insulator 282, the insulator 222, and the insulator 221 preferably includes an insulator having a function of preventing diffusion of oxygen and impurities such as water and hydrogen. Examples of the insulator include aluminum oxide, magnesium oxide, hafnium oxide, zirconium oxide, oxide containing aluminum and hafnium (hafnium aluminate), oxide containing hafnium and zirconium (hafnium zirconium oxide), gallium oxide, indium gallium zinc oxide, silicon nitride, and silicon nitride oxide. For example, silicon nitride, which has a higher hydrogen barrier property, is preferably used for the insulator 283 and the insulator 221. For example, the insulator 282 preferably includes aluminum oxide or the like, which has a function of capturing and fixing hydrogen well. For example, hafnium oxide, which has high capability of capturing or fixing hydrogen and is a high dielectric constant (high-k) material, is preferably used for the insulator 222.

Such a structure can inhibit impurities such as water and hydrogen from diffusing into the transistor 200 or the like from an interlayer insulating film or the like positioned above the insulator 283. Furthermore, impurities such as water and hydrogen can be inhibited from diffusing into the transistor 200 or the like from an interlayer insulating film or the like positioned below the insulator 221. Moreover, hydrogen contained in the insulator 280, the insulator 224, and the insulator 250, and the like can be captured and fixed in the insulator 282 or the insulator 222. Providing the insulator 282 and the insulator 283 can inhibit oxygen contained in the insulator 280 and the like from diffusing to the components over the transistor 200 or the like. Providing the insulator 222 and the insulator 221 can prevent oxygen contained in the insulator 224 and the like from diffusing below the transistor 200 or the like. With such a structure where the transistor 200 is surrounded by upper and lower insulators having a function of inhibiting diffusion of oxygen and impurities such as water and hydrogen, excess oxygen and hydrogen can be prevented from diffusing into the oxide semiconductor. Thus, the semiconductor device can have improved electrical characteristics and reliability.

For example, silicon nitride, which has a high hydrogen barrier property, is preferably used for the insulator 255, the insulator 275, and the insulator 250c. Aluminum oxide, which has high capability of capturing or fixing hydrogen, is preferably used for the insulator 250a, for example.

Here, it is preferable that a region of the insulator 275 not overlapping with the oxide 230 be in contact with the insulator 222, a side end portion of the insulator 275 be in contact with the insulator 255, and an upper end portion of the insulator 255 and upper end portions of the insulator 250a to the insulator 250c be in contact with the insulator 282. With the above structure, in a region sandwiched between the insulator 283 and the insulator 221, the insulator 280 is separated from the oxide 230 by the insulator 275, the insulator 280 is separated from the insulator 250b by the insulator 255 and the insulator 250a, the conductor 260 is separated from the insulator 250b by the insulator 250c, and the conductor 242a2 and the conductor 242b2 are separated from the insulator 250b by the insulator 255 and the insulator 250a.

Accordingly, diffusion of impurities contained in the insulator 280, such as water and hydrogen, into the oxide 230 and the insulator 250b can be prevented. Impurities such as water and hydrogen contained in the conductor 260 can be prevented from diffusing into the oxide 230 through the insulator 250b. Impurities such as water and hydrogen contained in the conductor 242a2 and the conductor 242b2 can be prevented from diffusing into the oxide 230 through the insulator 250b. For example, even when a contact plug is formed in contact with top surfaces of the conductor 242a2 and the conductor 242b2 and impurities such as water and hydrogen diffuse into the conductor 242a2 and the conductor 242b2 through the contact plug, the amount of impurities such as water and hydrogen diffusing into the oxide 230 can be reduced. Hydrogen contained in the insulator 250a and the insulator 250b can be captured and fixed in the insulator 282. With such a structure, the amount of hydrogen diffusing into the oxide semiconductor can be further reduced. Thus, the semiconductor device can have improved electrical characteristics and reliability.

In the transistor 200, the conductor 205 is placed to overlap with the oxide 230 and the conductor 260. Here, the conductor 205 is preferably provided to be embedded in an opening portion formed in the insulator 216. Moreover, the conductor 205 is preferably provided to extend in the channel width direction as illustrated in FIG. 1A and FIG. 1C. With such a structure, the conductor 205 functions as a wiring when a plurality of transistors are provided.

As illustrated in FIG. 1B and FIG. 1C, the conductor 205 preferably includes the conductor 205a and the conductor 205b. The conductor 205a is provided in contact with the bottom surface and the sidewall of the opening portion. The conductor 205b is provided to fill a concave portion that is defined by the conductor 205a and formed along the opening portion. Here, the top surface of the conductor 205 is level or substantially level with the top surface of the insulator 216.

Here, the conductor 205a preferably includes a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, the conductor 205a is preferably formed using a conductive material having a function of inhibiting diffusion of oxygen (e.g., at least one of oxygen atoms and oxygen molecules).

When a conductive material having a function of inhibiting diffusion of hydrogen is used for the conductor 205a, impurities such as hydrogen contained in the conductor 205b can be prevented from diffusing into the oxide 230 through the insulator 216 and the like. When a conductive material having a function of inhibiting diffusion of oxygen is used for the conductor 205a, the conductivity of the conductor 205b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 205a can have a single-layer structure or a stacked-layer structure of the above conductive material. For example, the conductor 205a preferably includes titanium nitride.

A conductive material containing tungsten, copper, or aluminum as its main component is preferably used for the conductor 205b. For example, the conductor 205b preferably includes tungsten.

The conductor 205 can function as the second gate electrode. In that case, by changing a potential applied to the conductor 205 not in conjunction with but independently of a potential applied to the conductor 260, the threshold voltage (Vth) of the transistor 200 can be controlled. In particular, by applying a negative potential to the conductor 205, Vth of the transistor 200 can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electrical resistivity of the conductor 205 is designed in consideration of the potential applied to the conductor 205, and the thickness of the conductor 205 is set in accordance with the electrical resistivity. The thickness of the insulator 216 is substantially equal to that of the conductor 205. Here, the conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, inhibiting diffusion of the impurities into the oxide 230.

Although the stacked-layer structure of the conductor 205a and the conductor 205b is described above, the present invention is not limited to this structure. The conductor 205 may have a single-layer structure or a stacked-layer structure of three or more layers. For example, in the case where the conductor 205 has a three-layer structure, a conductor that contains the same material as the conductor 205a can be further provided over the conductor 205b of the above-described stacked-layer structure of the conductors 205a and 205b. In that case, the level of the top surface of the conductor 205b may be lower than the level of the uppermost portion of the conductor 205a, and the aforementioned conductor may be formed to fill the depressed portion formed by the conductor 205a and the conductor 205b.

The insulator 224, the insulator 221, and the insulator 222 function as a second gate insulator.

The insulator 224 that is in contact with the oxide 230 preferably includes silicon oxide or silicon oxynitride, for example. Accordingly, oxygen can be supplied from the insulator 224 to the oxide 230, so that oxygen vacancies can be reduced.

The insulator 224 is preferably processed into an island shape in the same manner as the oxide 230. Thus, in the case where a plurality of the transistors 200 are provided, the insulator 224 having a substantially same size is provided in each of the transistors 200. Accordingly, among the transistors 200, the amount of oxygen supplied from the insulator 224 to the oxide 230 is substantially the same. This can reduce variations in electrical characteristics of the transistors 200 in the substrate plane. Note that the structure is not limited to this, and it is possible not to pattern the insulator 224 as in the case of the insulator 222.

Note that the insulator 224 may have a stacked-layer structure of two or more layers. In that case, the stacked layers are not necessarily formed of the same material and may be formed of different materials.

A conductive material that is less likely to be oxidized or a conductive material having a function of inhibiting diffusion of oxygen is preferably used for each of the conductor 242a, the conductor 242b, and the conductor 260. Examples of the conductive material include a conductive material containing nitrogen and a conductive material containing oxygen. Thus, a decrease in the conductivity of the conductor 242a, the conductor 242b, and the conductor 260 can be inhibited. In the case where a conductive material containing metal and nitrogen is used for the conductor 242a, the conductor 242b, and the conductor 260, the conductor 242a, the conductor 242b, and the conductor 260 are conductors that contain at least metal and nitrogen.

In FIG. 1B, the conductors 242a and 242b each have a two-layer structure. The conductor 242a is a stacked film of the conductor 242a1 and the conductor 242a2 over the conductor 242a1, and the conductor 242b is a stacked film of the conductor 242b1 and the conductor 242b2 over the conductor 242b1. In this case, a conductive material that is less likely to be oxidized or a conductive material having a function of inhibiting diffusion of oxygen is preferably used for the layer (the conductor 242a1 and the conductor 242b1) in contact with the oxide 230b. This can inhibit a reduction in the conductivity of the conductors 242a and 242b. Oxygen is prevented from being extracted from the oxide 230b, that is, an excessive amount of oxygen vacancies can be prevented from being formed. For the layer (the conductor 242a1 and the conductor 242b1) in contact with the oxide 230b, a material that is likely to absorb (extract) hydrogen is preferably used, in which case the hydrogen concentration in the oxide 230 can be reduced.

As the conductors 242a1 and 242b1, a metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

Note that hydrogen included in the oxide 230b or the like diffuses into the conductor 242a1 or the conductor 242b1 in some cases. In particular, when a nitride containing tantalum is used for the conductor 242a1 and the conductor 242b1, hydrogen included in the oxide 230b or the like is likely to diffuse into the conductor 242a1 or the conductor 242b1, and the diffused hydrogen is bonded to nitrogen included in the conductor 242a1 or the conductor 242b1 in some cases. That is, hydrogen included in the oxide 230b or the like is absorbed by the conductor 242a1 or the conductor 242b1 in some cases.

The conductor 242a2 and the conductor 242b2 preferably have higher conductivity than the conductor 242a1 and the conductor 242b1. For example, the thicknesses of the conductor 242a2 and the conductor 242b2 are preferably larger than the thicknesses of the conductor 242a1 and the conductor 242b1. For the conductor 242a2 and the conductor 242b2, a conductor that can be used for the conductor 205b can be used. The above structure can reduce the resistances of the conductor 242a2 and the conductor 242b2. Accordingly, the operating speed of the semiconductor device of this embodiment can be improved.

For example, tantalum nitride or titanium nitride can be used for the conductor 242a1 and the conductor 242b1, and tungsten can be used for the conductor 242a2 and the conductor 242b2.

To inhibit a reduction in the conductivity of the conductors 242a and 242b, an oxide having crystallinity, such as a CAAC-OS, is preferably used for the oxide 230b. Specifically, a metal oxide containing indium, zinc, and one or more selected from gallium, aluminum, and tin is preferably used. When a CAAC-OS is used, oxygen extraction from the oxide 230b by the conductor 242a or the conductor 242b can be inhibited. Furthermore, it is possible to inhibit a reduction in the conductivity of the conductor 242a and the conductor 242b.

As illustrated in FIG. 1B and FIG. 1C, the insulator 255 is provided in the opening formed in the insulator 280 and the like, and in contact with the side surface of the insulator 280, a side surface of the insulator 275, a side surface of the insulator 271a, a side surface of the insulator 271b, the side surface of the conductor 242a2, the side surface of the conductor 242b2, the top surface of the conductor 242a1, the top surface of the conductor 242b1, and the top surface of the insulator 222. In other words, the insulator 255 is formed in a sidewall shape to be in contact with a sidewall of the opening formed in the insulator 280 and the like.

The insulator 255 is formed in contact with the side surface of the conductor 242a2 and the side surface of the conductor 242b2, and is an inorganic insulator that protects the conductor 242a2 and the conductor 242b2. The insulator 255 is preferably an inorganic insulator that is less likely to be oxidized because it is exposed to an oxidation atmosphere. Since the insulator 255 is in contact with the conductor 242a2 and the conductor 242b2, the insulator 255 is preferably an inorganic insulator that is less likely to oxidize the conductor 242a2 and the conductor 242b2. Therefore, for the insulator 255, an insulating material that can be used for the insulator 250c having a barrier property against oxygen is preferably used. For the insulator 255, silicon oxynitride can be used.

With the insulator 255 described above, even when heat treatment is performed in an atmosphere containing oxygen after the division of the conductor 242_1 into the conductor 242a1 and the conductor 242b1 and before the formation of the insulator 250, the conductor 242a2 and the conductor 242b2 are not excessively oxidized.

The thickness of the insulator 255 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulator 255 has a thickness in the above range, excessive oxidation of the conductor 242a2 and the conductor 242b2 can be prevented. In this case, at least part of the insulator 255 may have a region with the above-described thickness. Since the insulator 255 is provided in contact with the sidewall of the opening formed in the insulator 280 and the like, the insulator 255 is preferably formed by a method capable of depositing a film with good coverage, such as an ALD method. When the thickness of the insulator 255 is set excessively large, the time for depositing the insulator 255 by an ALD method is long, which decreases the productivity; for this reason, the thickness of the insulator 255 is preferably in the above range.

Furthermore, the insulator 255 may have a stacked-layer structure of two or more layers. In that case, at least one of the stacked layers is the above-described inorganic insulator that is less likely to be oxidized. For example, as illustrated in FIG. 3C, the insulator 255 may have a stacked-layer structure of an insulator 255a and an insulator 255b over the insulator 255a. The insulator 255a can be regarded as being provided on the inner side of the insulator 255b. Here, a bottom surface of the insulator 255b is in contact with the insulator 255a in some cases. The inorganic insulator that is less likely to be oxidized may be used for the insulator 255a, and an insulator that can be used for the insulator 250b (e.g., silicon oxide) may be used for the insulator 255b. The dielectric constant of the insulator 255b is preferably lower than that of the insulator 255a. In the above manner, the insulator 255 has a two-layer structure to have a large thickness, the distance between the conductor 260 and the conductor 242a or the conductor 242b can be increased, so that the parasitic capacitance can be reduced.

Although FIG. 3C illustrates a structure in which the insulator 255a is positioned on the outer side and the insulator 255b is positioned on the inner side, the present invention is not limited thereto. For example, as illustrated in FIG. 3D, the insulator 255b may be positioned on the outer side and the insulator 255a may be positioned on the inner side. Here, a bottom surface of the insulator 255a is in contact with the insulator 255b in some cases.

The insulator 255 functions as a mask at the time of dividing the conductor 242_1 into the conductor 242a1 and the conductor 242b1. Accordingly, as illustrated in FIG. 1B or the like, it is preferable that the side end portion of the insulator 255 be aligned or substantially aligned with the side end portion of the conductor 242a1 and a side end portion of the conductor 242b1 in the cross-sectional view of the transistor 200.

In the case where side end portions are aligned or substantially aligned with each other in a cross-sectional view and the case where top surface shapes are the same or substantially the same, it can be said that outlines of stacked layers at least partly overlap with each other in a top view. For example, the case where a lower part of a side end portion of an upper layer is in contact with an upper part of a side end portion of a lower layer is included. For example, the case where an upper layer and a lower layer are processed using the same mask pattern or mask patterns that are partly the same is included. For another example, the case where a lower layer is processed using an upper layer as a mask is also included in the expression. Note that, in some cases, the outlines do not exactly overlap with each other; the outline of part of the upper layer is positioned inward from the outline of the lower layer, or the outline of part of the upper layer is positioned outward from the outline of the lower layer. Such a case is also regarded as side end portions being aligned or substantially aligned or top surface shapes being the same or substantially the same.

Here, a part of the conductor 242a1 having a top surface on which the insulator 255 is formed to extend beyond the conductor 242a2 toward the conductor 260 side. Similarly, a part of the conductor 242b1 having a top surface on which the insulator 255 is formed to extend from the conductor 242b2 toward the conductor 260 side. As illustrated in FIG. 2B, in a cross-sectional view of the transistor 200 in the channel length direction, the distance L2 between the conductor 242a1 and the conductor 242b1 is preferably smaller than the distance L1 between the conductor 242a2 and the conductor 242b2. Specifically, the difference between the distance L1 and the distance L2 is equal to or substantially equal to twice the thickness of the insulator 255.

Since the distance L2 between the conductor 242a1 and the conductor 242b1 is preferably short because the distance L2 reflects the channel length of the transistor 200. For example, the distance L2 is preferably less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm. For example, the distance L2 is preferably greater than or equal to 2 nm and less than or equal to 20 nm. With such a structure, the distance between the source and the drain can be shortened, and the channel length can be accordingly shortened. Thus, the frequency characteristics of the transistor 200 can be improved. In this manner, miniaturization of the semiconductor device enables the semiconductor device to have a higher operation speed.

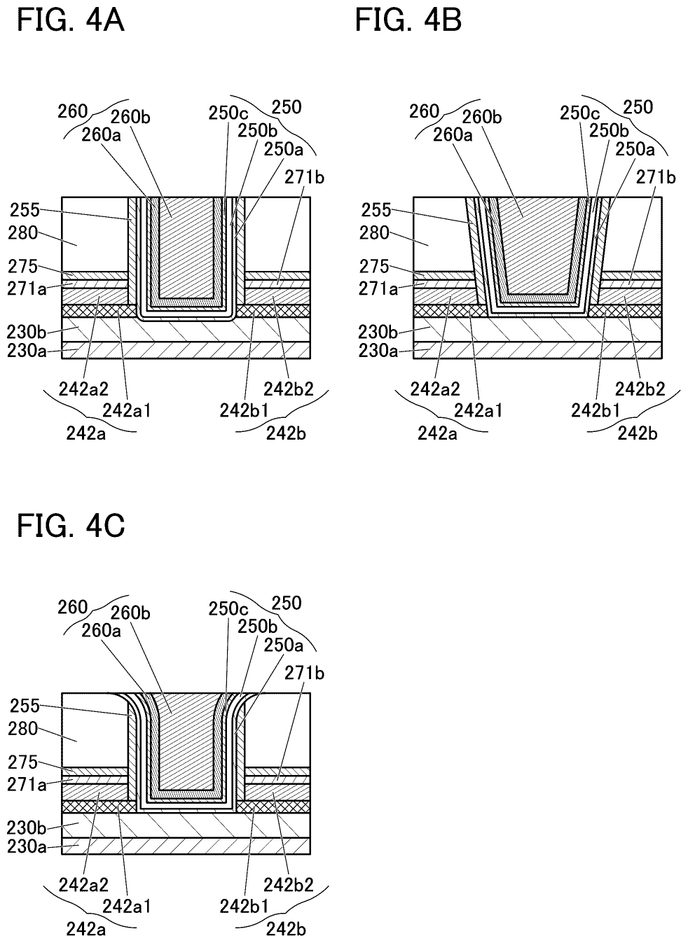

As illustrated in FIG. 4A, a depression is sometimes formed in a portion of the oxide 230b that is exposed from the conductor 242a1 and the conductor 242b1. In other words, in a top surface of the oxide 230b, the level of a region sandwiched between the conductor 242a1 and the conductor 242b1 is lower than the level of a region overlapping with the conductor 242a1 and the level of a region overlapping with the conductor 242b1 in some cases.

In the transistor 200 illustrated in FIG. 2A, the side surfaces of the conductor 242a1 and the conductor 242b1 that face each other and the side surfaces of the conductor 242a2 and the conductor 242b that face each other are perpendicular or substantially perpendicular to the top surface of the oxide 230b; however, the present invention is not limited thereto. As illustrated in FIG. 4B, for example, the facing side surfaces of the conductor 242a1 and the conductor 242b1 and the facing side surfaces of the conductor 242a2 and the conductor 242b2 may have tapered shapes. In that case, the side surfaces of the insulator 271a, the insulator 271b, the insulator 275, and the insulator 280 have tapered shapes in some cases.

Moreover, the taper angles of the conductors 242a1 and 242b1 may be formed to be more acute than the taper angles of the conductors 242a2 and 242b2.

As illustrated in FIG. 4C, an upper portion of the side surface of the insulator 255 has a tapered shape in some cases. Furthermore, as illustrated in FIG. 4C, an upper portion of the insulator 280 has a tapered shape that continues or roughly continues to the tapered shape of the side surface of the insulator 255 in some cases. As illustrated in FIG. 4C, an upper portion of the insulator 255 and an upper portion of the insulator 280 have curved surfaces in some cases. Here, the insulator 250a is sometimes in contact with the tapered shapes of the upper portions of the insulator 255 and the insulator 280. In that case, when the upper portions of the insulator 255 and the insulator 280 have curved surfaces, the insulator 250a can be formed with good coverage.

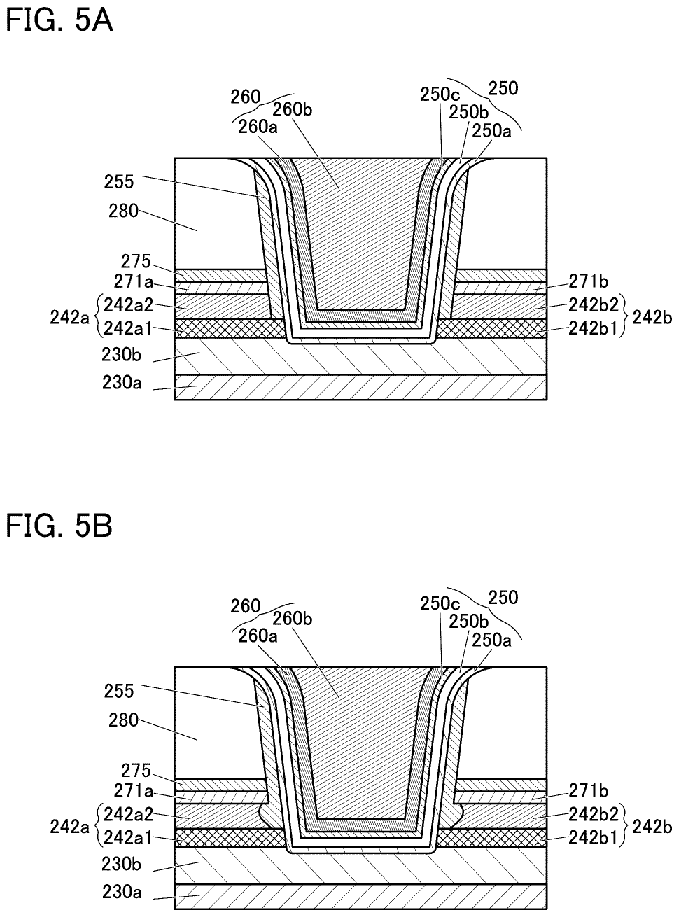

As illustrated in FIG. 5A, the transistor 200 may have the combined structures illustrated in FIG. 4A to FIG. 4C. That is, in some cases, the oxide 230b includes a depression in a part exposed from the conductors 242a1 and 242b1, the side surfaces of the conductors 242a1 and 242b1 have tapered shapes, the side surfaces of the conductors 242a2 and 242b2 have tapered shapes, and the upper portion of the side surface of the insulator 255 has a tapered shape.

Furthermore, as illustrated in FIG. 5B, the transistor 200 may have a structure in which the side surface of the conductor 242a2 and the side surface of the conductor 242b2 each have a recess. In other words, the conductor 242a2 and the conductor 242b2 can each be expressed as having a constricted part in a cross-sectional view. In addition, the side end portion of the insulator 271a more protrudes than the most recessed portion on the side surface of the conductor 242a2, toward the conductor 260 side. In other words, the insulator 271a has a shape overhanging the conductor 242a2. The insulator 271b also has a shape overhanging the conductor 242b2. The recesses on the side surface of the conductor 242a2 and the side surface of the conductor 242b2 preferably have a curved shape as illustrated in FIG. 5B. When the recesses are provided on the side surface of the conductor 242a2 and the side surface of the conductor 242b2, the insulator 255 can be formed to fill the recesses. With this structure, the thickness of the insulator 255 can be made larger in the vicinity of the side surface of the conductor 242a2 and the side surface of the conductor 242b2, so that oxidation of the side surface of the conductor 242a2 and the side surface of the conductor 242b2 can be further inhibited.

The insulator 271a and the insulator 271b are inorganic insulators functioning as etching stoppers in the processing into the conductor 242a2 and the conductor 242b2 and protecting the conductor 242a2 and the conductor 242b2. Since the insulator 271a and the insulator 271b are respectively in contact with the conductor 242a and the conductor 242b, the insulator 271a and the insulator 271b are preferably inorganic insulators that are less likely to oxidize the conductors 242a and 242b. Thus, the insulator 271a preferably has a stacked-layer structure of an insulator 271a1 and an insulator 271a2 over the insulator 271a1, and the insulator 271b preferably has a stacked-layer structure of an insulator 271b1 and an insulator 271b2 over the insulator 271b1. Here, the insulators 271a1 and 271b1 are preferably formed using the nitride insulator that can be used for the insulator 250c, so as not to easily oxidize the conductors 242a2 and 242b2. The insulators 271a2 and 271b2 are preferably formed using the oxide insulator that can be used for the insulator 250b, so as to function as etching stoppers.

Here, the insulator 271a1 is in contact with the top surface of the conductor 242a2 and part of the insulator 275, and the insulator 271b1 is in contact with the top surface of the conductor 242b2 and another part of the insulator 275. The insulator 271a2 is in contact with the top surface of the insulator 271a1 and the bottom surface of the insulator 275, and the insulator 271b2 is in contact with the top surface of the insulator 271b1 and the bottom surface of the insulator 275. For example, silicon nitride can be used for the insulator 271a1 and the insulator 271b1, and silicon oxide can be used for the insulator 271a2 and the insulator 271b2.

An insulator to be the insulator 271a and the insulator 271b functions as a mask for a conductor to be the conductor 242a and the conductor 242b, and thus each of the conductor 242a and the conductor 242b does not have a curved surface between the side surface and the top surface. Thus, end portions at the intersections of the side surfaces and the top surfaces of the conductor 242a and the conductor 242b are angular. The cross-sectional area of each of the conductor 242a and the conductor 242b is larger in the case where the end portion at the intersection of the side surface and the top surface of each of the conductor 242a and the conductor 242b is angular than in the case where the end portion has a curved surface. Furthermore, when a nitride insulator that is less likely to oxidize a metal is used for the insulators 271a1 and 271b1, excessive oxidation of the conductor 242a and the conductor 242b can be prevented. Accordingly, the resistance of the conductor 242a and the conductor 242b is reduced, so that the on-state current of the transistor can be increased.

As illustrated in FIG. 1B and FIG. 1C, the conductor 260 is placed in the opening formed in the insulator 280 and the insulator 275. The conductor 260 is provided in the opening to cover the top surface of the insulator 222, the side surface of the insulator 224, the side surface of the oxide 230a, the side surface of the oxide 230b, and the top surface of the oxide 230b, with the insulator 250 therebetween. The top surface of the conductor 260 is positioned to be level or substantially level with the uppermost portion of the insulator 250, the uppermost portion of the insulator 255, and the top surface of the insulator 280.

Note that the sidewall of the opening in which the conductor 260 and the insulator 250 are placed may be perpendicular or substantially perpendicular to the top surface of the insulator 222 or may be tapered. The tapered shape of the sidewall can improve the coverage with the insulator 255 and the insulator 250 provided in the opening in the insulator 280; as a result, defects such as voids can be reduced.

The conductor 260 functions as the first gate electrode of the transistor 200. Here, the conductor 260 is preferably provided to extend in the channel width direction as illustrated in FIG. 1A and FIG. 1C. With such a structure, the conductor 260 functions as a wiring when a plurality of transistors are provided.

In the case of the above structure, a curved surface may be provided between the side surface of the oxide 230b and the top surface of the oxide 230b in a cross-sectional view of the transistor 200 in the channel width direction as illustrated in FIG. 1C. That is, an end portion of the side surface and an end portion of the top surface may be curved (hereinafter also referred to as rounded).

The radius of curvature of the curved surface is preferably greater than 0 nm and less than the thickness of the oxide 230b in a region overlapping with the conductor 242a and the conductor 242b, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 250 and the conductor 260.

Note that in this specification and the like, a transistor structure where a channel formation region is electrically surrounded by at least the electric field of a first gate electrode is referred to as a surrounded channel (S-channel) structure. The S-channel structure disclosed in this specification and the like has a structure different from a Fin-type structure or a planar structure. The S-channel structure disclosed in this specification and the like can be regarded as a kind of the Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor 200 has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. When the transistor 200 has the S-channel structure, the GAA structure, or the LGAA structure, the channel formation region that is formed at the interface between the oxide 230 and the gate insulator or in the vicinity of the interface can correspond to the entire bulk of the oxide 230. Accordingly, the density of current flowing through the transistor can be increased, which can be expected to increase the on-state current of the transistor or increase the field-effect mobility of the transistor.

In this embodiment, the insulator 224 with an island shape is provided as described above. Accordingly, as illustrated in FIG. 1C, at least part of the bottom surface of the conductor 260 can be positioned lower than the bottom surface of the oxide 230b. Thus, the conductor 260 can be provided to face the top surface and the side surface of the oxide 230b, so that an electric field of the conductor 260 can be applied to the top surface and the side surface of the oxide 230b. When the insulator 224 with an island shape is provided in this manner, the transistor 200 can have the S-channel structure.

Although FIG. 1C illustrates a transistor with an S-channel structure as the transistor 200, the semiconductor device of one embodiment of the present invention is not limited thereto. For example, a transistor structure that can be used in one embodiment of the present invention may be one or more selected from the planar structure, the Fin-type structure, and the GAA structure.

FIG. 1B and the like illustrate the conductor 260 having a two-layer structure. Here, the conductor 260 preferably includes the conductor 260a and the conductor 260b placed over the conductor 260a. For example, the conductor 260a is preferably placed to cover the bottom surface and a side surface of the conductor 260b. In this case, a conductive material that is less likely to be oxidized or a conductive material having a function of inhibiting diffusion of oxygen is preferably used for the conductor 260a.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

When the conductor 260a has a function of inhibiting diffusion of oxygen, the conductivity of the conductor 260b can be inhibited from being lowered because of oxidation due to oxygen contained in the insulator 280 or the like. As the conductive material having a function of inhibiting diffusion of oxygen, titanium, titanium nitride, tantalum, tantalum nitride, ruthenium, or ruthenium oxide is preferably used, for example.

For the conductor 260b, a conductor having high conductivity is preferably used. For example, a conductive material containing tungsten, copper, or aluminum as its main component can be used for the conductor 260b. The conductor 260b may have a stacked-layer structure; for example, a stacked-layer structure of titanium or titanium nitride and the above conductive material may be employed.

In the transistor 200, the conductor 260 is formed in a self-aligned manner to fill the opening formed in the insulator 280 and the like. The formation of the conductor 260 and the like in this manner allows the conductor 260 to be placed to overlap with a region between the conductor 242a1 and the conductor 242b1 without alignment.

The insulator 216 and the insulator 280 each preferably have a lower dielectric constant than the insulator 222. When a material with a low dielectric constant is used for an interlayer film, parasitic capacitance generated between wirings can be reduced.

For example, the insulator 216 and the insulator 280 each preferably include one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. A material such as silicon oxide, silicon oxynitride, or porous silicon oxide is particularly preferably used, in which case a region including oxygen that is released by heating can be easily formed.

The top surfaces of the insulator 216 and the insulator 280 may be planarized.

The concentration of impurities such as water or hydrogen in the insulator 280 is preferably reduced. For example, the insulator 280 preferably includes an oxide containing silicon, such as silicon oxide or silicon oxynitride.

### <Component Materials for Semiconductor Device>

Component materials that can be used in the semiconductor device are described below. Note that each layer included in the semiconductor device may have a single-layer structure or a stacked-layer structure.

### <<Substrate>>

As a substrate where the transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is the above-described semiconductor substrate including an insulator region, e.g., an SOI (Silicon On Insulator) substrate. Examples of the conductor substrate include a graphite substrate, a metal substrate, an alloy substrate, and a conductive resin substrate. Other examples of substrates include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, these substrates provided with one or more kinds of elements may be used. Examples of the element provided for the substrate include a capacitor, a resistor, a switching element, a light-emitting element, and a memory element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In contrast, when a material with a low relative dielectric constant is used for the insulator functioning as an interlayer film, parasitic capacitance generated between wirings can be reduced. Thus, a material is preferably selected depending on the function of the insulator.

Examples of the insulator with a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used. Specific examples of the insulator having a function of inhibiting passage of oxygen and impurities such as hydrogen include a metal oxide such as aluminum oxide, magnesium oxide, gallium oxide, germanium oxide, yttrium oxide, zirconium oxide, lanthanum oxide, neodymium oxide, hafnium oxide, and tantalum oxide and a metal nitride such as aluminum nitride, silicon nitride oxide, and silicon nitride.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 230, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. Examples of the conductor include tantalum nitride, titanium nitride, tungsten, a nitride containing titanium and aluminum, a nitride containing tantalum and aluminum, ruthenium oxide, ruthenium nitride, an oxide containing strontium and ruthenium, and an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. Alternatively, a semiconductor having high electrical conductivity, typified by polycrystalline silicon containing an impurity element such as phosphorus, or silicide such as nickel silicide may be used.

In the case of using a conductor having a stacked-layer structure, for example, a stacked-layer structure combining a material containing the above metal element and a conductive material containing oxygen, a stacked-layer structure combining a material containing the above metal element and a conductive material containing nitrogen, or a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above-described metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With use of such a material, hydrogen contained in the metal oxide where the channel is formed can be captured in some cases. Alternatively, hydrogen entering from an external insulator or the like can be captured in some cases.

### <<Metal Oxide>>

For the oxide 230, a metal oxide functioning as a semiconductor (an oxide semiconductor) is preferably used. A metal oxide that can be used for the oxide 230 of one embodiment of the present invention will be described below.

The metal oxide preferably contains at least indium or zinc. In particular, indium and zinc are preferably contained. Moreover, aluminum, gallium, yttrium, tin, antimony, or the like is preferably contained in addition to them. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, an element M, and zinc is considered. The element M is aluminum, gallium, yttrium, tin, or antimony. Examples of other elements that can be used as the element M include boron, titanium, iron, nickel, germanium, zirconium, molybdenum, lanthanum, cerium, neodymium, hafnium, tantalum, tungsten, magnesium, and cobalt. Note that a combination of two or more of the above elements may be used as the element M. In particular, the element M is preferably one or more kinds selected from gallium, aluminum, yttrium, and tin.

Note that in this specification and the like, a metal oxide containing nitrogen is also collectively referred to as a metal oxide in some cases. A metal oxide containing nitrogen may be referred to as a metal oxynitride.

Hereinafter, an In—Ga—Zn oxide is described as an example of the metal oxide.

Examples of crystal structures of an oxide semiconductor include amorphous (including completely amorphous), CAAC (c-axis-aligned crystalline), nc (nanocrystalline), CAC (cloud-aligned composite), single crystal, and polycrystalline structures.

Note that oxide semiconductors might be classified in a manner different from the above-described one when classified in terms of the structure. For example, oxide semiconductors are classified into a single crystal oxide semiconductor and a non-single-crystal oxide semiconductor. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the maximum diameter of the crystal region may be approximately several tens of nanometers.

The CAAC-OS is an oxide semiconductor with high crystallinity in which no clear grain boundary is observed. Thus, in the CAAC-OS, a reduction in electron mobility due to the grain boundary is less likely to occur. Moreover, since the crystallinity of an oxide semiconductor might be decreased by entry of impurities, formation of defects, or the like, the CAAC-OS can also be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for an OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter also referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

In a material composition of a CAC-OS in an In—Ga—Zn oxide that contains In, Ga, Zn, and O, there are regions containing In as a main component (first regions) in part of the CAC-OS and regions containing Ga as a main component (second regions) in another part of the CAC-OS. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. In the case of forming the CAC-OS by a sputtering method, one or more selected from an inert gas (typically, argon), an oxygen gas, and a nitrogen gas can be used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

Here, the first region is a region having higher conductivity than the second region. That is, when carriers flow through the first region, the conductivity of a metal oxide is exhibited. Accordingly, when the first regions are distributed in a metal oxide like a cloud, high field-effect mobility (μ) can be achieved.

On the other hand, the second region is a region having a higher insulating property than the first region. That is, when the second regions are distributed in a metal oxide, leakage current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

A transistor using the CAC-OS has high reliability. Thus, the CAC-OS is most suitable for a variety of semiconductor devices such as a display device.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <<Other Semiconductor Materials>>

A semiconductor material that has a band gap (a semiconductor material that is not a zero-gap semiconductor) may be used for the semiconductor layer of the transistor. For example, a single-element semiconductor such as silicon or a compound semiconductor such as gallium arsenide may be used.

For the semiconductor layer of the transistor, transition metal chalcogenide functioning as a semiconductor is preferably used, for example. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer of the transistor can provide a semiconductor device with a high on-state current.

### <Manufacturing Method of Semiconductor Device>

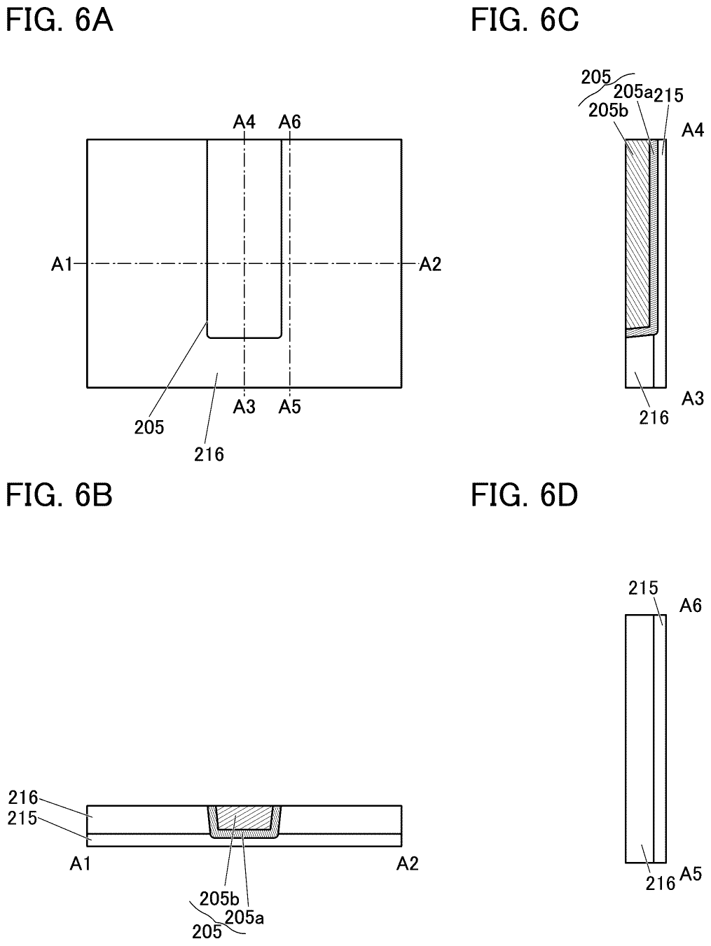

An example of a method for manufacturing the semiconductor device of one embodiment of the present invention will be described with reference to FIG. 6A to FIG. 18D. Here, the case of manufacturing the semiconductor device illustrated in FIG. 1A to FIG. 1D is described as an example.

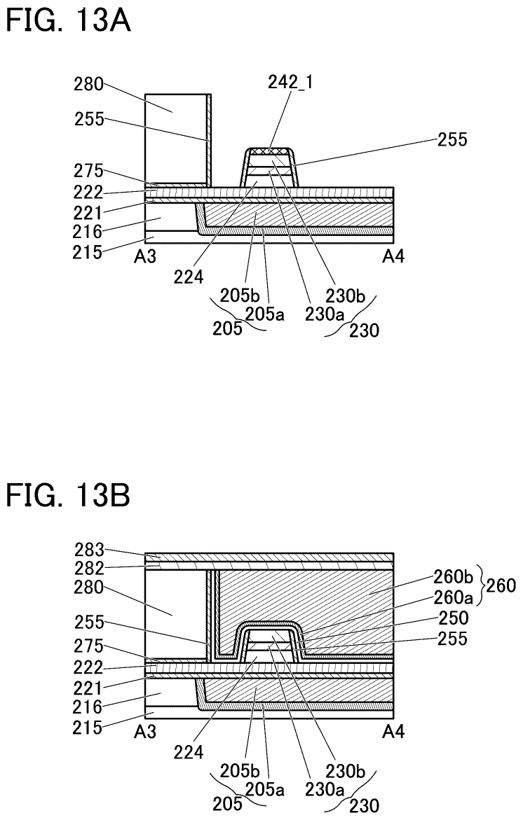

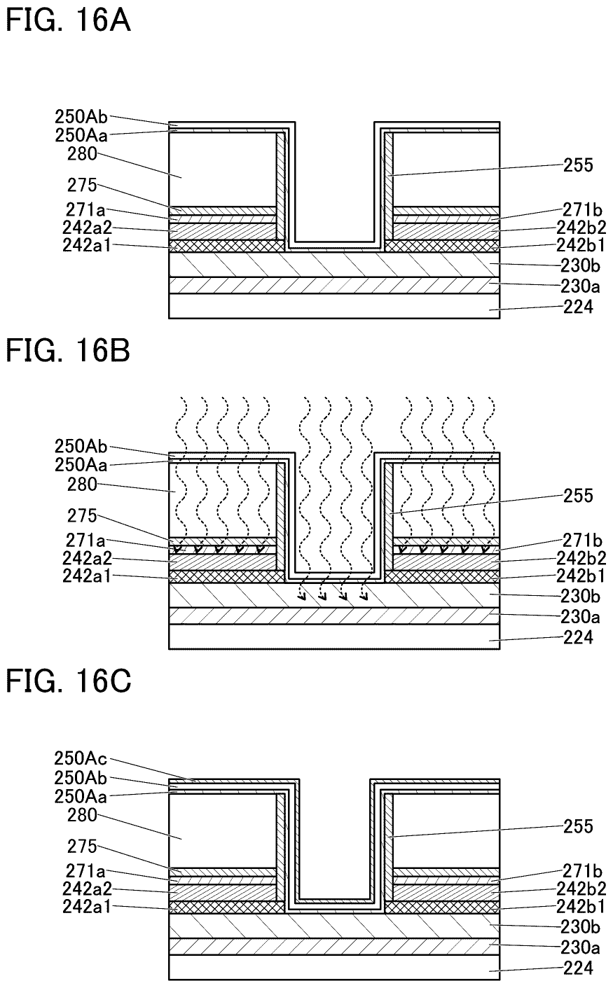

Note that A of each drawing is a plan view. Moreover, B of each drawing is a cross-sectional view corresponding to a portion indicated by the dashed-dotted line A1-A2 in A of each drawing, and is also a cross-sectional view in the channel length direction of the transistor 200. Furthermore, C of each drawing is a cross-sectional view corresponding to a portion indicated by the dashed-dotted line A3-A4 in A of each drawing, and is also a cross-sectional view in the channel width direction of the transistor 200. Moreover, D of each drawing is a cross-sectional view corresponding to a portion indicated by the dashed-dotted line A5-A6 in A of each drawing, and is also a cross-sectional view in the channel width direction of the transistor 200. Note that for clarity of the drawing, some components are not illustrated in the plan view of A of each drawing. FIG. 13A and FIG. 13B are each a cross-sectional view corresponding to a portion indicated by the dashed-dotted line A3-A4. FIG. 16A to FIG. 16C are enlarged cross-sectional views of the transistor 200 in the channel length direction.

Hereinafter, an insulating material for forming an insulator, a conductive material for forming a conductor, or a semiconductor material for forming a semiconductor can be deposited by a sputtering method, a chemical vapor deposition (CVD) method, a molecular beam epitaxy (MBE) method, a pulsed laser deposition (PLD) method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is deposited by a reactive sputtering method.

Note that CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, such plasma damage is not caused in the case of the thermal CVD method, which does not use plasma, and thus the yield of the semiconductor device can be increased. In addition, the thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, and the like can be used.

The CVD method and the ALD method are different from the sputtering method in which particles ejected from a target or the like are deposited. Thus, the CVD method and the ALD method are deposition methods that enable good step coverage almost regardless of the shape of an object to be processed. In particular, an ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the semiconductor device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors.

First, a substrate (not illustrated) is prepared, and the insulator 215 is deposited over the substrate (see FIG. 6A to FIG. 6D). As described above, the insulator 215 can be formed using an insulator similar to any one of the insulator 224, the insulator 282, and the insulator 283 or a stack including two or more thereof. As the disposition method for the insulator 215, a sputtering method, a CVD method, an MBE method, a PLD method, or an ALD method can be used, for example. It is preferable to use a sputtering method that does not need to use a molecule containing hydrogen as a deposition gas, in which case the hydrogen concentration in the insulator 215 can be reduced.

Next, the insulator 216 is deposited over the insulator 215. The insulator 216 is preferably deposited by a sputtering method. By using a sputtering method that does not need to use a molecule containing hydrogen as a deposition gas, the hydrogen concentration in the insulator 216 can be reduced. Without limitation to a sputtering method, the insulator 216 may be deposited by a CVD method, an MBE method, a PLD method, an ALD method, or the like as appropriate. In this embodiment, for the insulator 216, silicon oxide is deposited by a sputtering method.

The insulator 215 and the insulator 216 are preferably deposited successively without exposure to the air. For example, a multi-chamber film formation apparatus is used. As a result, the amounts of hydrogen in the deposited insulator 215 and insulator 216 can be reduced, and furthermore, entry of hydrogen into the films in intervals between deposition steps can be inhibited.

Then, an opening reaching the insulator 215 is formed in the insulator 216. Wet etching may be used for the formation of the opening; however, dry etching is preferably used for microfabrication. As the insulator 215, it is preferable to select an insulator that functions as an etching stopper film at the time of forming a groove by etching the insulator 216. For example, in the case where silicon oxide or silicon oxynitride is used for the insulator 216 in which the groove is to be formed, silicon nitride, aluminum oxide, hafnium oxide, or the like is preferably used for the insulator 215.

After the formation of the opening, a conductive film to be the conductor 205a is formed. The conductive film to be the conductor 205a desirably includes a conductor having a function of inhibiting passage of oxygen. For example, tantalum nitride, tungsten nitride, or titanium nitride can be used. Alternatively, a stacked film of the conductor having a function of inhibiting passage of oxygen and tantalum, tungsten, titanium, molybdenum, aluminum, copper, or a molybdenum-tungsten alloy can be used. The conductive film to be the conductor 205a can be formed by a sputtering method, a CVD method, an MBE method, a PLD method, an ALD method, or the like.

In this embodiment, titanium nitride is deposited for the conductive film to be the conductor 205a. When such a metal nitride is used for a layer below the conductor 205b, oxidation of the conductor 205b by the insulator 216 or the like can be inhibited. Furthermore, even when a metal that is likely to diffuse, such as copper, is used for the conductor 205b, the metal can be prevented from diffusing to the outside through the conductor 205a.

Next, a conductive film to be the conductor 205b is formed. Tantalum, tungsten, titanium, molybdenum, aluminum, copper, a molybdenum-tungsten alloy, or the like can be used for the conductive film to be the conductor 205b. The conductive film can be formed by a plating method, a sputtering method, a CVD method, an MBE method, a PLD method, an ALD method, or the like. In this embodiment, tungsten is deposited for the conductive film to be the conductor 205b.

Then, CMP treatment is performed to remove parts of the conductive film to be the conductor 205a and the conductive film to be the conductor 205b, so that the insulator 216 is exposed (see FIG. 6A to FIG. 6D). As a result, the conductor 205a and the conductor 205b remain only in the opening portion. Note that the insulator 216 is partly removed by the CMP treatment in some cases.

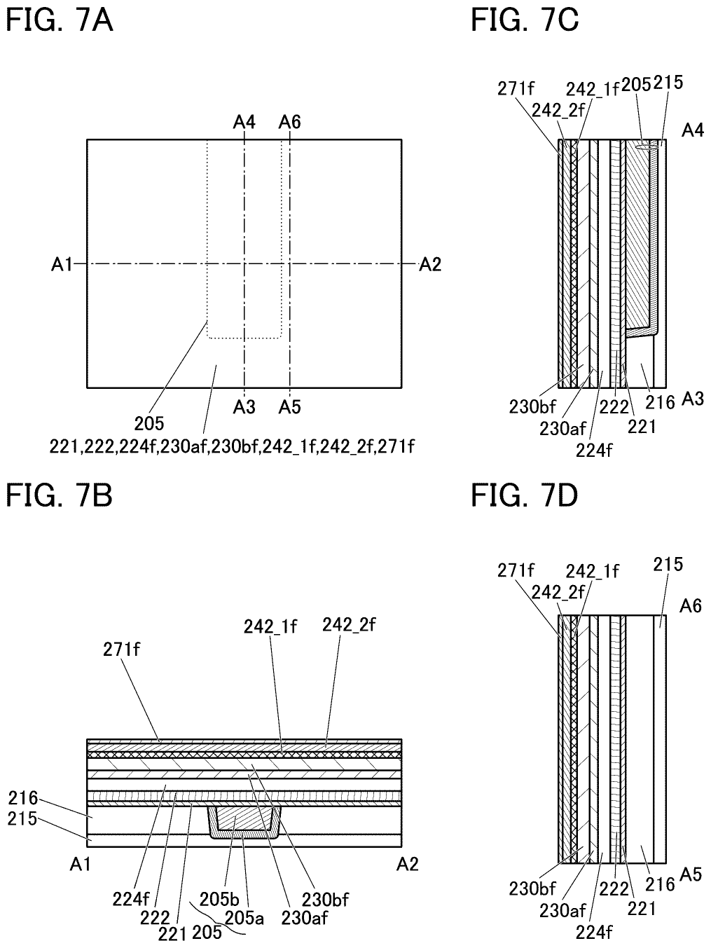

Next, the insulator 221 is deposited over the insulator 216 and the conductor 205 (see FIG. 7A to FIG. 7D).

An insulator having a barrier property against oxygen, hydrogen, and water is used as the insulator 221. The insulator 221 can be deposited by a sputtering method, a CVD method, an MBE method, a PLD method, or an ALD method, for example. In this embodiment, for the insulator 221, silicon nitride is deposited by a PEALD method.

Next, the insulator 222 is deposited over the insulator 221 (see FIG. 7A to FIG. 7D).

An insulator containing an oxide of one or both of aluminum and hafnium is preferably deposited as the insulator 222. Note that as the insulator containing an oxide of one or both of aluminum and hafnium, for example, aluminum oxide, hafnium oxide, or an oxide containing aluminum and hafnium (hafnium aluminate) is preferably used. Alternatively, hafnium-zirconium oxide is preferably used. The insulator containing an oxide of one or both of aluminum and hafnium has a barrier property against oxygen, hydrogen, and water. When the insulator 222 has a barrier property against hydrogen and water, hydrogen and water contained in components provided around the transistor are inhibited from diffusing into the transistor through the insulator 222, and generation of oxygen vacancies in the oxide 230 can be inhibited.

The insulator 222 can be deposited by a sputtering method, a CVD method, an MBE method, a PLD method, or an ALD method, for example. In this embodiment, for the insulator 222, hafnium oxide is deposited by an ALD method.

Next, an insulating film 224f is deposited over the insulator 222 (see FIG. 7A to FIG. 7D). For the insulating film 224f, an insulator corresponding to the insulator 224 is used.

The insulating film 224f can be formed by a sputtering method, a CVD method, an MBE method, a PLD method, or an ALD method, for example. In this embodiment, for the insulating film 224f, silicon oxide is deposited by a sputtering method. By using a sputtering method that does not need to use a molecule containing hydrogen as a deposition gas, the hydrogen concentration in the insulating film 224f can be reduced. The hydrogen concentration in the insulating film 224f is preferably reduced in this manner because the insulating film 224f is in contact with the oxide 230a in a later step.

Note that heat treatment may be performed before the insulating film 224f is formed. The heat treatment may be performed under reduced pressure, and the insulating film 224f may be successively formed without exposure to the air. Such treatment can remove moisture and hydrogen adsorbed onto the surface of the insulator 222 and can reduce the moisture concentration and the hydrogen concentration in the insulator 222. The insulator 221 is provided in contact with a bottom surface of the insulator 222, whereby entry of moisture or impurities such as hydrogen from the component below the insulator 221, which is caused by the heat treatment, can be prevented. The heat treatment temperature is preferably higher than or equal to 100° C. and lower than or equal to 400° C. In this embodiment, the heat treatment is performed at 250° C.

Next, an oxide film 230af is formed over the insulating film 224f, and an oxide film 230bf is formed over the oxide film 230af (see FIG. 7A to FIG. 7D). A metal oxide corresponding to the oxide 230a is used for the oxide film 230af, and a metal oxide corresponding to the oxide 230b is used for the oxide film 230bf. Note that the oxide film 230af and the oxide film 230bf are preferably formed successively without being exposed to an atmospheric environment. By the deposition without exposure to the air, impurities or moisture from the atmospheric environment can be prevented from being attached onto the oxide film 230af and the oxide film 230bf, so that the interface between the oxide film 230af and the oxide film 230bf or the vicinity of the interface can be kept clean.

The oxide film 230af and the oxide film 230bf can each be formed by a sputtering method, a CVD method, an MBE method, a PLD method, or an ALD method, for example. In this embodiment, the oxide film 230af and the oxide film 230bf are formed by a sputtering method.

For example, in the case where the oxide film 230af and the oxide film 230bf are formed by a sputtering method, oxygen or a mixed gas of oxygen and a noble gas is used as a sputtering gas. Increasing the proportion of oxygen contained in the sputtering gas can increase the amount of excess oxygen in the deposited oxide films. In the case where the oxide films are formed by a sputtering method, an In-M-Zn oxide target or the like can be used.

In particular, when the oxide film 230af is formed, part of oxygen contained in the sputtering gas is supplied to the insulating film 224f in some cases. Thus, the proportion of oxygen contained in the sputtering gas is preferably higher than or equal to 70%, further preferably higher than or equal to 80%, still further preferably 100%.

In the case where the oxide film 230bf is formed by a sputtering method and the proportion of oxygen contained in the sputtering gas for deposition is higher than 30% and lower than or equal to 100%, preferably higher than or equal to 70% and lower than or equal to 100%, an oxygen-excess oxide semiconductor is formed. In a transistor using an oxygen-excess oxide semiconductor for its channel formation region, relatively high reliability can be obtained. Note that one embodiment of the present invention is not limited thereto. In the case where the oxide film 230bf is formed by a sputtering method and the proportion of oxygen contained in the sputtering gas for deposition is higher than or equal to 1% and lower than or equal to 30%, preferably higher than or equal to 5% and lower than or equal to 20%, an oxygen-deficient oxide semiconductor is formed. In a transistor using an oxygen-deficient oxide semiconductor in its channel formation region, relatively high field-effect mobility can be obtained. Furthermore, when the deposition is performed while the substrate is being heated, the crystallinity of the oxide film can be improved.

In this embodiment, the oxide film 230af is deposited by a sputtering method using an oxide target with In:Ga:Zn=1:3:2 [atomic ratio] or an oxide target with In:Ga:Zn=1:3:4 [atomic ratio]. In addition, the oxide film 230bf is deposited by a sputtering method using an oxide target with In:Ga:Zn=1:1:1 [atomic ratio], an oxide target with In:Ga:Zn=1:1:1.2 [atomic ratio], an oxide target with In:Ga:Zn=4:2:4.1 [atomic ratio], or an oxide target with In:Ga:Zn=1:1:2 [atomic ratio]. Note that each of the oxide films is preferably formed so as to have characteristics required for the oxide 230a and the oxide 230b by selecting the deposition conditions and the atomic ratios as appropriate.

Note that the insulating film 224f, the oxide film 230af, and the oxide film 230bf are preferably deposited by a sputtering method without exposure to the air. For example, a multi-chamber deposition apparatus is preferably used. Thus, entry of hydrogen into the insulating film 224f, the oxide film 230af, and the oxide film 230bf in intervals between deposition steps can be inhibited.

Next, heat treatment is preferably performed. The heat treatment is performed in a temperature range where the oxide film 230af and the oxide film 230bf do not become polycrystals. The temperature of the heat treatment is preferably higher than or equal to 100° C., higher than or equal to 250° C., or higher than or equal to 350° C. and lower than or equal to 650° C., lower than or equal to 600° C., or lower than or equal to 550° C.

Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in an atmosphere of mixing a nitrogen gas and an oxygen gas, the proportion of the oxygen gas is preferably approximately 20%. The heat treatment may be performed under reduced pressure. Alternatively, heat treatment may be performed in a nitrogen gas or inert gas atmosphere, and then another heat treatment may be performed in an atmosphere containing an oxidizing gas at 10 ppm or more, 1% or more, or 10% or more in order to compensate for released oxygen.

The gas used in the above heat treatment is preferably highly purified. For example, the amount of moisture contained in the gas used in the above heat treatment is preferably 1 ppb or less, further preferably 0.1 ppb or less, still further preferably 0.05 ppb or less. The heat treatment using a highly purified gas can prevent entry of moisture or the like into the oxide film 230af, the oxide film 230bf, and the like as much as possible.

In this embodiment, the heat treatment is performed at 450° C. for one hour with the flow rate ratio of nitrogen gas to oxygen gas being 4:1. Through such heat treatment using the oxygen gas, impurities such as carbon, water, and hydrogen in the oxide film 230af and the oxide film 230bf can be reduced. The reduction of impurities in the films in this manner improves the crystallinity of the metal oxide film 230af and the metal oxide film 230bf, thereby offering a dense structure with a higher density. Thus, crystalline regions in the oxide film 230af and the oxide film 230bf are expanded, so that in-plane variations of the crystalline regions in the oxide film 230af and the oxide film 230bf can be reduced. Accordingly, an in-plane variation of electrical characteristics of transistors can be reduced.

By performing the heat treatment, hydrogen in the insulator 216, the insulating film 224f, the oxide film 230af, and the oxide film 230bf is absorbed by the insulator 222. In other words, hydrogen in the insulator 216, the insulating film 224f, the oxide film 230af, and the oxide film 230bf diffuses into the insulator 222. Accordingly, the hydrogen concentration in the insulator 222 increases, while the hydrogen concentrations in the insulator 216, the insulating film 224f, the oxide film 230af, and the oxide film 230bf decrease. Note that the insulator 221 is provided in contact with the bottom surface of the insulator 222, whereby entry of moisture or impurities such as hydrogen from below the insulator 221, which is caused by the heat treatment, can be prevented.

Specifically, the insulating film 224f (to be the insulator 224 later) functions as the second gate insulator of the transistor 200, and the oxide film 230af and the oxide film 230bf (to be the oxide 230a and the oxide 230b later) function as the channel formation region of the transistor 200. The transistor 200 formed using the insulating film 224f, the oxide film 230af, and the oxide film 230bf with reduced hydrogen concentrations is preferable because of its favorable reliability.

Next, a conductive film 242_1f is formed over the oxide film 230bf, and a conductive film 242_2f is formed over the conductive film 242_1f (see FIG. 7A to FIG. 7D). A conductor corresponding to the conductors 242a1 and 242b1 may be used for the conductive film 242_1f, and a conductor corresponding to the conductors 242a2 and 242b2 may be used for the conductive film 242_2f. After the formation of the oxide film 230bf, the conductive film 242_1f is formed over and in contact with the oxide film 230bf without performing an etching step or the like between the formation of the oxide film and the formation of the conductive film, whereby the top surface of the oxide film 230bf can be protected by the conductive film 242_1f. Thus, diffusion of impurities into the oxide 230 included in the transistor can be reduced, whereby the electrical characteristics and reliability of the semiconductor device can be improved.

The conductive film 242_1f and the conductive film 242_2f can each be formed by a sputtering method, a CVD method, an MBE method, a PLD method, or an ALD method, for example.

In this embodiment, by a sputtering method, a tantalum nitride film is deposited as the conductive film 242_1f, and a tungsten film is deposited for the conductive film 242_2f. Note that heat treatment may be performed before the formation of the conductive film 242_1f. This heat treatment may be performed under reduced pressure, and the conductive film 242_1f may be successively formed without exposure to the air. Such treatment can remove moisture and hydrogen adsorbed onto the surface of the oxide 230b, and further can reduce the moisture concentration and the hydrogen concentration in the oxide 230a and the oxide 230b. The heat treatment temperature is preferably higher than or equal to 100° C. and lower than or equal to 400° C. In this embodiment, the heat treatment is performed at 250° C.

Next, an insulating film 271f is deposited over the conductive film 242_1f (see FIG. 7A to FIG. 7D). The insulating film 271f can be formed by a sputtering method, a CVD method, an MBE method, a PLD method, or an ALD method, for example. As the insulating film 271f, an insulating film having a function of inhibiting passage of oxygen is preferably used. For example, as the insulating film 271f, a stacked film of a silicon nitride film and a silicon oxide film over the silicon nitride film may be deposited by a sputtering method.

Here, in the case where the insulating film 271f is formed by stacking films, the films are preferably formed successively without exposure to the air. By the film formation without exposure to the air, an interface between the stacked films of the insulating film 271f or the vicinity thereof can be kept clean. It is further preferable to form the components from conductive film 242_1f to the insulating film 271f successively without exposure to the air.

Note that heat treatment may be performed before the insulating film 271f is deposited. The heat treatment may be performed under reduced pressure, and the insulating film 271f may be successively formed without exposure to the air. Such treatment can remove moisture and hydrogen adsorbed onto the surface of the conductive film 242_1f and the conductive film 242_2f and can reduce the moisture concentrations and the hydrogen concentrations in the conductive film 242_1f and the conductive film 242_2f. The heat treatment temperature is preferably higher than or equal to 100° C. and lower than or equal to 400° C. In this embodiment, the heat treatment is performed at 250° C.

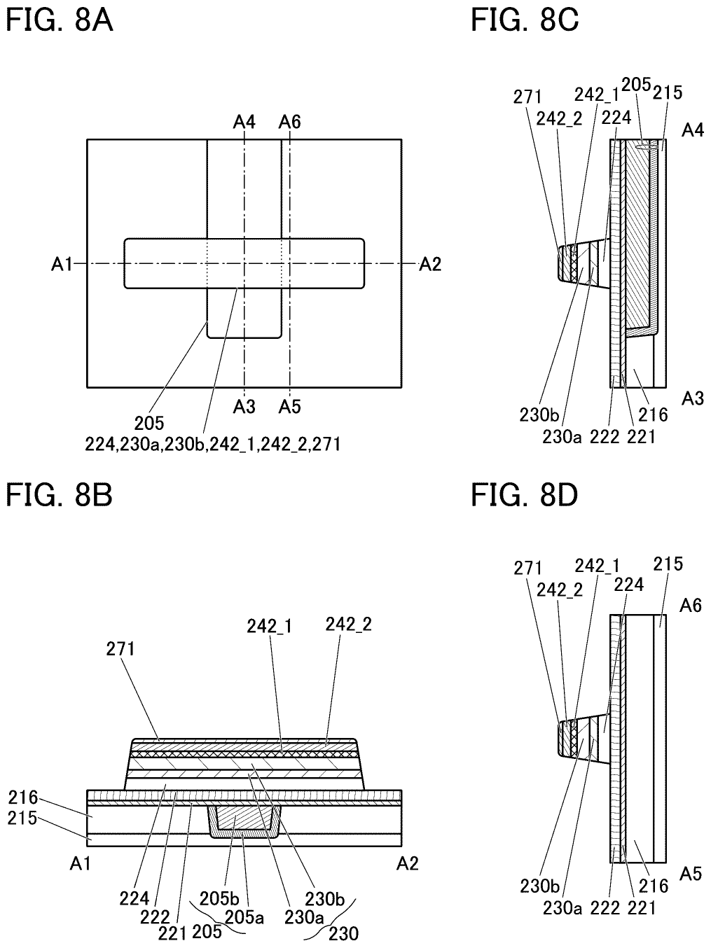

Subsequently, the insulating film 224f, the oxide film 230af, the oxide film 230bf, the conductive film 242_1f, the conductive film 242_2f, and the insulating film 271f are processed into an island shape by a lithography method to form the insulator 224, the oxide 230a, the oxide 230b, a conductor 242_1, a conductor 242_2, and an insulator 271 (see FIG. 8A to FIG. 8D).

A dry etching method or a wet etching method can be used for the processing. Processing by a dry etching method is suitable for microfabrication. The insulating film 224f, the oxide film 230af, the oxide film 230bf, the conductive film 242_1f, the conductive film 242_2f, and the insulating film 271f may be processed under different conditions.

Here, the insulator 224, the oxide 230a, the oxide 230b, the conductor 242_1, the conductor 242_2, and the insulator 271 are preferably processed into an island shape at a time. In that case, side end portions of the conductor 242_1 and side end portions of the conductor 242_2 are preferably aligned or substantially aligned with side end portions of the oxide 230a and the oxide 230b. Furthermore, it is preferable that side end portions of the insulator 224 be aligned or substantially aligned with the side end portions of the oxide 230. Moreover, it is preferable that the side end portion of the insulator 271 be aligned or substantially aligned with the side end portion of the conductor 242_2. With such a structure, the number of steps for the semiconductor device of one embodiment of the present invention can be reduced. Thus, a method for manufacturing a semiconductor device with high productivity can be provided.

The insulator 224, the oxide 230a, the oxide 230b, the conductor 242_1, the conductor 242_2, and the insulator 271 are formed to at least partly overlap with the conductor 205. The insulator 222 is exposed in a region not overlapping with the insulator 224, the oxide 230a, the oxide 230b, the conductor 242_1, the conductor 242_2, and the insulator 271.

As illustrated in FIG. 8B, the side surfaces of the insulator 224, the oxide 230a, the oxide 230b, the conductor 242_1, the conductor 242_2, and the insulator 271 may have tapered shapes. The taper angles of the side surfaces of the insulator 224, the oxide 230a, the oxide 230b, the conductor 242_1, the conductor 242_2, and the insulator 271 may be greater than or equal to 60° and less than 90°, for example. With such tapered shapes of the side surfaces, the coverage with the insulator 275 and the like can be improved in a later step, so that defects such as voids can be reduced.

Not being limited to the above, the insulator 224, the oxide 230a, the oxide 230b, the conductor 242_1, the conductor 242_2, and the insulator 271 may have side surfaces that are perpendicular or substantially perpendicular to the top surface of the insulator 222. With such a structure, a plurality of transistors can be provided with high density in a small area.

Note that in a lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask can be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that the use of a mask may be unnecessary in the case of using an electron beam or an ion beam.

Note that the resist mask that is no longer needed after the processing can be removed by dry etching treatment such as ashing using oxygen plasma (hereinafter, referred to oxygen plasma treatment in some cases) or the like, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the insulating film 271f, a resist mask is formed thereover, and then the hard mask material is etched. The etching of the insulating film 271f and the like may be performed after removing the resist mask or with the resist mask remaining. In the latter case, the resist mask sometimes disappears during the etching. The hard mask may be removed by etching after the etching of the oxide film 230bf and the like. Meanwhile, the hard mask is not necessarily removed when the hard mask material does not affect later steps or can be utilized in later steps.

A spin on carbon (SOC) film and a spin on glass (SOG) film may be formed between an object to be processed and the resist mask. Using the SOC film and the SOG film as masks can improve the adhesion between the object to be processed and the resist mask, resulting in enhancement of the durability of a mask pattern. For example, the SOC film, the SOG film, and the resist mask are formed in this order over the object to be processed and lithography can be performed.

An etching gas including a halogen can be used as an etching gas for dry etching treatment; specifically, an etching gas including one or more of fluorine, chlorine, and bromine can be used. As the etching gas, for example, a C₄F₆ gas, a C₅F₆ gas, a C₄F₈ gas, a CF₄ gas, a SF₆ gas, a CHF₃ gas, a CH₂F₂ gas, a Cl₂ gas, a BCl₃ gas, a SiCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. Depending on an object to be subjected to the dry etching treatment, a gas that contains a hydrocarbon gas or a hydrogen gas and does not contain a halogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example. The etching apparatus can be set as appropriate depending on an object to be etched.

In the above etching process, the insulator 271 can function as an etching stopper that protects the conductor 242_2. For example, a metallic hard mask over the insulator 271 in the above etching process makes it difficult to obtain the etching selectivity of the hard mask to the conductor 242_2 at the time of removing the hard mask in some cases. However, when the insulator 271 is formed over the conductor 242_2, the insulator 271 can function as an etching stopper that protects the conductor 242_2 in the etching for removing the hard mask. This can prevent formation of a curved surface between the side surface and a top surface of the conductor 242_2, and the end portion at the intersection of the side surface and the top surface of each of the conductor 242a2 and the conductor 242b2 to be formed later is angular. The cross-sectional area of the conductor 242_2 having an angular end portion at the intersection of the side surface and the top surface is larger than that in the case where the end portion is rounded. Furthermore, when a nitride insulator that is less likely to oxidize a metal is used for the insulator 271, excessive oxidation of the conductor 242_2 can be prevented. Accordingly, the resistance of the conductor 242a2 and the conductor 242b2 is reduced, so that the on-state current of the transistor can be increased.

By processing the insulator 224 into an island shape, the insulator 275 can be provided in contact with the side surface of the insulator 224 and the top surface of the insulator 222 in a step to be described later. That is, the insulator 224 can be isolated from the insulator 280 by the insulator 275. Such a structure can prevent an excess amount of oxygen and impurities such as hydrogen from entering the oxide 230 from the insulator 280 through the insulator 224.

In the case where a plurality of the transistors 200 are provided by processing the insulator 224 into an island shape, the processed insulators 224 have substantially the same size as each other and are provided in the respective transistors 200. Accordingly, among the transistors 200, the amount of oxygen supplied from the insulator 224 to the oxide 230 is substantially the same. This can reduce variations in electrical characteristics of the transistors 200 in the substrate plane. Note that the structure is not limited to this, and it is possible not to pattern the insulator 224 as in the case of the insulator 222.

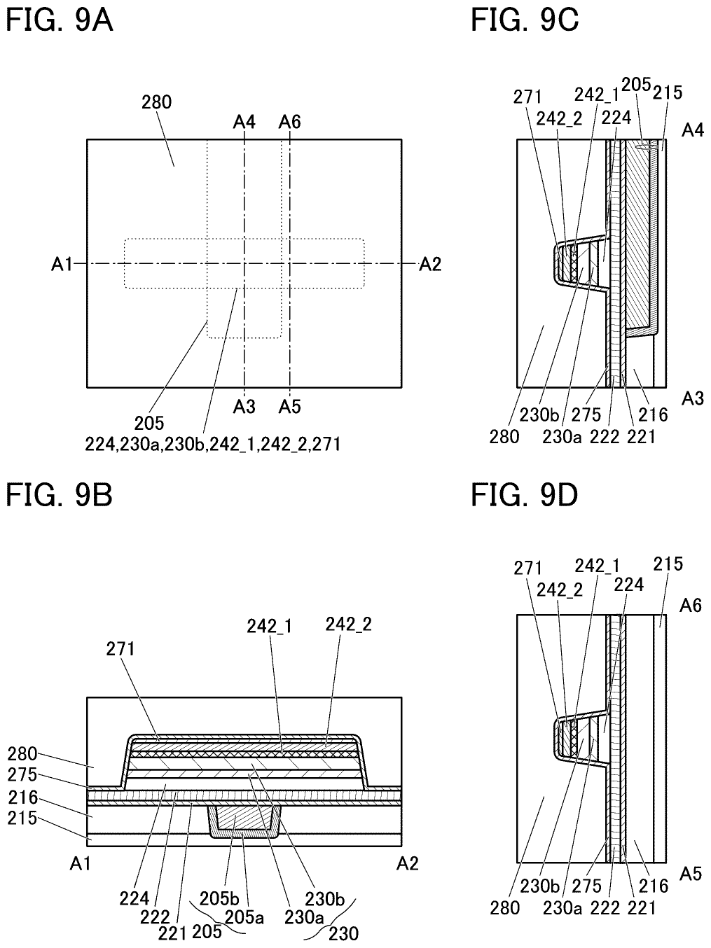

Next, the insulator 275 is formed to cover the insulator 224, the oxide 230a, the oxide 230b, the conductor 242_1, the conductor 242_2, and the insulator 271, and the insulator 280 is formed over the insulator 275 (see FIG. 9A to FIG. 9D). The above-described insulators can be used for the insulator 275 and the insulator 280.

Here, it is preferable that the insulator 275 be in contact with the top surface of the insulator 222.

As the insulator 280, an insulator having a flat top surface is preferably formed by forming an insulating film to be the insulator 280 and then performing CMP treatment on the insulating film. Note that, for example, silicon nitride may be deposited over the insulator 280 by a sputtering method and CMP treatment may be performed on the silicon nitride until the insulator 280 is reached.

The insulator 275 and the insulator 280 can each be deposited by a sputtering method, a CVD method, an MBE method, a PLD method, or an ALD method, for example.

For the insulator 275, an insulator having a function of inhibiting passage of oxygen is preferably used. For example, for the insulator 275, silicon nitride is preferably deposited by a PEALD method. Alternatively, for the insulator 275, it is preferable that aluminum oxide be deposited by a sputtering method and silicon nitride be deposited thereover by a PEALD method. When the insulator 275 has the above-described structure, the function of inhibiting diffusion of oxygen and impurities such as water or hydrogen can be improved.

In this manner, the oxide 230a, the oxide 230b, the conductor 242_1, and the conductor 242_2 can be covered with the insulator 275, which has a function of inhibiting diffusion of oxygen. This can suppress direct diffusion of oxygen from the insulator 280 or the like into the insulator 224, the oxide 230a, the oxide 230b, the conductor 242_1, and the conductor 242_2 in a later step.

For the insulator 280, silicon oxide is preferably deposited by a sputtering method. When the insulating film to be the insulator 280 is formed by a sputtering method in an oxygen-containing atmosphere, the insulator 280 containing excess oxygen can be formed. By using a sputtering method that does not need to use a molecule containing hydrogen as a deposition gas, the hydrogen concentration in the insulator 280 can be reduced. Note that heat treatment may be performed before the formation of the insulating film. The heat treatment may be performed under reduced pressure, and the insulating film may be successively deposited without exposure to the air. Such treatment can remove moisture and hydrogen adsorbed onto the surface of the insulator 275 and the like, and further can reduce the moisture concentrations and the hydrogen concentrations in the oxide 230a, the oxide 230b, and the insulator 224. For the heat treatment, the above heat treatment conditions can be used.

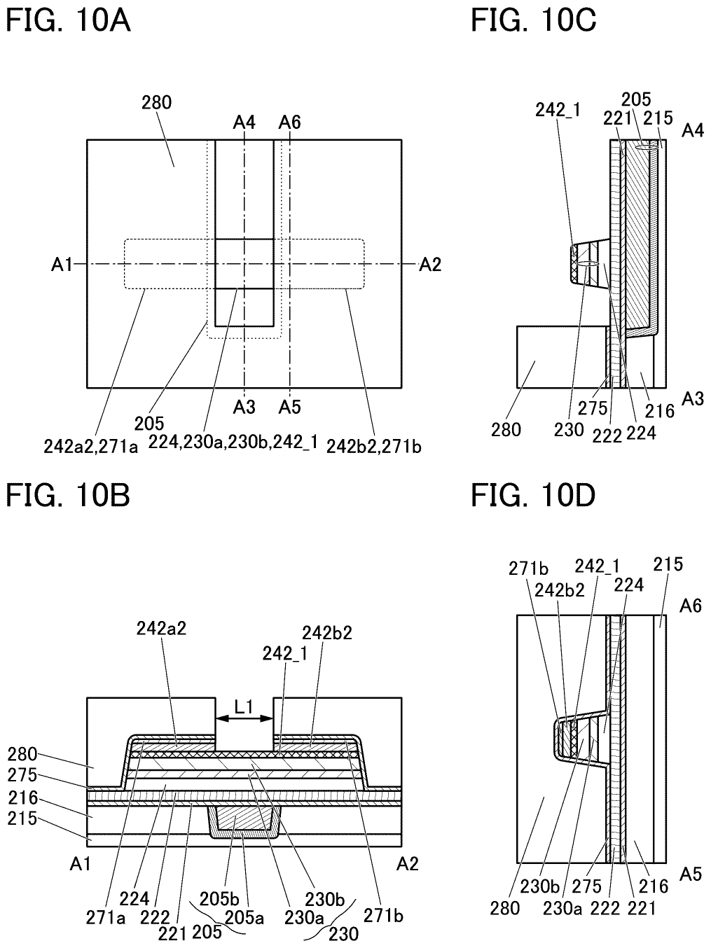

Next, the conductor 242_2, the insulator 271, the insulator 275, and the insulator 280 are processed by a lithography method, thereby forming an opening reaching the conductor 242_1 and the insulator 222 (see FIG. 10A to FIG. 10D). Here, the conductor 242_2 is divided into the conductor 242a2 and the conductor 242b2 and the insulator 271 is divided into the insulator 271a and the insulator 271b. The opening reaching the conductor 242_1 is formed in a region where the oxide 230b and the conductor 205 overlap with each other. In the cross-sectional view of the transistor 200 in the channel length direction, the opening has a width L1, which corresponds to the distance L1 between the conductor 242a2 and the conductor 242b2 illustrated in FIG. 2B. That is, the width of the opening is larger than the distance L2 between the conductors 242a1 and 242b1 illustrated in FIG. 2B.

The above-described method can be used as appropriate as the lithography method. In order to process the opening in the insulator 280 minutely, a lithography method using an electron beam or short-wavelength light such as EUV light is preferably employed.

For example, the SOC film, the SOG film, and the resist mask are formed in this order over the insulator 280 and lithography can be performed. A resist mask having an opening is formed using an electron beam or short-wavelength light such as EUV light, and the SOG film, the SOC film, the insulator 280, the insulator 275, the insulator 271, and the conductor 242_2 are processed with use of the resist mask.

Furthermore, the above processing is preferably performed by a dry etching method. A dry etching method enables anisotropic etching and thus is suitable for forming an opening with a high aspect ratio and the width L1 illustrated in FIG. 2B. Note that the above description can be referred to for the conditions and an apparatus for the dry etching method. Etching treatment of the SOG film, the SOC film, the insulator 280, the insulator 275, the insulator 271, and the conductor 242_2 may be performed under different conditions.

In the etching of the SOG film, CF₄ can be used for an etching gas, for example. In the etching of the SOC film, H₂ and N₂ can be used as an etching gas, for example. For example, in the case where a silicon oxide film is used as the insulator 280, C₄F₈, C₄F₆, O₂, and Ar can be used as an etching gas. For example, in the case where silicon nitride is used as the insulator 275, CH₂F₂, O₂, and Ar can be used as an etching gas. In the case where a stacked film of silicon nitride and silicon oxide is used for the insulator 271, etching treatment can be performed with an ICP etching apparatus using CHF₃ and O₂ as an etching gas, for example.

In the case where tungsten is used for the conductor 242_2 and tantalum nitride is used for the conductor 242_1, etching treatment can be performed with an ICP etching apparatus using CF₄, Cl₂, and O₂ as an etching gas, for example. Here, since the conductor 242_2 overlapping with the opening with the width L1 formed in the insulator 280 and the like is etched, the distance between the divided conductors 242a2 and 242b2 becomes L1. Note that when the side surfaces of the conductor 242a2 and the conductor 242b2 are side-etched in the etching, a recess is formed on each of the side surfaces of the conductor 242a2 and the conductor 242b2 as illustrated in FIG. 5B.

This etching treatment needs to be stopped when the opening reaches the top surface of the conductor 242_1 in order that the conductor 242a1 and the conductor 242b1 between which the distance is L2 are formed under the conductor 242a2 and the conductor 242b2 in a later step. Therefore, in this step, etching treatment is performed with an ICP etching apparatus under a condition that the etching rate of the conductor 242_2 with respect to the etching rate of the conductor 242_1 (hereinafter referred to as etching selectivity of the conductor 242_2) is high.

When bias power applied to a lower electrode of the ICP etching apparatus is set low, ion incident energy can be reduced and the etching rate of the conductor 242_1 can be reduced. For example, the bias power applied to the lower electrode of the ICP etching apparatus is set lower than 50 W, preferably approximately 25 W or lower than or equal to 25 W. However, the present invention is not limited thereto, and the bias power applied to the lower electrode of the ICP etching apparatus can be set higher than or equal to 50 W. When the bias power is high, the recession formed on the side surfaces of the conductors 242a2 and 242b2 can be small. In that case, the bias power is set to 100 W, for example.

When CF₄, Cl₂, and O₂ are used as an etching gas, tungsten of the conductor 242_2 becomes a reaction product with high volatility, such as WF₆ or WOCl, and the etching rate of the conductor 242_2 is increased. In contrast, tantalum nitride on the surface of the conductor 242_1 becomes a reaction product with extremely low volatility, such as tantalum oxide or tantalum oxynitride, and etching is suppressed. Therefore, the flow rate ratio of an oxygen gas in the etching gas is preferably high. For example, the flow rate ratio of an oxygen gas in the etching gas is set to higher than 35%, preferably approximately 48% or higher than or equal to 48%.

The etching of the conductor 242_2 is performed under the above conditions; thus, the conductor 242_2 can be divided into the conductor 242a2 and the conductor 242b2 without excessive etching of the conductor 242_1. Accordingly, processing can be performed as designed even in a semiconductor device with a minute structure.

Note that the SOC film may be removed by performing dry etching treatment such as ashing with oxygen plasma, wet etching treatment, wet etching treatment after dry etching treatment, or dry etching treatment after wet etching treatment.

The processing of the insulator 271 and the conductor 242_2 and removal of the SOC film can be performed successively without exposure to the air. For example, the processing is performed without exposure to the air by using a multi-chamber etching apparatus.

In the above manner, the conductor 242_2, the insulator 271, the insulator 275, and the insulator 280 are processed to form the opening with the width L1.

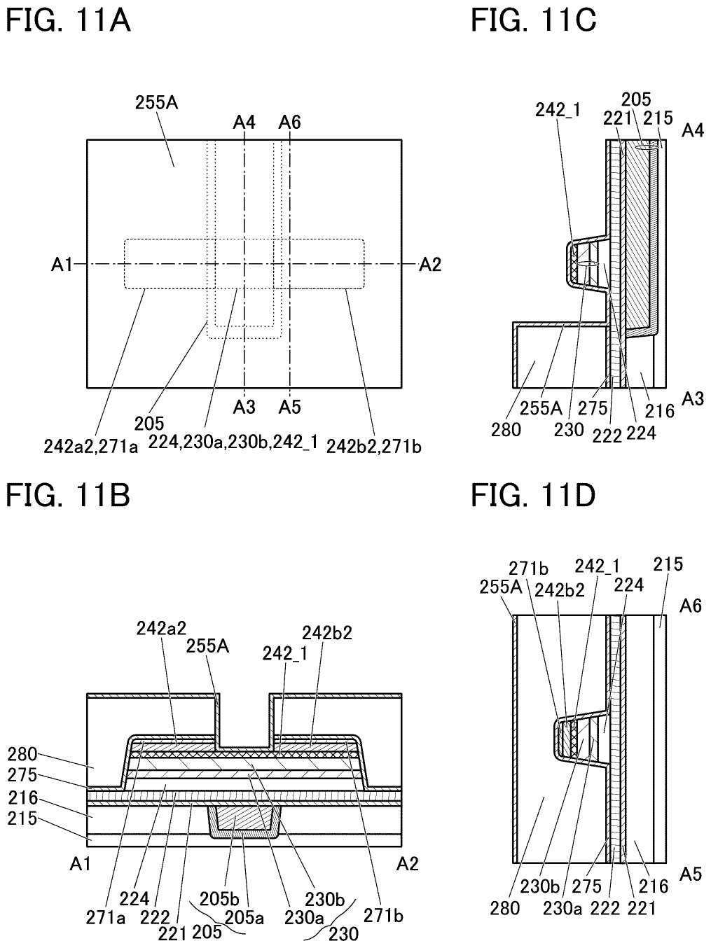

Next, an insulating film 255A is formed to cover the insulator 280, the conductor 242_1, and the insulator 222 (see FIGS. 11A to 11D). The insulating film 255A is an insulating film to be the insulator 255 in a later step, and the insulator described above can be used, for example. The insulating film 255A can be formed by a sputtering method, a CVD method, an MBE method, a PLD method, or an ALD method, for example.

The insulating film 255A preferably has good coverage because the insulating film 255A is formed along the opening formed in the conductor 242a2, the conductor 242b2, the insulator 271, the insulator 275, and the insulator 280. Thus, the insulating film 255A is preferably deposited by a deposition method providing good coverage, such as an ALD method. For example, for the insulating film 255A, silicon nitride is preferably deposited by a PEALD method.

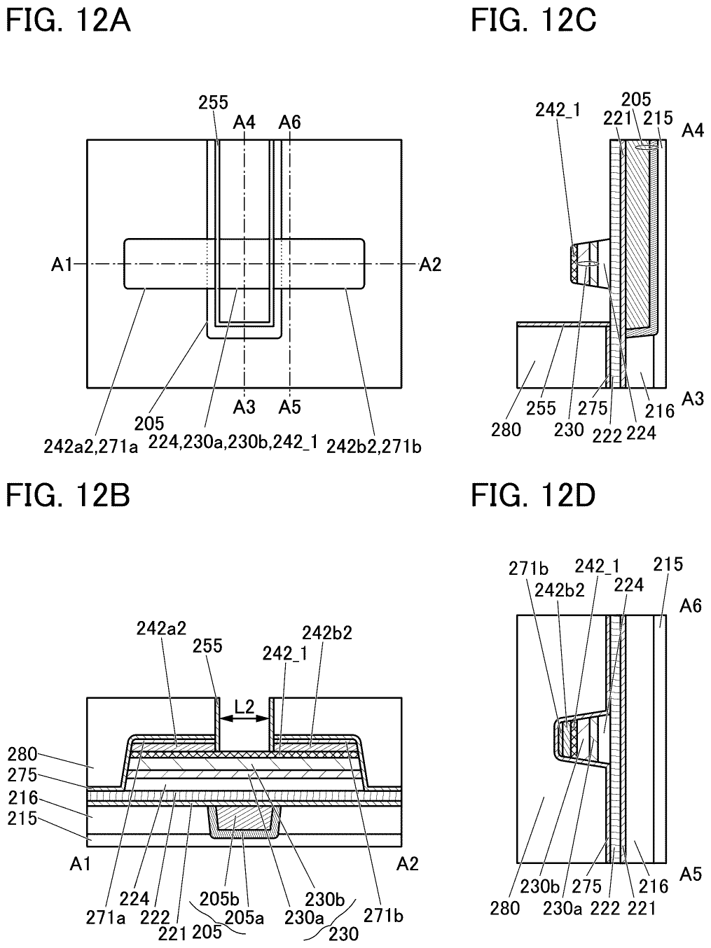

Next, part of the insulating film 255A is removed by anisotropic etching, so that the insulator 255 in a sidewall shape is formed in contact with the sidewall of the opening (see FIG. 12A to FIG. 12D). Thus, the insulator 255 is formed in contact with the side surfaces of the insulator 280, the insulator 275, the insulator 271a, the insulator 271b, the conductor 242a2, and the conductor 242b2, and the top surfaces of the conductor 242_1 and the insulator 222. In a cross-sectional view in the channel length direction, since the insulator 255 is formed in the opening with the width L1, the distance between the insulator 255 on the A1 side and the insulator 255 on the A2 side, which is regarded as L2, is shorter than L1. Here, the difference between L1 and L2 is equal to or substantially equal to as twice the thickness of the insulator 255.

A dry etching method is preferably employed for the anisotropic etching. Note that the above description can be referred to for the conditions and an apparatus for the dry etching method. In the case where silicon nitride is used for the insulating film 255A, etching treatment can be performed with an ICP etching apparatus using CHF₃ and O₂ as an etching gas, for example.

In the etching of the insulating film 255A, the generated ions may collide with a corner portion of an edge of the opening of the insulator 280 and the insulator 255. Thus, as illustrated in FIG. 4C, the corner is polished to have a tapered shape in some cases. The corner portion is relatively easily removed when a gas that is easily ionized, such as argon, is contained in the etching gas or a bias voltage is applied to an electrode on the substrate side, for example.

In the case where the recess is formed on each of the side surfaces of the conductor 242a1 and the conductor 242b1 as illustrated in FIG. 5B, the insulator 255 may be formed to fill the recess. At this time, the thickness of the insulator 255 becomes large in the vicinity of the side surface of the conductor 242a1 and the side surface of the conductor 242b1, so that oxidation of the side surface of the conductor 242a1 and the side surface of the conductor 242b1 can be further inhibited.

In that case, as illustrated in FIG. 13A, in the cross-sectional view in the channel width direction, a part of the insulator 255 is formed in contact with the side surface of the insulator 224, the side surface of the oxide 230, the side surface of the conductor 242_1, and the top surface of the insulator 222 in some cases. In this case, as illustrated in FIG. 13B, in the transistor 200, the part of the insulator 255 is formed in contact with the side surface of the oxide 230 and the side surface of the insulator 224 in some cases. At this time, in the transistor 200, the insulator 250 is in contact with neither the side surface of the oxide 230 nor the side surface of the insulator 224.

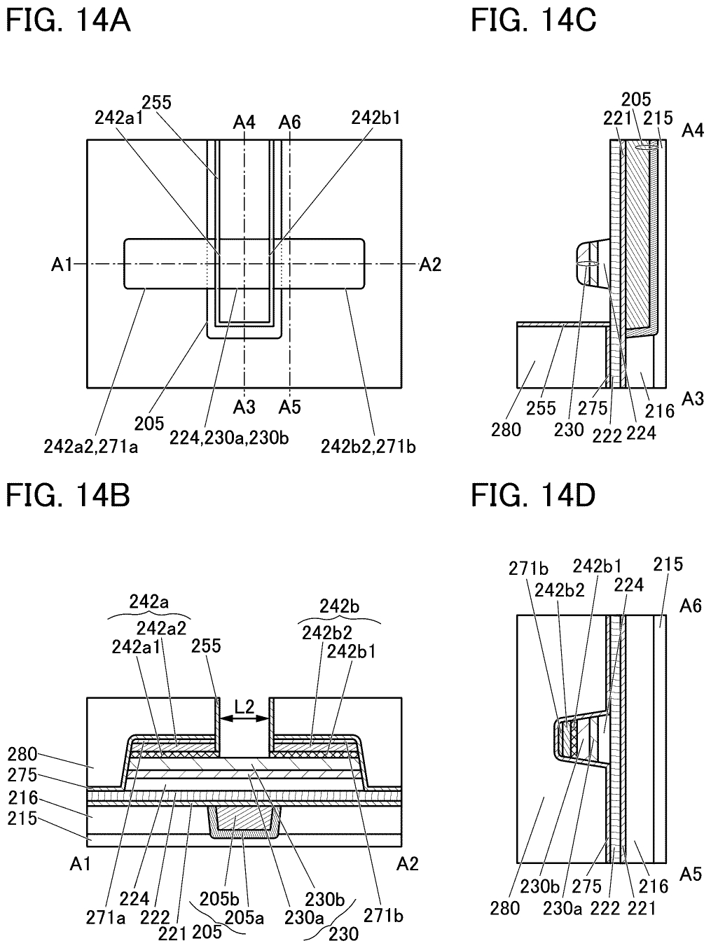

Subsequently, the conductor 242_1 exposed from the insulator 255 is removed by anisotropic etching to form the conductors 242a1 and 242b1 (see FIGS. 14A to 14D). In other words, the conductor 242_1 is processed using the insulator 255 as a mask, whereby the conductor 242_1 is divided into the conductor 242a1 and the conductor 242b1. When the conductor 242_1 is processed by anisotropic etching, side etching of the insulator 255 can be inhibited. By processing the conductor 242_1 using the insulator 255 as a mask in this manner, in a cross-sectional view of the transistor 200, the side end portion of the insulator 255 is aligned or substantially aligned with the side end portions of the conductor 242a1 and the conductor 242b1. Thus, in the cross-sectional view in the channel length direction, the distance between the conductor 242a1 and the conductor 242b1 also becomes L2. L2 is shorter than L1, and a difference between L1 and L2 is equal to or substantially equal to twice the thickness of the insulator 255.

A dry etching method is preferably employed for the anisotropic etching. Note that the above description can be referred to for the conditions and an apparatus for the dry etching method. In the case where tantalum nitride is used for the conductor 242_1, etching treatment can be performed with an ICP etching apparatus using Cl₂ and Ar as an etching gas, for example.

As described above, the insulator 255 is formed over the conductor 242_1 by anisotropic etching, and the conductor 242_1 is divided using the insulator 255 as a mask, whereby the insulator 255 which functions as a mask can be formed in a self-aligned manner. Accordingly, the numbers of masks and steps can be reduced in the process of manufacturing the semiconductor device of this embodiment. Thus, a method for manufacturing a semiconductor device with high productivity can be provided.

By the above method, the opportunity for exposure of the island-shaped oxide 230 to a dry etching atmosphere can be only during the processing of the conductor 242_1. In other words, at the time of forming the insulator 255, exposure of the top surface of the island-shaped oxide 230 to a dry etching atmosphere can be prevented. This can reduce dry etching damage (e.g., damage due to ion collision) to the oxide 230b functioning as the channel formation region of the transistor 200. By reducing the bias power from the middle of the dry etching of the conductor 242_1, damage to the oxide 230 can be further reduced. However, as illustrated in FIG. 4A, a depression is formed in a portion of the oxide 230 exposed from the conductors 242a1 and 242b1 in some cases.

Note that ashing treatment using oxygen plasma may be performed after the processing of the conductor 242_1. Such oxygen plasma treatment can remove impurities generated by the etching and diffusing into the oxide 230 or the like. The impurities are generated from a component of the object processed by the above etching treatment and a component contained in a gas or the like used for the etching. Examples of the impurities include chlorine, fluorine, tantalum, silicon, and hafnium. In particular, when a chlorine gas is used in the processing of the conductor 242_1 as in the above-described etching, the oxide 230 is exposed to the atmosphere containing the chlorine gas, in which case chlorine attached to the oxide 230 is preferably removed. Removal of impurities attached to the oxide 230 in this manner can improve the electrical characteristics and reliability of the transistor.

At least a part of the insulator 255 might be oxidized by the oxygen plasma treatment. In other words, the insulator 255 might contain oxygen. In that case, a region of the insulator 255 which has a high oxygen concentration is observed through composition analysis performed on the insulator 255 by SIMS or the like. After oxidation of the insulator 255 proceeds and the transistor 200 is formed, at least a part of the insulator 255 becomes silicon oxynitride or silicon nitride oxide in some cases.

The processing of the insulating film 255A and the conductor 242_1 and the oxygen plasma treatment can be performed successively without exposure to the air. For example, the processing is performed without exposure to the air by using a multi-chamber etching apparatus.

In the above manner, the conductors 242a1 and 242b1 having oxidation resistance can be formed below the conductors 242a2 and 242b2 having high conductivity, and the insulator 255 having oxidation resistance can be formed in contact with the side surfaces of the conductors 242a2 and 242b2. With this structure, the conductors 242a2 and 242b2 having high conductivity can be used as the source electrode and the drain electrode of the transistor 200, so that frequency characteristics of the transistor 200 and operation speed of the semiconductor device can be improved.

In order to remove impurities and the like attached to the surface of the oxide 230b in the above etching step, cleaning treatment may be performed. Examples of the cleaning method include wet cleaning using a cleaning solution or the like (which can also be referred to as wet etching treatment), plasma treatment using plasma, and cleaning by heat treatment, and any of these cleanings may be performed in appropriate combination. Note that the cleaning treatment sometimes makes the groove portion deeper.

The wet cleaning may be performed using an aqueous solution in which one or more of ammonia water, oxalic acid, phosphoric acid, and hydrofluoric acid is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the oxide 230b and the like can be reduced with such a frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning using diluted ammonia water is performed. The cleaning treatment can remove impurities that are attached onto the surfaces of the oxide 230a, the oxide 230b, and the like or diffused into the oxide 230a, the oxide 230b, and the like. Furthermore, the crystallinity of the oxide 230a, the oxide 230b, or the like can be increased.

After the etching or the cleaning, heat treatment is preferably performed. The temperature of the heat treatment is preferably higher than or equal to 100° C., higher than or equal to 250° C., or higher than or equal to 350° C. and lower than or equal to 650° C., lower than or equal to 600° C., lower than or equal to 550° C., or lower than or equal to 400° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, it is preferable that the flow rate ratio of a nitrogen gas to an oxygen gas be 4:1 and the heat treatment be performed at a temperature of 350° C. for one hour. Accordingly, oxygen can be supplied to the oxide 230a and the oxide 230b to reduce oxygen vacancies. In addition, the crystallinity of the oxide 230b can be improved by such heat treatment. Furthermore, hydrogen remaining in the oxide 230a and the oxide 230b reacts with supplied oxygen, so that the hydrogen can be removed as H₂O (dehydration). This can inhibit recombination of hydrogen remaining in the oxide 230a and the oxide 230b with oxygen vacancies and formation of VoH. Accordingly, the transistor including the oxide 230 can have favorable electrical characteristics and higher reliability. In addition, variations in electrical characteristics of transistors formed over the same substrate can be reduced. Note that the heat treatment may be performed under reduced pressure. Alternatively, heat treatment may be performed in an oxygen atmosphere, and then heat treatment may be successively performed in a nitrogen atmosphere without exposure to the air.

Here, as described above, the insulator 255, which includes an inorganic insulator that is less likely to be oxidized, is in contact with the side surface of the conductor 242a2 and the side surface of the conductor 242b2. This can prevent the conductors 242a2 and 242b2 from being excessively oxidized by the heat treatment even when a tungsten film or the like that is relatively easily oxidized is used for the conductors 242a2 and 242b2.

In the case where heat treatment is performed in the state where the conductor 242a and the conductor 242b are in contact with the oxide 230b, the sheet resistance of the oxide 230b in a region overlapping with the conductor 242a and a region overlapping with the conductor 242b is decreased in some cases. Furthermore, the carrier concentration is sometimes increased. Thus, the resistance of the oxide 230b in the region overlapping with the conductor 242a and the region overlapping with the conductor 242b can be lowered in a self-aligned manner.

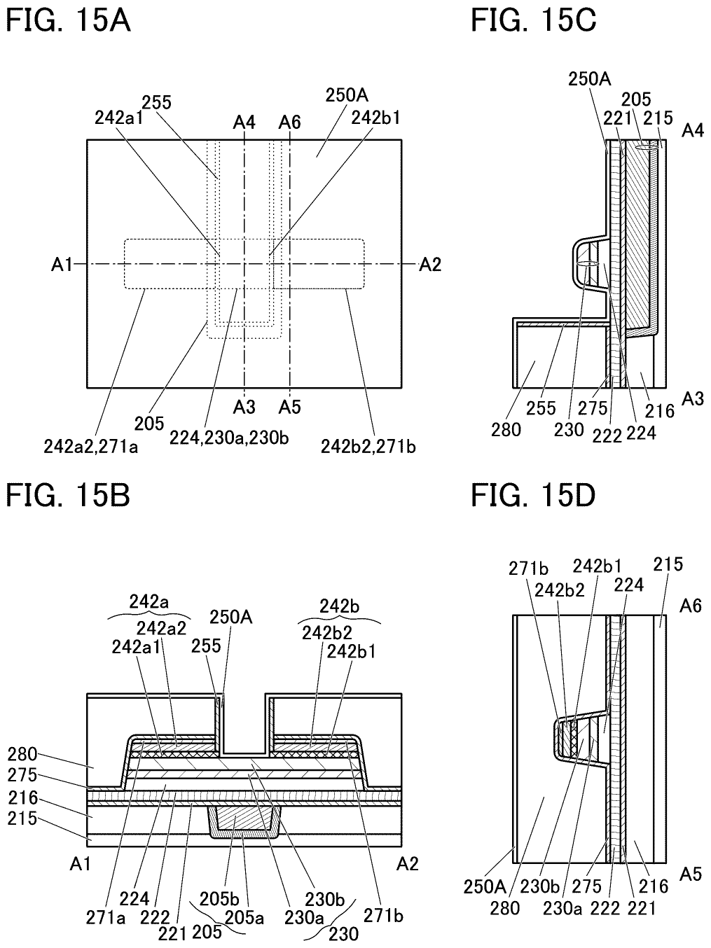

Then, an insulating film 250A to be the insulator 250 is formed to fill the opening formed in the insulator 280 and the like (see FIG. 15A to FIG. 15D). Here, the insulating film 250A is in contact with the insulator 280, the insulator 255, the conductor 242a1, the conductor 242b1, the insulator 222, the insulator 224, the oxide 230a, and the oxide 230b.

The insulating film 250A can be formed by a sputtering method, a CVD method, an MBE method, a PLD method, an ALD method, or the like. The insulating film 250A is preferably deposited by an ALD method, for example. Like the insulator 250 described above, the insulating film 250A is preferably formed to have a small thickness, and a variation in the film thickness needs to be reduced. Since an ALD method is a deposition method in which a precursor and a reactant (e.g., oxidizer) are alternately introduced and the film thickness can be adjusted with the number of repetition times of the cycle, accurate control of the film thickness is possible. Furthermore, the insulator film 250A needs to be formed to favorably cover the bottom surface and the side surface of the opening. By an ALD method, atomic layers can be deposited one by one on the bottom surface and the side surface of the opening, whereby the insulator film 250A can be formed in the opening with good coverage.

In the case where the insulating film 250A is formed by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the oxide 230b can be reduced.

The insulator 250 can have a stacked-layer structure as illustrated in FIG. 2A and the like. A method of forming the insulating film 250A in the case where the insulator 250 has a three-layer structure of an insulator 250a, an insulator 250b, and an insulator 250c as in FIG. 2A will be described below with reference to FIG. 16A to FIG. 16C. The insulating film 250A in FIG. 16A to FIG. 16C includes an insulating film 250Aa, an insulating film 250Ab over the insulating film 250Aa, and an insulating film 250Ac over the insulating film 250Ab.

First, the insulating film 250Aa to be the insulator 250a is formed to fill the opening formed in the insulator 280 and the like, and the insulating film 250Ab is formed over the insulating film 250Aa (see FIG. 16A). In this embodiment, aluminum oxide is deposited for the insulating film 250Aa by a thermal ALD method and silicon oxide is deposited for the insulating film 250Ab by a PEALD method.

Next, it is preferable to perform microwave treatment in an atmosphere containing oxygen (see FIG. 16B). Here, the microwave treatment refers to, for example, treatment using an apparatus including a power source that generates high-density plasma with use of a microwave. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is preferably set to greater than or equal to 300 MHz and less than or equal to 300 GHz, further preferably greater than or equal to 2.4 GHz and less than or equal to 2.5 GHz, and can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 230b efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably set to lower than or equal to 750° C., further preferably lower than or equal to 500° C., and can be approximately 250° C., for example. The oxygen plasma treatment may be followed successively by heat treatment without exposure to the air. The temperature of the heat treatment is preferably higher than or equal to 100° C. and lower than or equal to 750° C., further preferably higher than or equal to 300° C. and lower than or equal to 500° C., for example.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (02/(02+Ar)) is further preferably higher than or equal to 10% and lower than or equal to 40%. The oxygen flow rate ratio (O₂/(O₂+Ar)) is still further preferably higher than or equal to 10% and lower than or equal to 30%. The carrier concentration in the oxide 230b can be reduced by thus performing the microwave treatment in an oxygen-containing atmosphere. In addition, the carrier concentrations in the oxide 230b can be prevented from being excessively reduced by preventing an excess amount of oxygen from being introduced into the chamber in the microwave treatment.

The microwave treatment in an oxygen-containing atmosphere can convert an oxygen gas into plasma using a high-frequency wave such as a microwave or RF, and apply the oxygen plasma to a region of the oxide 230b which is between the conductor 242a and the conductor 242b. By the effect of the plasma, the microwave, or the like, VoH in the region can be divided into an oxygen vacancy and hydrogen, and hydrogen can be removed from the region. Here, in the case of employing the structure illustrated in FIG. 2A and the like, an insulating film having a function of capturing and fixing hydrogen (e.g., aluminum oxide) is preferably used as the insulating film 250Aa. With such a structure, hydrogen generated by the microwave treatment can be captured or fixed in the insulating film 250Aa. Accordingly, VoH contained in the channel formation region can be reduced. In the above manner, oxygen vacancies and VoH in the channel formation region can be reduced to lower the carrier concentration. In addition, oxygen radicals generated by the oxygen plasma can be supplied to oxygen vacancies in the channel formation region, thereby further reducing oxygen vacancies in the channel formation region and lowering the carrier concentration.

The oxygen implanted into the channel formation region has any of a variety of forms such as an oxygen atom, an oxygen molecule, an oxygen ion, and an oxygen radical (also referred to as O radical, which is an atom, a molecule, or an ion having an unpaired electron). Note that the oxygen implanted into the channel formation region has any one or more of the above forms, particularly suitably an oxygen radical. Furthermore, the film quality of the insulator 250 can be improved, leading to higher reliability of the transistor.

Meanwhile, the oxide 230b includes a region overlapping with the conductor 242a or 242b. The region can function as a source region or a drain region. Here, the conductors 242a and 242b preferably function as blocking films preventing the effect caused by the high-frequency wave such as a microwave or RF, the oxygen plasma, or the like in the microwave treatment in an oxygen-containing atmosphere. Therefore, the conductors 242a and 242b preferably have a function of blocking an electromagnetic wave greater than or equal to 300 MHz and less than or equal to 300 GHz, for example, greater than or equal to 2.4 GHz and less than or equal to 2.5 GHz.

The effect of the high-frequency wave such as a microwave or RF, the oxygen plasma, or the like is blocked by the conductors 242a and 242b and does not affect the region of the oxide 230b overlapping with the conductor 242a or 242b. Hence, a reduction in VoH and supply of an excess amount of oxygen do not occur in the source region and the drain region in the microwave treatment, preventing a decrease in carrier concentration.

The insulator 255 having a barrier property against oxygen is provided in contact with the side surfaces of the conductors 242a and 242b. The insulating film 250Aa and the insulating film 250Ab are provided to cover the conductors 242a1 and 242b1 and the insulator 255. This can inhibit formation of oxide films on the side surfaces of the conductors 242a and 242b by the microwave treatment.

In the above manner, oxygen vacancies and VoH can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited, and the conductivity (the state of the low-resistance regions) before the microwave treatment is performed can be maintained. As a result, a change in the electrical characteristics of the transistor can be inhibited, and thus a variation in the electrical characteristics of transistors in the substrate plane can be inhibited.

In the microwave treatment, thermal energy is directly transmitted to the oxide 230b in some cases owing to an electromagnetic interaction between the microwave and a molecule in the oxide 230b. The oxide 230b may be heated by this thermal energy. Such heat treatment is sometimes referred to as microwave annealing. When microwave treatment is performed in an oxygen-containing atmosphere, an effect equivalent to that of oxygen annealing is sometimes obtained. In the case where hydrogen is contained in the oxide 230b, it is probable that the thermal energy is transmitted to the hydrogen in the oxide 230b and the hydrogen activated by the energy is released from the oxide 230b.

Furthermore, the microwave treatment improves the film quality of the insulating film 250Aa and the insulating film 250Ab, thereby inhibiting diffusion of hydrogen, water, impurities, and the like. Accordingly, hydrogen, water, impurities, and the like can be inhibited from diffusing into the oxide 230b, the oxide 230a, and the like through the insulator 250 in a later step such as formation of a conductive film to be the conductor 260 or later treatment such as heat treatment. By thus improving the film quality of the insulator 250, the reliability of the transistor can be improved.

Next, an insulating film 250Ac is formed over the insulating film 250Ab (see FIG. 16C). In this embodiment, silicon nitride is deposited for the insulating film 250Ac by a PEALD method. In this manner, the insulating film 250A including the insulating films 250Aa to 250Ac can be formed.

Although an example in which microwave treatment is performed after the formation of the insulating film 250Ab is described above, the present invention is not limited to this example. After the formation of the insulating film 250Ac, the microwave treatment can be performed. Alternatively, before the formation of the insulating film 250Aa, the microwave treatment can be performed.

After the microwave treatment, heat treatment may be performed with the reduced pressure being maintained. Such treatment enables hydrogen in the insulating film, the oxide 230b, and the oxide 230a to be removed efficiently. Part of hydrogen is gettered by the conductors 242a and 242b in some cases. Alternatively, the step of performing microwave treatment and then performing heat treatment with the reduced pressure being maintained may be repeated a plurality of cycles. The repetition of the heat treatment enables hydrogen in the insulating film, the oxide 230b, and the oxide 230a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 230b and the like are adequately heated by the microwave annealing.

In the case where the insulator 250 has a stacked-layer structure of the insulator 250a and the insulator 250c as illustrated in FIG. 3A, the insulating film 250Ab is not formed in the above process. In the case where the insulator 250 has a stacked-layer structure of the insulator 250a, the insulator 250b, the insulator 250c, and the insulator 250d as illustrated in FIG. 3B, the following steps may be performed: an insulating film to be the insulator 250d is formed after the microwave treatment in FIG. 16B, the microwave treatment is performed again, and then the insulating film 250Ac is formed. Here, hafnium oxide can be deposited for the insulating film to be the insulator 250d by a thermal ALD method. In the above manner, the microwave treatment in an oxygen-containing atmosphere may be performed multiple times (at least two or more times).

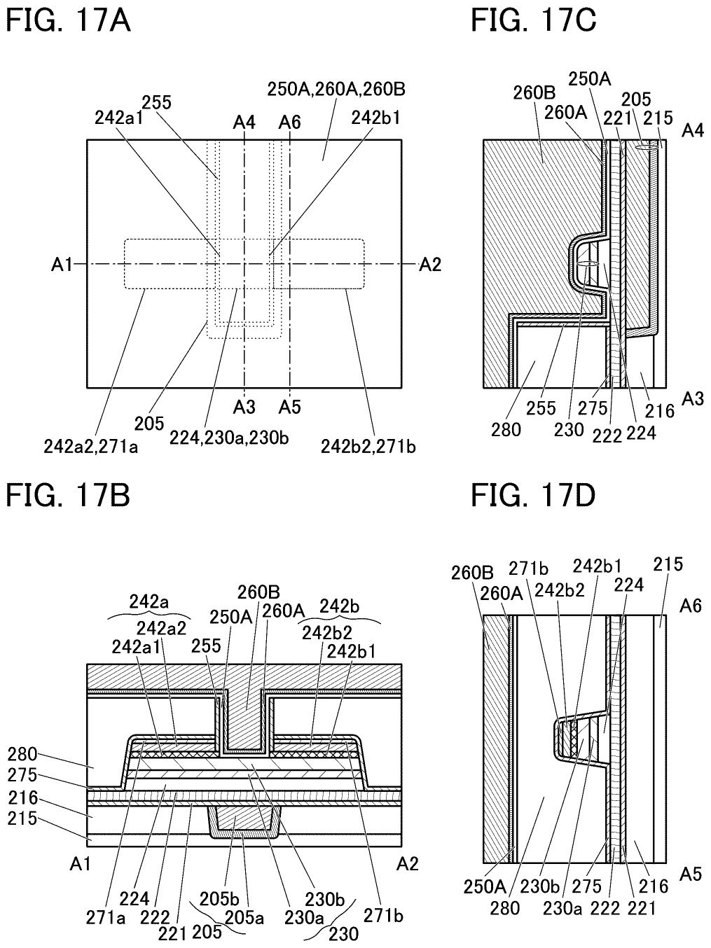

Next, a conductive film 260A to be the conductor 260a and a conductive film 260B to be the conductor 260b are formed in this order (see FIG. 17A to FIG. 17D). The conductive film 260A and the conductive film 260B can each be formed by a sputtering method, a CVD method, an MBE method, a PLD method, a plating method, or an ALD method, for example. In this embodiment, titanium nitride is deposited by an ALD method for the conductive film 260A, and tungsten is deposited by a CVD method for the conductive film 260B.

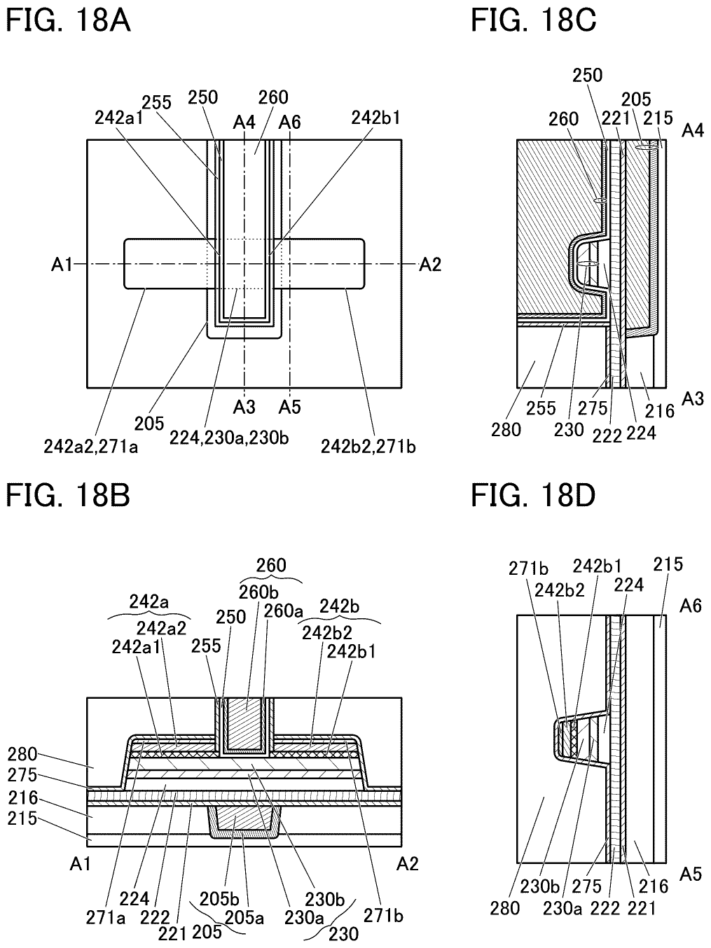

Then, the insulating film 250A, the conductive film 260A, and the conductive film 260B are polished by CMP treatment until the insulator 280 is exposed. That is, portions of the insulating film 250A, the conductive film 260A, and the conductive film 260B exposed from the opening are removed. Thus, the insulator 250 and the conductor 260 (the conductor 260a and the conductor 260b) are formed in the opening overlapping with the conductor 205 (see FIG. 18A to FIG. 18D).

Thus, the insulator 250 is in contact with the insulator 255, the conductor 242a1, the conductor 242b1, the oxide 230, the insulator 224, and the insulator 222 in the opening. The conductor 260 is positioned to fill the opening with the insulator 250 therebetween. In this manner, the transistor 200 is formed.

Next, the insulator 282 is formed over the insulator 255, the insulator 250, the conductor 260, and the insulator 280. The insulator 282 can be deposited by a sputtering method, a CVD method, an MBE method, a PLD method, or an ALD method, for example. The insulator 282 is preferably deposited by a sputtering method. By using a sputtering method that does not need to use a molecule containing hydrogen as a deposition gas, the hydrogen concentration in the insulator 282 can be reduced.

When the insulator 282 is deposited by a sputtering method in an oxygen-containing atmosphere, oxygen can be added to the insulator 280 during the deposition. Thus, excess oxygen can be contained in the insulator 280. At this time, the insulator 282 is preferably formed while the substrate is being heated. Here, as described above, when part of the insulator 255 is oxidized, oxygen that has been supplied to the insulator 280 is diffused into the oxide 230b through the insulator 255 and the insulator 250, so that a suitable amount of oxygen can be supplied to the oxide 230b.

In this embodiment, for the insulator 282, aluminum oxide is deposited by a sputtering method using an aluminum target in an atmosphere containing an oxygen gas. The amount of oxygen implanted, by a sputtering method, into a layer below the insulator 282 can be controlled depending on the amount of RF power applied to the substrate. For example, the amount of oxygen implanted into the layer below the insulator 282 decreases as the RF power decreases, and the amount of oxygen is easily saturated even when the insulator 282 has a small thickness. Moreover, the amount of oxygen implanted into the layer below the insulator 282 increases as the RF power increases. With low RF power, the amount of oxygen implanted into the insulator 280 can be reduced. Alternatively, the insulator 282 may have a stacked-layer structure of two layers. In this case, for example, the lower layer of the insulator 282 is deposited with no RF power applied to the substrate, and the upper layer of the insulator 282 is deposited with an RF power applied to the substrate.

The RF frequency is preferably 10 MHz or higher. The typical frequency is 13.56 MHz. The higher the RF frequency is, the less damage the substrate receives.

Note that heat treatment may be performed before the deposition of the insulator 282. The heat treatment may be performed under reduced pressure, and the insulator 282 may be successively deposited without exposure to the air. Such treatment can remove moisture and hydrogen adsorbed onto the surface of the insulator 280, and further can reduce the moisture concentration and the hydrogen concentration in the insulator 280. The heat treatment temperature is preferably higher than or equal to 100° C. and lower than or equal to 400° C. In this embodiment, the heat treatment is performed at 250° C.

Subsequently the insulator 283 is formed over the insulator 282. The insulator 283 can be deposited by a sputtering method, a CVD method, an MBE method, a PLD method, or an ALD method, for example. The insulator 283 is preferably deposited by a sputtering method. By using a sputtering method that does not need to use a molecule containing hydrogen as a deposition gas, the hydrogen concentration in the insulator 283 can be reduced. In this embodiment, for the insulator 283, silicon nitride is deposited by a sputtering method.

Here, it is preferable that the insulator 282 and the insulator 283 be successively deposited without being exposed to the atmospheric environment. By the deposition without exposure to the air, impurities or moisture from the atmospheric environment can be prevented from being attached onto the insulator 282 and the insulator 283, so that the interface between the insulator 282 and the insulator 283 or the vicinity of the interface thereof can be kept clean.

Heat treatment may be performed after the insulator 283 is formed. The heat treatment temperature is preferably higher than or equal to 100° C. and lower than or equal to 400° C. By the heat treatment, hydrogen contained in the insulator 280, the insulator 250, and the oxide 230 is absorbed by the insulator 282. In other words, hydrogen contained in the insulator 280, the insulator 250, and the oxide 230 diffuses into the insulator 282. Accordingly, the hydrogen concentration in the insulator 282 increases, and the hydrogen concentrations in the insulator 280, the insulator 250, and the oxide 230 decrease. Note that the insulator 283 is provided in contact with a top surface of the insulator 282, which can prevent entry of impurities such as moisture or hydrogen from a component above the insulator 283 in the heat treatment. By the heat treatment, hydrogen contained in the insulator 216, the insulator 224, and the oxide 230 is absorbed by the insulator 222. In other words, hydrogen contained in the insulator 216, the insulator 224, and the oxide 230 diffuses into the insulator 222. Accordingly, the hydrogen concentration in the insulator 222 increases, while the hydrogen concentrations in the insulator 216, the insulator 224, and the oxide 230 decrease. Note that the insulator 221 is provided in contact with the bottom surface of the insulator 222, whereby entry of moisture or impurities such as hydrogen from below the insulator 221, which is caused by the heat treatment, can be prevented.

Through the above steps, the semiconductor device illustrated in FIG. 1 can be manufactured.

The semiconductor device of this embodiment has a structure in which a conductor over an oxide semiconductor has a two-layer structure; the lower layer of the conductor is less likely to be oxidized, the upper layer of the conductor has high conductivity, whereby the conductor functioning as an electrode or a wiring is in contact with a top surface of the oxide semiconductor. The conductor functions as a source electrode and a drain electrode of an OS transistor 200. The semiconductor device of this embodiment is miniaturized by setting the distance between conductors in the lower layer of the source electrode and the drain electrode to be shorter than the distance between conductors in the upper layer of the source electrode and the drain electrode, so that the frequency characteristics and the operation speed of the semiconductor device can be improved. In the semiconductor device of this embodiment, an insulator functioning as a protection film is provided in contact with side surfaces of the conductors in the upper layer of the source electrode and the drain electrode. Thus, excessive oxidation of the conductors in the upper layer of the source electrode and the drain electrode can be prevented.

The semiconductor device of this embodiment includes OS transistors. Since the off-state current of the OS transistors is low, a semiconductor device or a memory device with low power consumption can be achieved. Since the OS transistors have excellent frequency characteristics, a semiconductor device or a memory device with high operating speed can be achieved. With use of the OS transistors, a semiconductor device having favorable electrical characteristics, a semiconductor device with a small variation in electrical characteristics of transistors, a semiconductor device with a high on-state current, or a highly reliable semiconductor device or memory device can be achieved.

This embodiment can be combined with the other embodiments as appropriate. In this specification, in the case where a plurality of structure examples are shown in one embodiment, the structure examples can be combined as appropriate.

### Embodiment 2

In this embodiment, the comparison between the OS transistor described in the above embodiment and a transistor including silicon in a channel formation region (also referred to as a Si transistor) will be described.

### [OS Transistor]

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. As examples of the impurity, hydrogen, nitrogen, and the like are given. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In the OS transistor, a defect that is an oxygen vacancy in the oxide semiconductor into which hydrogen enters (hereinafter sometimes referred to as VoH) may be formed and may generate an electron serving as a carrier. When VoH is formed in the channel formation region, the donor concentration in the channel formation region increases in some cases. As the donor concentration in the channel formation region increases, the threshold voltage might vary. Therefore, when the channel formation region in the oxide semiconductor includes oxygen vacancies, the transistor is likely to have normally-on characteristics (characteristics with which, even when no voltage is applied to the gate electrode, the channel exists and current flows through the transistor). Therefore, impurities, oxygen vacancies, and VoH are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), an increase in leakage current, and the like. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions in the OS transistor.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, an OS transistor can be suitably used as a transistor having a short channel length as compared with a Si transistor. Note that the gate length refers to the length of a gate electrode in a direction in which carriers move inside a channel formation region during operation of the transistor and to the width of the bottom surface of the gate electrode in a top view of the transistor.

Miniaturization of an OS transistor can improve the frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has an effect superior to that of a Si transistor, such as a low off-state current and capability of having a short channel length.

The configuration, structure, method, or the like described in this embodiment can be used in combination with the configuration, structure, method, or the like described in the other embodiments and the like as appropriate.

### Embodiment 3

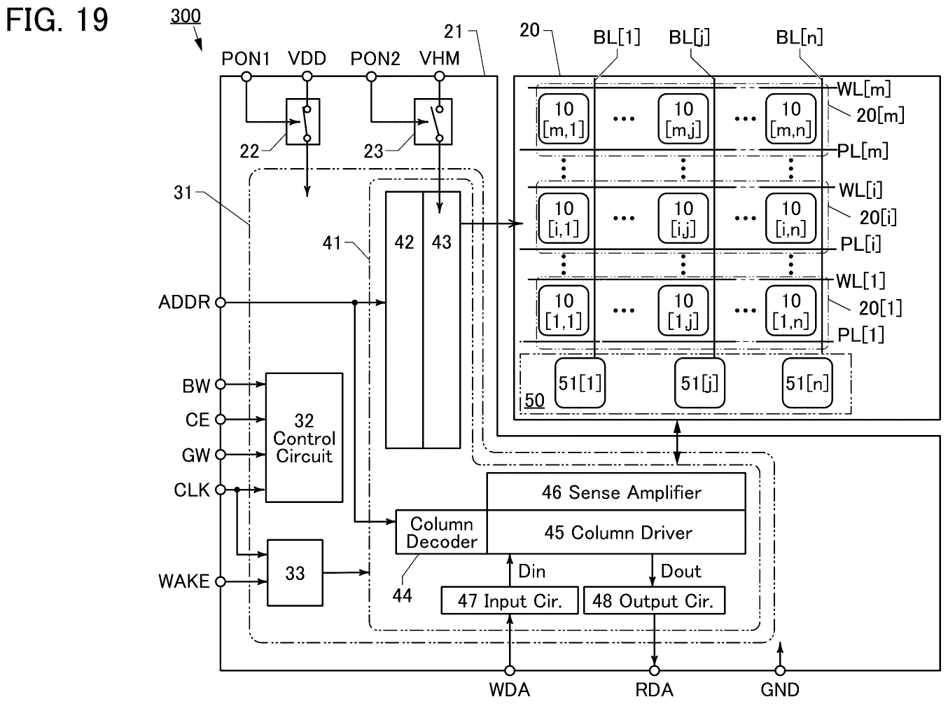

In this embodiment, a memory device using the transistor of one embodiment of the present invention will be described with reference to FIG. 19 to FIG. 25.

In this embodiment, a specific structure example of a memory device using a memory cell including the transistor described in the above embodiment will be described. In this embodiment, a structure example of a memory device provided with stacked layers including memory cells and a layer including a functional circuit having functions of amplifying and outputting a data potential retained in a memory cell will be described.

### [Structure Example of Memory Device]

FIG. 19 is a block diagram of the memory device of one embodiment of the present invention.

A memory device 300 illustrated in FIG. 19 includes a driver circuit 21 and a memory array 20. The memory array 20 includes a plurality of memory cells 10 and a functional layer 50 including a plurality of functional circuits 51.

FIG. 19 illustrates an example in which the memory array 20 includes the plurality of memory cells 10 arranged in a matrix of m rows and n columns (each of m and n is an integer greater than or equal to 2). In the example illustrated in FIG. 19, the functional circuit 51 is provided for each wiring BL functioning as a bit line, and the functional layer 50 includes n functional circuits 51 that are provided to correspond to n wirings BL.

In FIG. 19, the memory cell 10 in the first row and the first column is referred to as a memory cell 10[1,1], and the memory cell 10 in the m-th row and the n-th column is referred to as a memory cell 10[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 10 in the i-th row and the j-th column is denoted as a memory cell 10[i,j]. Note that in this embodiment and the like, “i+α” (α is a positive or negative integer) is not below 1 and does not exceed m. Similarly, “j+α” is not below 1 and does not exceed n.

The memory array 20 includes m wirings WL extending in the row direction, m wirings PL extending in the row direction, and the n wirings BL extending in the column direction. In this embodiment and the like, a first wiring WL (provided in the first row) is denoted as a wiring WL[1], and an m-th wiring WL (provided in the m-th row) is denoted as a wiring WL[m]. Similarly, a first wiring PL (provided in the first row) is denoted as a wiring PL[1], and an m-th wiring PL (provided in the m-th row) is denoted as a wiring PL[m]. Similarly, a first wiring BL (provided in the first column) is denoted as a wiring BL[1], and an n-th wiring BL (provided in the n-th column) is denoted as a wiring BL[n].

A plurality of the memory cells 10 provided in the i-th row are electrically connected to the wiring WL in the i-th row (wiring WL[i]) and the wiring PL in the i-th row (wiring PL[i]). A plurality of the memory cells 10 provided in the j-th column are electrically connected to the wiring BL in the j-th column (wiring BL[j]).

A DOSRAM (registered trademark) (Dynamic Oxide Semiconductor Random Access Memory) can be used for the memory array 20. A DOSRAM is a RAM including a 1T (transistor) 1C (capacitor) memory cell and refers to a memory in which an access transistor is an OS transistor. A current flowing between a source and a drain in an off state, that is, a leakage current, is extremely low in an OS transistor. A DOSRAM can retain electric charges corresponding to data stored in a capacitor for a long time by turning off an access transistor (by bring the access transistor into a non-conducting state). For this reason, the refresh operation frequency of a DOSRAM can be lower than that of a DRAM formed with a transistor containing silicon in its channel formation region (a Si transistor). As a result, power consumption can be reduced. The OS transistor also has excellent frequency characteristics and thus enables high-speed reading and writing of the memory device. Hence, a memory device that can operate at high speed can be provided.

In the memory array 20 illustrated in FIG. 19, a plurality of memory arrays 20[1] to 20[m] can be stacked. When the memory arrays 20[1] to 20[m] included in the memory array 20 are provided in the direction perpendicular to the surface of a substrate provided with the driver circuit 21, the memory density of the memory cells 10 can be increased.

The wiring BL functions as a bit line for writing and reading data. The wiring WL functions as a word line for controlling the on and off state (conducting and non-conducting state) of an access transistor serving as a switch. The wiring PL has a function of a constant potential line connected to a capacitor. Note that a wiring CL (not illustrated) can be additionally provided as a wiring having a function of supplying a back gate potential to a back gate of an OS transistor serving as the access transistor. Alternatively, the wiring PL may also have a function of supplying the back gate potential.

The memory cell 10 included in each of the memory arrays 20[1] to 20[m] is connected to the functional circuit 51 through the wiring BL. The wiring BL can be provided in the direction perpendicular to the surface of the substrate provided with the driver circuit 21. Since the wiring BL provided to extend from the memory cells 10 included in the memory arrays 20[1] to 20[m] is provided in the direction perpendicular to the surface of the substrate, the length of the wiring between the memory array 20 and the functional circuit 51 can be shortened. Accordingly, a signal transmission distance between the two circuits connected to the bit line can be shortened, and the resistance and parasitic capacitance of the bit line can be significantly reduced; thus, power consumption and signal delays can be reduced. Moreover, even when the capacitance of the capacitors included in the memory cells 10 is reduced, the memory device can be made to operate.

The functional circuit 51 has functions of amplifying a data potential retained in the memory cell 10 and outputting the amplified data potential to a sense amplifier 46 included in the driver circuit 21 through a later-described wiring GBL (not illustrated). With this structure, a slight difference in the potential of the wiring BL can be amplified at the time of data reading. Like the wiring BL, the wiring GBL can be provided in the direction perpendicular to the surface of the substrate provided with the driver circuit 21. Since the wiring BL and the wiring GBL provided to extend from the memory cells 10 included in the memory arrays 20[1] to 20[m] are provided in the direction perpendicular to the surface of the substrate, the length of the wiring between the functional circuit 51 and the sense amplifier 46 can be shortened. Accordingly, a signal transmission distance between the two circuits connected to the wiring GBL can be shortened, and the resistance and parasitic capacitance of the wiring GBL can be significantly reduced; thus, power consumption and signal delays can be reduced.

Note that the wiring BL is provided in contact with a semiconductor layer of the transistor included in the memory cell 10. Alternatively, the wiring BL is provided in contact with a region functioning as a source or a drain in the semiconductor layer of the transistor included in the memory cell 10. Alternatively, the wiring BL is provided in contact with a conductor provided in contact with the region functioning as the source or the drain in the semiconductor layer of the transistor included in the memory cell 10. That is, the wiring BL is a wiring for electrically connecting one of the source and the drain of the transistor included in the memory cell 10 in each layer of the memory array 20 to the functional circuit 51 in the perpendicular direction.

The memory array 20 can be provided over the driver circuit 21 to overlap therewith. When the driver circuit 21 and the memory array 20 are provided to overlap with each other, a signal transmission distance between the driver circuit 21 and the memory array 20 can be shortened. Accordingly, resistance and parasitic capacitance between the driver circuit 21 and the memory array 20 are reduced, so that power consumption and signal delays can be reduced. In addition, the memory device 300 can be downsized.

The functional circuit 51 can be provided at any desired position, e.g., over a circuit that is formed using Si transistors in a manner similar to that of the memory arrays 20[1] to 20[m] when being formed with an OS transistor like the transistor included in the memory cell 10 of the DOSRAM, whereby integration can be easily performed. With the structure in which a signal is amplified by the functional circuit 51, a circuit in a subsequent stage, such as the sense amplifier 46, can be downsized; hence, the memory device 300 can be downsized.

The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the memory device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 300. For example, the control circuit performs a logical operation on the signal CE, the signal GW, and the signal BW to determine an operation mode (e.g., a writing operation or a reading operation) of the memory device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for performing writing and reading of data to/from the memory cells 10. Moreover, the peripheral circuit 41 is a circuit that outputs signals for controlling the functional circuits 51. The peripheral circuit 41 includes a row decoder 42, a column decoder 44, a row driver 43, a column driver 45, an input circuit 47 (Input Cir.), an output circuit 48 (Output Cir.), and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 300, a high power supply voltage is VDD and a low power supply voltage is GND (a ground potential). In addition, VHM is a high power supply voltage used to set the word line at high level and is higher than VDD. The on/off state of the PSW 22 is controlled by the signal PON1, and the on/off state of the PSW 23 is controlled by the signal PON2. The number of power domains to which VDD is supplied is one in the peripheral circuit 31 in FIG. 19 but can be more than one. In that case, a power switch is provided for each power domain.

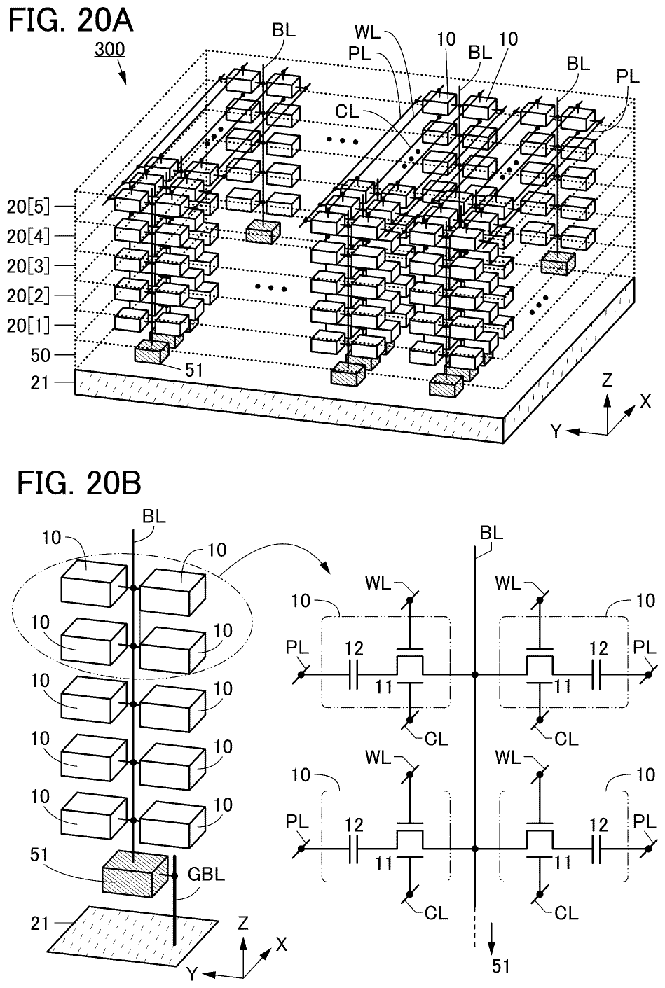

In the memory array 20 including the memory arrays 20[1] to 20[m] (m is an integer greater than or equal to 2) and the functional layer 50, the memory arrays 20 can be provided in stacked layers over the driver circuit 21. Stacking the memory arrays 20 in the plurality of layers can increase the memory density of the memory cells 10. FIG. 20A is a perspective view of the memory device 300 that includes the functional layer 50 and five layers (m=5) of memory arrays 20[1] to 20[5], which overlap with each other, over the driver circuit 21.

In FIG. 20A, the memory array 20 provided in the first layer is denoted as the memory array 20[1], the memory array 20 provided in the second layer is denoted as the memory array 20[2], and the memory array 20 provided in the fifth layer is denoted as the memory array 20[5]. FIG. 20A also shows the wiring WL, the wiring PL, and the wiring CL provided to extend in the X direction and the wiring BL provided to extend in the Z direction (the direction perpendicular to the surface of the substrate provided with the driver circuit). For easy viewing of the drawing, some of the wirings WL and the wirings PL included in the memory arrays 20 are not illustrated.

FIG. 20B is a schematic view for describing a structure example of the functional circuit 51, which is connected to the wiring BL, and the memory cells 10 included in the memory arrays 20[1] to 20[5], which are connected to the wiring BL, illustrated in FIG. 20A. FIG. 20B illustrates the wiring GBL provided between the functional circuit 51 and the driver circuit 21. Note that a structure in which a plurality of memory cells (memory cells 10) are electrically connected to one wiring BL is also referred to as “memory string”. In the drawings, the wiring GBL is sometimes represented by a bold line for increasing visibility.

FIG. 20B illustrates an example of a circuit structure of the memory cell 10 connected to the wiring BL. The memory cell 10 includes a transistor 11 and a capacitor 12. As for the transistor 11, the capacitor 12, and the wirings (e.g., the wiring BL and the wiring WL), for example, the wiring BL[1] and the wiring WL[1] are referred to as the wiring BL and the wiring WL in some cases. Here, the transistor 11 corresponds to the transistor 200 described in Embodiment 1.

In the memory cell 10, one of a source and a drain of the transistor 11 is connected to the wiring BL. The other of the source and the drain of the transistor 11 is connected to one electrode of the capacitor 12. The other electrode of the capacitor 12 is connected to the wiring PL. A gate of the transistor 11 is connected to the wiring WL. A back gate of the transistor 11 is connected to the wiring CL.

The wiring PL is a wiring for supplying a constant potential for retaining the potential of the capacitor 12. The wiring CL is a wiring for supplying a constant potential for controlling the threshold voltage of the transistor 11. The wiring PL and the wiring CL may have the same potential. In that case, the number of wirings connected to the memory cell 10 can be reduced by connecting the two wirings.

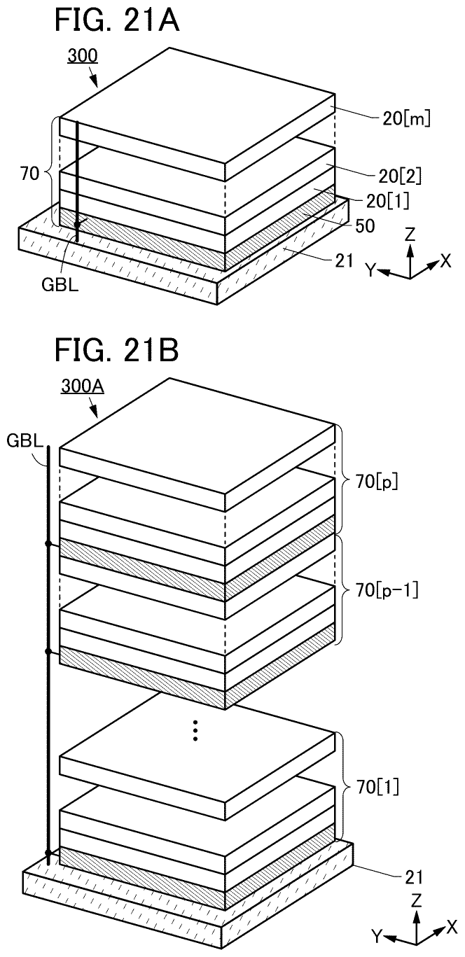

The wiring GBL illustrated in FIG. 20B is provided to electrically connect the driver circuit 21 and the functional layer 50. FIG. 21A is a schematic view of the memory device 300 in which the functional circuit 51 and the memory arrays 20[1] to 20[m] are regarded as a repeating unit 70. Although FIG. 21A illustrates one wiring GBL, the wiring GBL is provided as appropriate depending on the number of functional circuits 51 provided in the functional layer 50.

Note that the wiring GBL is provided in contact with a semiconductor layer of a transistor included in the functional circuit 51. Alternatively, the wiring GBL is provided in contact with a region functioning as a source or a drain in the semiconductor layer of the transistor included in the functional circuit 51. Alternatively, the wiring GBL is provided in contact with a conductor provided in contact with the region functioning as the source or the drain in the semiconductor layer of the transistor included in the functional circuit 51. That is, the wiring GBL can be regarded as a wiring for electrically connecting the driver circuit 21 and one of the source and the drain of the transistor included in the functional circuit 51 in the functional layer 50 in the perpendicular direction.

The repeating unit 70 including the functional circuit 51 and the memory arrays 20[1] to 20[m] may have a stacked-layer structure. A memory device 300A of one embodiment of the present invention can include repeating units 70[1] to 70[p] (p is an integer greater than or equal to 2) as illustrated in FIG. 21B. The wiring GBL is connected to the functional layer 50 included in the repeating units 70. The wiring GBL is provided as appropriate depending on the number of functional circuits 51.

In one embodiment of the present invention, OS transistors are provided in stacked layers and a wiring functioning as a bit line is provided in the direction perpendicular to the surface of the substrate provided with the driver circuit 21. Since the wiring that is provided to extend from the memory array 20 and function as a bit line is provided in the direction perpendicular to the surface of the substrate, the length of the wiring between the memory array 20 and the driver circuit 21 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 10 is provided in a layer where the memory array 20 is provided. With this structure, a slight difference in the potential of the wiring BL functioning as a bit line can be amplified at the time of data reading to drive the sense amplifier 46 included in the driver circuit 21. A circuit such as a sense amplifier can be downsized, so that the memory device 300 can be downsized. Moreover, even when the capacitance of the capacitors 12 included in the memory cells 10 is reduced, the memory device 300 can be made to operate.

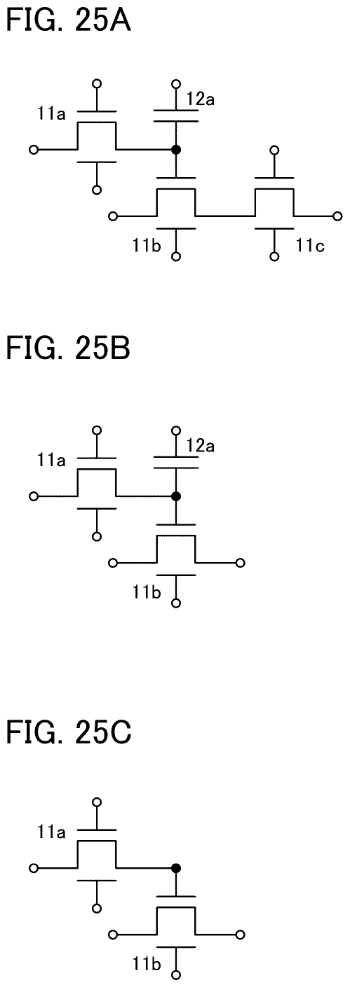

Although an example in which the memory cell 10 has a 1T (transistor) 1C (capacitor) structure is described above, the present invention is not limited to this. For example, as illustrated in FIG. 25A, a 3T1C memory cell may be used for a memory device. The memory cell illustrated in FIG. 25A includes transistors 11a, 11b, and 11c and a capacitor 12a. Here, the transistors 11a, 11b, and 11c can have the same structure as the transistor 11, and the capacitor 12a can have the same structure as the capacitor 12. A RAM with such a configuration is sometimes referred to as a NOSRAM (registered trademark) (Nonvolatile Oxide Semiconductor RAM).

As illustrated in FIG. 25A, one of a source and a drain of the transistor 11a is electrically connected to one electrode of the capacitor 12a and a first gate of the transistor 11b. One of a source and a drain of the transistor 11b is electrically connected to one of a source and a drain of the transistor 11c. Note that wirings are provided as appropriate for a first gate, the other of the source and the drain, and a second gate of the transistor 11a; the other of the source and the drain and a second gate of the transistor 11b; a first gate, the other of the source and the drain, and a second gate of the transistor 11c; and the other electrode of the capacitor 12a. The structure of the memory device can be changed as appropriate depending on these wirings.

Alternatively, a 2T1C memory cell that includes only the transistors 11a and 11b and the capacitor 12a without including the transistor 11c as illustrated in FIG. 25B may be employed.

In the case where the parasitic capacitance of the transistor 11a and the transistor 11b is sufficiently large, the capacitor 12a may be omitted as illustrated in FIG. 25C. In that case, the memory cell is composed only of the transistor 11a and the transistor 11b.

### [Structure Examples of Memory Array 20 and Functional Circuit 51]

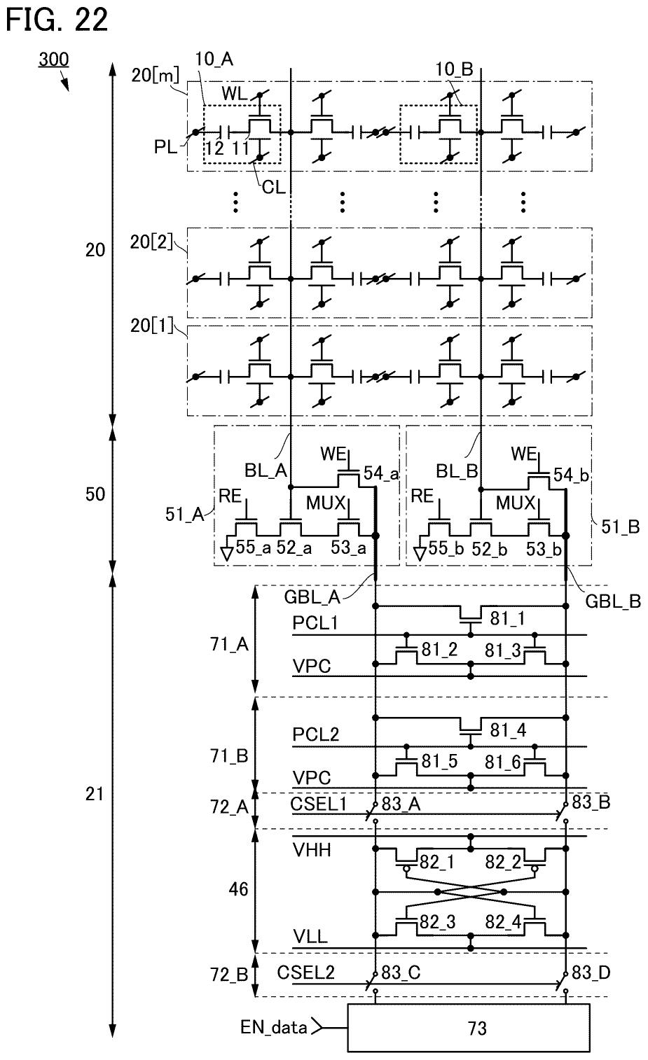

A structure example of the functional circuit 51 and structure examples of the memory array 20 and the sense amplifier 46 included in the driver circuit 21, which are described with reference to FIG. 19 to FIG. 21, are described with reference to FIG. 22. FIG. 22 illustrates the driver circuit 21 connected to the wirings GBL (a wiring GBL_A and a wiring GBL_B) connected to the functional circuits 51 (a functional circuit 51_A and a functional circuit 51_B) connected to the memory cells 10 (a memory cell 10_A and a memory cell 10_B) connected to different wirings BL (a wiring BL_A and a wiring BL_B). FIG. 22 also illustrates, as the driver circuit 21, a precharge circuit 71_A, a precharge circuit 71_B, a switch circuit 72_A, a switch circuit 72_B, and a write/read circuit 73 in addition to the sense amplifier 46.

As the functional circuits 51_A and 51_B, transistors 52_a, 52_b, 53_a, 53_b, 54_a, 54_b, 55_a, and 55_b are illustrated. The transistors 52_a, 52_b, 53_a, 53_b, 54_a, 54_b, 55_a, and 55_b illustrated in FIG. 22 are OS transistors like the transistor 11 included in the memory cell 10. The functional layer 50 including the functional circuits 51 can be provided in layers stacked over the driver circuit 21 like the memory arrays 20[1] to 20[m].

The wiring BL_A is connected to a gate of the transistor 52_a, and the wiring BL_B is connected to a gate of the transistor 52_b. One of a source and a drain of each of the transistors 53_a and 54_a is connected to the wiring GBL_A. One of a source and a drain of each of the transistors 53_b and 54_b is connected to the wiring GBL_B. The wirings GBL_A and GBL_B are provided in the perpendicular direction like the wirings BL_A and BL_B and connected to transistors included in the driver circuit 21. As illustrated in FIG. 22, a selection signal MUX, a control signal WE, or a control signal RE is supplied to gates of the transistors 53_a, 53_b, 54_a, 54_b, 55_a, and 55_b.

Transistors 81_1 to 81_6 and 82_1 to 82_4 included in the sense amplifier 46, the precharge circuit 71_A, and the precharge circuit 71_B illustrated in FIG. 22 are Si transistors. Switches 83_A to 83_D included in the switch circuit 72_A and the switch circuit 72_B can also be Si transistors. The one of the source and the drain of each of the transistors 53_a, 53_b, 54_a, and 54_b is connected to the transistor or switch included in the precharge circuit 71_A, the precharge circuit 71_B, the sense amplifier 46, or the switch circuit 72_A.

The precharge circuit 71_A includes the n-channel transistors 81_1 to 81_3. The precharge circuit 71_A is a circuit for precharging the wiring BL_A and the wiring BL_B with an intermediate potential VPC corresponding to a potential VDD/2 between a high power supply potential (VDD) and a low power supply potential (VSS) in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 46 includes the p-channel transistors 82_1 and 82_2 and the n-channel transistors 82_3 and 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged by selecting the memory cells 10_A and 10_B are changed, and the potentials of the wiring GBL_A and the wiring GBL_B are set to VDD or VSS in accordance with the changes. The potentials of the wiring GBL_A and the wiring GBL_B can be output to the outside through the switch 83_C, the switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The on and off states of the switch circuit 72_A are switched under the control of a switch signal CSEL1. In the case where the switches 83_A and 83_B are n-channel transistors, the switches 83_A and 83_B are turned on and off when the switch signal CSEL1 is at high level and low level, respectively. The switch circuit 72_B is a circuit for controlling electrical continuity between the write/read circuit 73 and the bit line pair connected to the sense amplifier 46. The on and off states of the switch circuit 72_B are switched under the control of a switching signal CSEL2. The switches 83_C and 83_D may operate in a manner similar to those of the switches 83_A and 83_B.

As illustrated in FIG. 22, the memory device 300 can have a structure where the memory cell 10, the functional circuit 51, and the sense amplifier 46 are connected to each other through the wiring BL and the wiring GBL provided in the perpendicular direction which is the shortest distance. Even with addition of the functional layer 50 including transistors included in the functional circuits 51, the loads of the wirings BL are reduced, whereby the writing time can be shortened and data reading can be facilitated.

As illustrated in FIG. 22, the transistors included in the functional circuits 51_A and 51_B are controlled in accordance with the control signals WE and RE and the selection signal MUX. The transistors can output the potential of the wiring BL through the wiring GBL to the driver circuit 21 in accordance with the control signals and the selection signal. The functional circuits 51_A and 51_B can each function as a sense amplifier that consists of OS transistors. With this structure, a slight difference in the potential of the wiring BL can be amplified at the time of reading to drive the sense amplifier 46 formed using Si transistors.

### <Structure Example of Memory Cell>

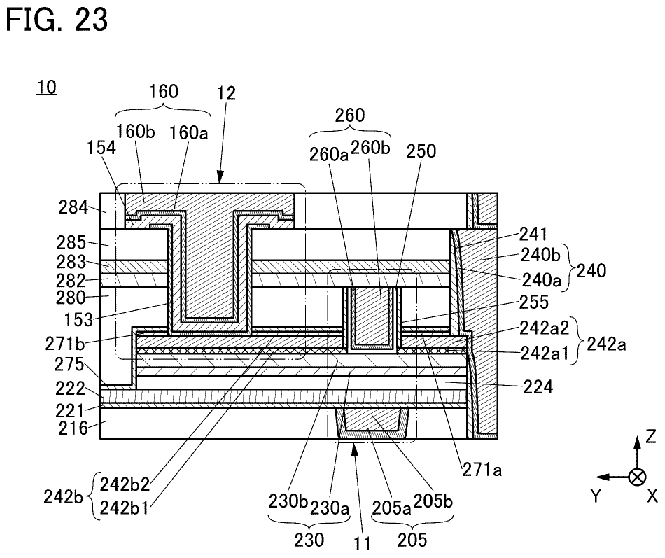

A structure example of the memory cell 10 used in the above-described memory device will be described with reference to FIG. 23.

Note that in FIG. 23, the X direction is parallel to the channel width direction of an illustrated transistor, the Y direction is perpendicular to the X direction, and the Z direction is perpendicular to the X direction and the Y direction.

As illustrated in FIG. 23, the memory cell 10 includes the transistor 11 and the capacitor 12. An insulator 285 is provided over the transistor 11, and an insulator 284 is provided over the insulator 285. An insulator that can be used for the insulator 216 can be used for the insulator 285 and the insulator 284. Note that the transistor 11 has the same structure as the transistor 200 described in the above embodiment, and the same components are denoted by the same reference numerals. The above embodiment can be referred to for the details of the transistor 200. A conductor 240 is provided in contact with one of the source and the drain of the transistor 11 (the conductor 242a). The conductor 240 is provided to extend in the Z direction and functions as the wiring BL.

The capacitor 12 includes a conductor 153 over the conductor 242b, an insulator 154 over the conductor 153, and a conductor 160 (a conductor 160a and a conductor 160b) over the insulator 154.

At least parts of the conductor 153, the insulator 154, and the conductor 160 are positioned in an opening provided in the insulator 271b, the insulator 275, the insulator 280, the insulator 282, the insulator 283, and the insulator 285. End portions of the conductor 153, the insulator 154, and the conductor 160 are positioned at least over the insulator 282, and preferably positioned over the insulator 285. The insulator 154 is provided to cover the end portion of the conductor 153. This enables the conductor 153 and the conductor 160 to be electrically insulated from each other.

The deeper the opening provided in the insulator 271b, the insulator 275, the insulator 280, the insulator 282, the insulator 283, and the insulator 285 is (i.e., the larger the thickness of one or more of the insulator 271b, the insulator 275, the insulator 280, the insulator 282, the insulator 283, and the insulator 285 is), the larger the electrostatic capacitance of the capacitor 12 can be. Increasing the electrostatic capacitance per unit area of the capacitor 12 can achieve miniaturization or higher integration of the semiconductor device.

The conductor 153 includes a region functioning as one electrode (a lower electrode) of the capacitor 12. The insulator 154 includes a region functioning as a dielectric of the capacitor 12. The conductor 160 includes a region functioning as the other electrode (an upper electrode) of the capacitor 12. The capacitor 12 forms a MIM (Metal-Insulator-Metal) capacitor.

The conductor 242b provided over the oxide 230 to overlap with the oxide 230 functions as a wiring electrically connected to the conductor 153 of the capacitor 12.

Each of the conductor 153 and the conductor 160 included in the capacitor 12 can be formed using any of a variety of conductors that can be used for the conductor 205 and the conductor 260. The conductor 153 and the conductor 160 are each preferably deposited by a deposition method that offers excellent coverage, such as an ALD method or a CVD method. For example, titanium nitride or tantalum nitride deposited by an ALD method or a CVD method can be used for the conductor 153.

The top surface of the conductor 242b2 is in contact with the bottom surface of the conductor 153. Here, when a conductive material having excellent conductivity is used for the conductor 242b2, the contact resistance between the conductor 153 and the conductor 242b can be reduced.

Titanium nitride deposited by an ALD method or a CVD method can be used for the conductor 160a, and tungsten deposited by a CVD method can be used for the conductor 160b. Note that in the case where the adhesion of tungsten to the insulator 154 is sufficiently high, a single-layer structure of tungsten deposited by a CVD method may be used for the conductor 160.

For the insulator 154 included in the capacitor 12, a high dielectric constant (high-k) material (a material with a high dielectric constant) is preferably used. The insulator 154 is preferably deposited by a deposition method that offers excellent coverage, such as an ALD method or a CVD method.

Examples of insulators of the high dielectric constant (high-k) material include an oxide, an oxynitride, a nitride oxide, and a nitride containing one or more kinds of metal elements selected from aluminum, hafnium, zirconium, gallium, and the like. In addition, the oxide, the oxynitride, the nitride oxide, or the nitride may contain silicon. Stacked insulators formed of any of the above materials can also be used.

Examples of the insulators of the high dielectric constant (high-k) material include aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, and an oxynitride containing hafnium and zirconium. Using such a high-k material allows the insulator 154 to be thick enough to inhibit a leakage current and the capacitor 12 to have sufficiently large capacitance.

It is preferable to use stacked insulators formed of any of the above materials, and it is preferable to use a stacked-layer structure of a high dielectric constant (high-k) material and a material having higher dielectric strength than the high dielectric constant (high-k) material. For the insulator 154, an insulator in which zirconium oxide, aluminum oxide, and zirconium oxide are stacked in this order can be used, for example. As another example, an insulator in which zirconium oxide, aluminum oxide, zirconium oxide, and aluminum oxide are stacked in this order can be used. As another example, an insulator in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor 12.

The deeper the opening provided in the insulator 271b, the insulator 275, the insulator 280, the insulator 282, the insulator 283, and the insulator 285 is (i.e., the larger the thickness of one or more of the insulator 271b, the insulator 275, the insulator 280, the insulator 282, the insulator 283, and the insulator 285 is), the larger the electrostatic capacitance of the capacitor 12 can be. Here, since the insulator 271b, the insulator 275, the insulator 282, and the insulator 283 function as barrier insulators, their thicknesses are preferably set in accordance with a barrier property required for the semiconductor device. The thickness of the conductor 260 functioning as a gate electrode depends on the thickness of the insulator 280; thus, the thickness of the insulator 280 is preferably set in accordance with the thickness of the conductor 260 required for the semiconductor device.

Accordingly, the electrostatic capacitance of the capacitor 12 is preferably set by adjusting the thickness of the insulator 285. For example, the thickness of the insulator 285 is set within the range from 50 nm to 250 nm inclusive, and the depth of the opening is approximately greater than or equal to 150 nm and less than or equal to 350 nm. When the capacitor 12 is formed within the above range, the capacitor 12 can have adequate electrostatic capacitance, and the height of one layer can be prevented from being excessively large in a semiconductor device in which a plurality of memory cell layers are stacked. Note that capacitors provided in memory cells may have different electrostatic capacitances between the plurality of memory cell layers. In this structure, the thicknesses of the insulators 285 provided in the memory cell layers vary, for example.

Note that the sidewall of an opening portion in which the capacitor 12 is positioned and which is provided in the insulator 285 and the like may be substantially perpendicular to the top surface of the insulator 222 or may be tapered. The tapered shape of the sidewall can improve the coverage with the conductor 153 and the like provided in the opening portion in the insulator 285 and the like; as a result, defects such as voids can be reduced.

The conductor 242a provided over the oxide 230 to overlap with the oxide 230 functions as a wiring electrically connected to the conductor 240. In FIG. 23, for example, the top surface and a side end portion of the conductor 242a are electrically connected to the conductor 240 extending in the Z direction. Specifically, in FIG. 23, the top surface and the side end portion of the conductor 242a2 and the side end portion of the conductor 242a1 are in contact with the conductor 240.

When the conductor 240 is in direct contact with at least one of the top surface and the side end portion of the conductor 242a, an electrode for connection does not need to be provided additionally, so that the area occupied by the memory arrays can be reduced. In addition, the integration degree of the memory cells is increased, and the memory capacity of the memory device can be increased. Note that the conductor 240 is preferably in contact with the side end portion and part of the top surface of the conductor 242a. When the conductor 240 is in contact with a plurality of surfaces of the conductor 242a, the contact resistance between the conductor 240 and the conductor 242a can be reduced. In particular, as illustrated in FIG. 23, the conductor 240 is in contact with part of the top surface and a side end portion of the conductor 242a2 with high conductivity, so that the contact resistance between the conductor 240 and the conductor 242a can be further reduced.

The conductor 240 is provided in an opening formed in the insulator 216, the insulator 221, the insulator 222, the insulator 275, the insulator 280, the insulator 282, the insulator 283, the insulator 285, and the insulator 284.

The conductor 240 preferably has a stacked-layer structure of the conductor 240a and the conductor 240b. For example, as illustrated in FIG. 23, the conductor 240 can have a structure in which the conductor 240a is provided in contact with the inner wall of the opening portion and the conductor 240b is provided inwardly from the conductor 240a. That is, the conductor 240a is positioned closer to the insulator 216, the insulator 221, the insulator 222, the insulator 275, the insulator 280, the insulator 282, the insulator 283, the insulator 285, and the insulator 284 than the conductor 240b is. The conductor 240a is in contact with the top surface and the side end portion of the conductor 242a.

A conductive material having a function of inhibiting passage of impurities such as water or hydrogen is preferably used for the conductor 240a. The conductor 240a can have a single-layer structure or a stacked-layer structure including one or more of tantalum, tantalum nitride, titanium, titanium nitride, ruthenium, and ruthenium oxide, for example. Thus, impurities such as water or hydrogen can be inhibited from entering the oxide 230 through the conductor 240.

The conductor 240 also functions as a wiring and thus is preferably formed using a conductor having high conductivity. For example, a conductive material containing tungsten, copper, or aluminum as its main component can be used for the conductor 240b.

For example, it is preferable to use titanium nitride for the conductor 240a and tungsten for the conductor 240b. In that case, the conductor 240a is a conductor that contains titanium and nitrogen, and the conductor 240b is a conductor that contains tungsten.

Note that the conductor 240 may have a single-layer structure or a stacked-layer structure of three or more layers.

As illustrated in FIG. 23, an insulator 241 is preferably provided in contact with a side surface of the conductor 240. Specifically, the insulator 241 is provided in contact with the inner wall of an opening in the insulator 216, the insulator 221, the insulator 222, the insulator 275, the insulator 280, the insulator 282, the insulator 283, the insulator 285, and the insulator 284. The insulator 241 is formed also on side surfaces of the insulator 224, the oxide 230, and the conductor 242a that are formed to protrude in the opening. Here, at least part of the conductor 242a is exposed from the insulator 241 and is in contact with the conductor 240. That is, the conductor 240 is provided to fill the opening with the insulator 241 therebetween.

As illustrated in FIG. 23, the uppermost portion of the insulator 241 formed below the conductor 242a is preferably positioned below the top surface of the conductor 242a. With this structure, the conductor 240 can be in contact with at least part of the side end portion of the conductor 242a. Note that the insulator 241 formed below the conductor 242a preferably includes a region in contact with a side surface of the oxide 230. With this structure, impurities such as water or hydrogen contained in the insulator 280 and the like can be inhibited from entering the oxide 230 through the conductor 240.

For the insulator 241, a barrier insulating film that can be used for the insulator 275 or the like is used. For the insulator 241, an insulator such as silicon nitride, aluminum oxide, or silicon nitride oxide is used, for example. With this structure, impurities such as water or hydrogen contained in the insulator 280 and the like can be inhibited from entering the oxide 230 through the conductor 240. In particular, silicon nitride is suitable because of its high blocking property against hydrogen. Furthermore, oxygen contained in the insulator 280 can be inhibited from being absorbed by the conductor 240.

Although FIG. 23 illustrates the structure in which the insulator 241 is a single layer, the present invention is not limited thereto. The insulator 241 may have a stacked-layer structure of two or more layers.

In the case where the insulator 241 has a two-layer stacked structure, a barrier insulating film against oxygen is used for a first layer in contact with the inner wall of the opening in the insulator 280 and the like, and a barrier insulating film against hydrogen is used for a second layer positioned inward from the first layer. For example, aluminum oxide deposited by an ALD method is used for the first layer, and silicon nitride deposited by a PEALD method is used for the second layer. With this structure, oxidation of the conductor 240 can be inhibited, and hydrogen can be inhibited from entering the oxide 230 and the like from the conductor 240. Thus, the transistor 11 can have improved electrical characteristics and reliability.

Note that the sidewall of the opening portion in which the conductor 240 and the insulator 241 are positioned may be perpendicular or substantially perpendicular to the top surface of the insulator 222 or may be tapered. The tapered sidewall can improve the coverage with the insulator 241 and the like provided in the opening portion.

### <Structure Example of Memory Device 300>

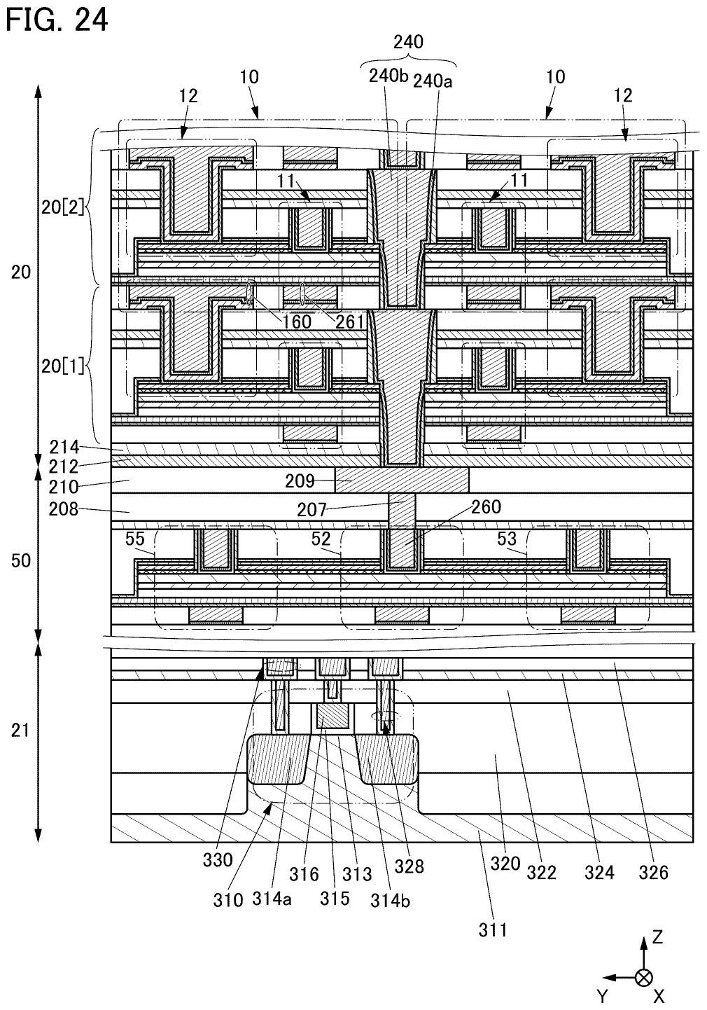

A structure example of the memory device 300 will be described with reference to FIG. 24.

The memory device 300 includes the driver circuit 21 that is a layer including a transistor 310 and the like, the functional layer 50 that is over the driver circuit 21 and is a layer including transistors 52, 53, 54, 55, and the like, and the memory arrays 20[1] to 20[m] over the functional layer 50 (only the memory arrays 20[1] and 20[2] are illustrated in FIG. 24). Note that the transistor 52 corresponds to the transistors 52_a and 52_b, the transistor 53 corresponds to the transistors 53_a and 53_b, the transistor 54 corresponds to the transistors 54_a and 54_b, and the transistor 55 corresponds to the transistors 55_a and 55_b.

FIG. 24 illustrates the transistor 310 included in the driver circuit 21 as an example. The transistor 310 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 310 can be a p-channel transistor or an n-channel transistor. As the substrate 311, a single crystal silicon substrate can be used, for example.

Here, in the transistor 310 illustrated in FIG. 24, the semiconductor region 313 (part of the substrate 311) in which a channel is formed has a protruding shape. Furthermore, the conductor 316 is provided to cover the side and top surfaces of the semiconductor region 313 with the insulator 315 therebetween. Note that the conductor 316 may be formed using a material for adjusting the work function. Such a transistor 310 is also referred to as a FIN-type transistor because it utilizes a protruding portion of a semiconductor substrate. An insulator functioning as a mask for forming the protruding portion may be provided in contact with an upper portion of the protruding portion. Although the case where the protruding portion is formed by processing part of the semiconductor substrate is described here, a semiconductor film having a protruding shape may be formed by processing an SOI (Silicon on Insulator) substrate.

Note that the transistor 310 illustrated in FIG. 24 is an example and the structure is not limited thereto; an appropriate transistor can be used in accordance with a circuit configuration or a driving method.

A wiring layer provided with an interlayer film, a wiring, a plug, and the like may be provided between the components. A plurality of wiring layers can be provided in accordance with the design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are sequentially stacked over the transistor 310 as interlayer films. A conductor 328 and the like are embedded in the insulator 320 and the insulator 322. A conductor 330 or the like is embedded in the insulator 324 and the insulator 326. Note that the conductor 328 and the conductor 330 function as a contact plug or a wiring.

The insulator functioning as an interlayer film may function as a planarization film that covers an uneven shape thereunder. For example, the top surface of the insulator 322 may be planarized by planarization treatment using a chemical mechanical polishing (CMP) method or the like to have improved planarity.

FIG. 24 illustrates the transistors 52, 53, and 55 included in the functional layer 50 as an example. Each of the transistors 52, 53, and 55 has the same structure as the transistor 11 included in the memory cell 10. Sources and drains of the transistors 52, 53, and 55 are connected in series.

An insulator 208 is provided over the transistors 52, 53, and 55, and a conductor 207 is provided in an opening formed in the insulator 208. Furthermore, an insulator 210 is provided over the insulator 208, and a conductor 209 is provided in an opening formed in the insulator 210. Moreover, an insulator 212 is provided over the insulator 210, and the insulator 214 is provided over the insulator 212. Part of the conductor 240 provided in the memory array 20[1] is embedded in an opening formed in the insulator 212 and the insulator 214. Here, for the insulator 208 and the insulator 210, an insulator that can be used for the insulator 216 can be used. For the insulator 212, an insulator that can be used for the insulator 283 can be used. For the insulator 214, an insulator that can be used for the insulator 282 can be used.

The bottom surface of the conductor 207 is provided in contact with the top surface of the conductor 260 of the transistor 52. The top surface of the conductor 207 is provided in contact with the bottom surface of the conductor 209. The top surface of the conductor 209 is provided in contact with the bottom surface of the conductor 240 provided in the memory array 20[1]. With such a structure, the conductor 240 corresponding to the wiring BL and a gate of the transistor 52 can be electrically connected to each other.

Each of the memory arrays 20[1] to 20[m] includes a plurality of the memory cells 10. The conductor 240 included in each memory cell 10 is electrically connected to the conductor 240 in an upper layer and the conductor 240 in a lower layer.

As illustrated in FIG. 24, the conductor 240 is shared between the adjacent memory cells 10. In the adjacent memory cells 10, the components in the right memory cell and the components in the left memory cell are arranged symmetrically about the conductor 240.

Here, the conductor 160 that functions as the upper electrode of the capacitor 12 in a lower layer (e.g., the layer of the memory array 20[1]) and a conductor 261 that functions as the second gate electrode of the transistor 11 in an upper layer (e.g., the layer of the memory array 20[2]) can be formed in the same layer. In other words, the conductor 160 of the capacitor 12 in the lower layer and the conductor 261 of the transistor 11 in the upper layer can be formed to be embedded in respective openings formed in the same insulator 216. The above-described structure is obtained by forming the conductor 160 of the capacitor 12 in the lower layer and the conductor 261 of the transistor 11 in the upper layer by processing one conductive film. At this time, the conductor 160 of the capacitor 12 in the lower layer includes the same material as the conductor 261 of the transistor 11 in the upper layer.

The conductor 160 of the capacitor 12 in the lower layer and the conductor 261 of the transistor 11 in the upper layer are formed at the same time in the above manner, whereby the number of steps for manufacturing the memory device of this embodiment can be reduced and the productivity of the memory device can be increased.

In the above-described memory array 20, the plurality of memory arrays 20[1] to 20[m] can be provided in stacked layers. When the memory arrays 20[1] to 20[m] included in the memory array 20 are provided in the direction perpendicular to the surface of a substrate provided with the driver circuit 21, the memory density of the memory cells 10 can be increased. Moreover, the memory array 20 can be formed by repeating the same manufacturing process in the perpendicular direction. The manufacturing cost of the memory array 20 in the memory device 300 can be reduced.

This embodiment can be combined with the other embodiments as appropriate.

### Embodiment 4

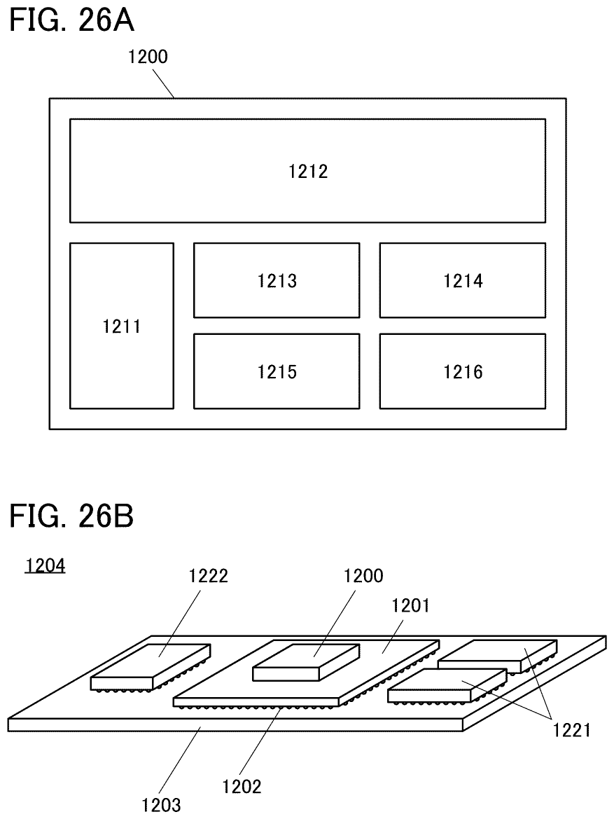

In this embodiment, an example of a chip on which the memory device of one embodiment of the present invention is mounted will be described with reference to FIG. 26.

A plurality of circuits (systems) are mounted on a chip 1200 illustrated in FIG. 26A and FIG. 26B. A technique for integrating a plurality of circuits (systems) into one chip is referred to as system on chip (SoC) in some cases.

As illustrated in FIG. 26A, the chip 1200 includes a CPU 1211, a GPU 1212, one or a plurality of analog arithmetic units 1213, one or a plurality of memory controllers 1214, one or a plurality of interfaces 1215, one or a plurality of network circuits 1216, and the like.

A bump (not illustrated) is provided on the chip 1200, and as illustrated in FIG. 26B, the chip 1200 is connected to a first surface of a package substrate 1201. A plurality of bumps 1202 are provided on a rear side of the first surface of the package substrate 1201, and the package substrate 1201 is connected to a motherboard 1203.

Memory devices such as a DRAM 1221 and a flash memory 1222 may be provided over the motherboard 1203. For example, the DOSRAM described in the above embodiment can be used as the DRAM 1221. This can make the DRAM 1221 have low power consumption, operate at high speed, and have a large capacity.

The CPU 1211 preferably includes a plurality of CPU cores. The GPU 1212 preferably includes a plurality of GPU cores. The CPU 1211 and the GPU 1212 may each include a memory for temporarily storing data. Alternatively, a common memory for the CPU 1211 and the GPU 1212 may be provided in the chip 1200. The DOSRAM described above can be used as the memory. Moreover, the GPU 1212 is suitable for parallel computation of a number of data and thus can be used for image processing or product-sum operation. When an image processing circuit or a product-sum operation circuit using the OS transistor described in the above embodiment is provided in the GPU 1212, image processing or product-sum operation can be performed with low power consumption.

Since the CPU 1211 and the GPU 1212 are provided in the same chip, a wiring between the CPU 1211 and the GPU 1212 can be shortened; accordingly, data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a circuit for connecting a network such as a LAN (Local Area Network). The network circuit 1216 may also include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 5

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### [Electronic Component]

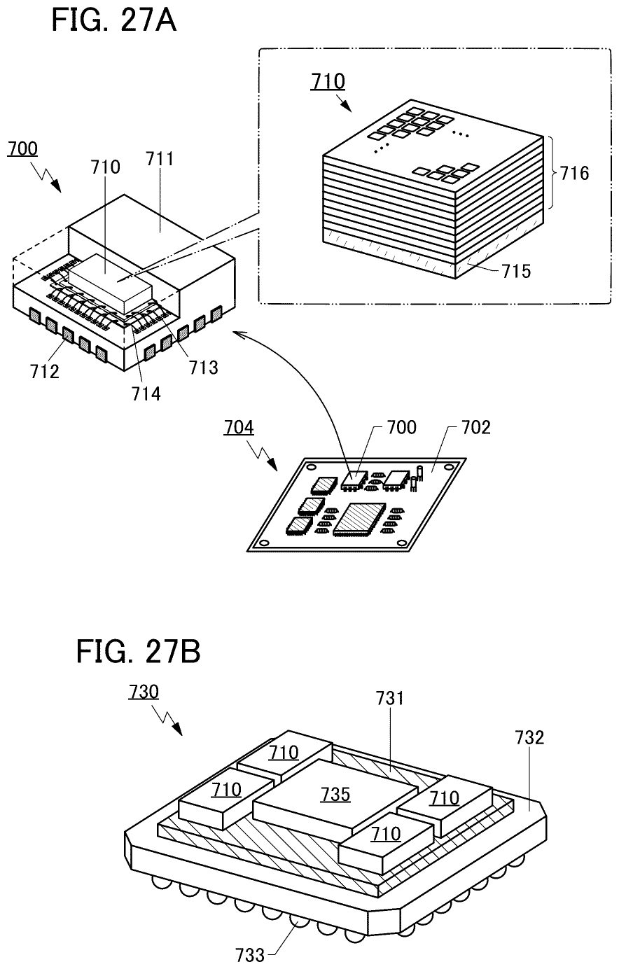

FIG. 27A is a perspective view of a substrate (a circuit board 704) on which an electronic component 700 is mounted. The electronic component 700 illustrated in FIG. 27A includes a semiconductor device 710 in a mold 711. Some components are omitted in FIG. 27A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) and a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

FIG. 27B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer and TSV, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 27B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

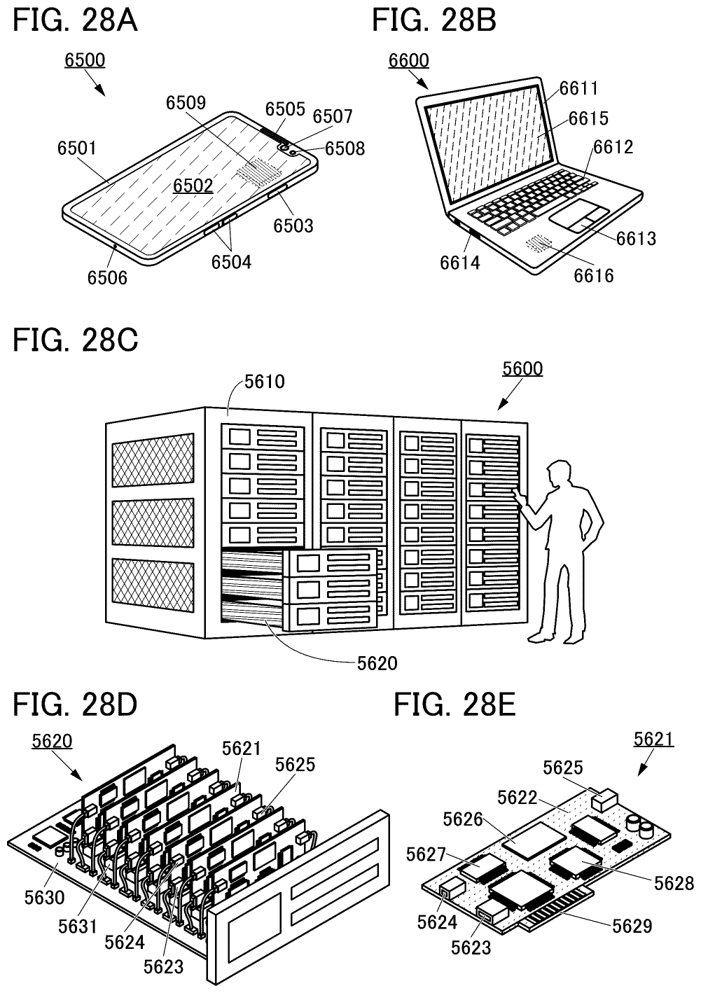

Next, a perspective view of an electronic device 6500 is illustrated in FIG. 28A. An electronic device 6500 illustrated in FIG. 28A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are provided as the control device 6509, for example. The semiconductor device of one embodiment of the present invention can be used for the display portion 6502, the control device 6509, and the like, for example.

An electronic device 6600 illustrated in FIG. 28B is an information terminal that can be used as a laptop personal computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 28C is a perspective view of a large computer 5600. In the large computer 5600 illustrated in FIG. 28C, a plurality of rack mount computers 5620 are stored in a rack 5610. Note that the large computer 5600 may be referred to as a supercomputer.

The computer 5620 can have a structure in a perspective view of FIG. 28D, for example. In FIG. 28D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 28E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 28E also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

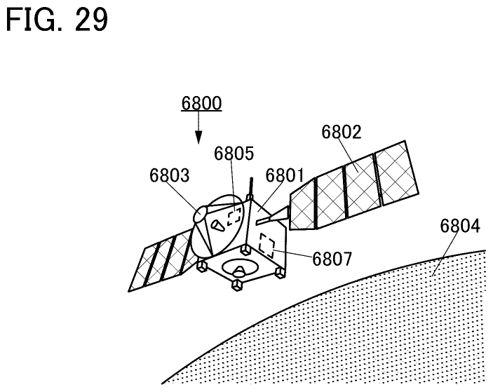

FIG. 29 illustrates an artificial satellite 6800 as an example of a device for space. The artificial satellite 6800 includes a body 6801, a solar panel 6802, an antenna 6803, a secondary battery 6805, and a control device 6807. In FIG. 29, a planet 6804 in outer space is illustrated as an example. Note that outer space refers to, for example, space at an altitude greater than or equal to 100 km, and outer space in this specification may also include thermosphere, mesosphere, and stratosphere.

Although not illustrated in FIG. 29, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for a device for space, such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system in a data center, for example. Long-term management of data, such as guarantee of data immutability, is required for the data center. The management of long-term data needs an increase in building size owing to installation of storages and servers for storing an enormous amount of data, stable electric power for data retention, cooling equipment necessary for data retention, and the like.

With use of the semiconductor device of one embodiment of the present invention for the storage system used in the data center, electric power required for data retention can be reduced and the size of a semiconductor device retaining data can be downsized. Thus, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

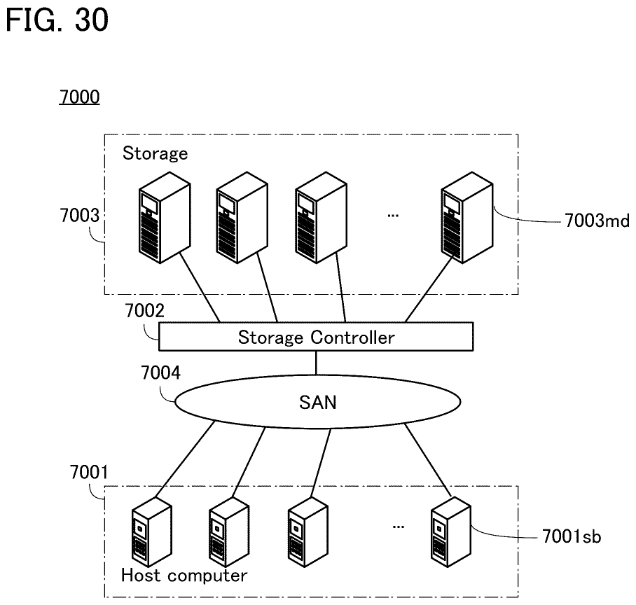

FIG. 30 illustrates a storage system applicable to a data center. A storage system 7000 illustrated in FIG. 30 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in the storage 7003. In the storage system, in order to solve the problem of low access speed of the storage 7003, a cache memory is normally provided in the storage 7003 to shorten data storage and output.

The above-described cache memory is used in the storage control circuit 7002 and the storage 7003. The data transmitted between the host 7001 and the storage 7003 is stored in the cache memory in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing of the storage is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. The semiconductor device of one embodiment of the present invention can be effectively used as one of the global warming countermeasures because of its low power consumption.

The configuration, structure, method, or the like described in this embodiment can be used in combination with the configuration, structure, method, or the like described in the other embodiments and the like as appropriate.

### Example 1

This example will describe the evaluation results of physical properties of the barrier insulator described in the above embodiment.

In this example, samples each including a stack described below were fabricated. In the stack, a tungsten film (hereinafter referred to as a W film), a silicon nitride film (hereinafter referred to as a SiNₓ film), and a titanium nitride film (hereinafter referred to as a TiNₓ film) are stacked in this order over a silicon substrate provided with a thermal oxide film on its surface. Here, the W film is assumed as the conductor 242a2 and the conductor 242b2 in the transistor 200 illustrated in FIG. 1. The SiNₓ film is assumed as the insulator 255 in the transistor 200 illustrated in FIG. 1. A TiNₓ film over the SiNₓ film is a film for protecting the sample in observation.

In this example, the stacks were prepared under different conditions such as the presence or absence of a SiNₓ film, the thickness of the SiNₓ film, and the presence or absence of heat treatment after the formation of the SiNₓ film, so that Samples 1A, 1B, 1C, 1D, 1E, 1F, 1G, 1H, 1J, and 1K were fabricated. Table 1 shows differences in the fabrication conditions between the samples.

TABLE 1

| | 1A | 1B | 1C | 1D | 1E | 1F | 1G | 1H | 1J | 1K |
|---|---|---|---|---|---|---|---|---|---|---|
| SiNₓ thickness | x | x | 0.5 | 0.5 | 1 | 1 | 5 | 5 | 7 | 7 |
| (nm) | | | | | | | | | | |
| Heat treatment | x | ∘ | x | ∘ | x | ∘ | x | ∘ | x | ∘ |

Note that in Table 1, a circle (∘) means that heat treatment was performed, and a cross (x) means that a SiNₓ film was not formed or heat treatment was not performed. The thickness of the SiNₓ film shown in Table 1 is the target thickness.

The W film was deposited to a thickness of 30 nm by a sputtering method.

In each sample, the SiNₓ film was deposited by a PEALD method to have the target thickness shown in Table 1. In this step for Sample 1A and Sample 1B, no SiNₓ film was deposited, but oxygen plasma treatment was performed with a dry etching apparatus. Note that the oxygen plasma treatment corresponds to the oxygen plasma treatment, relating to FIG. 14A to FIG. 14D, performed after the conductor 242_1 is divided into the conductor 242a1 and the conductor 242b1.

In Samples 1B, 1D, 1F, 1H, and 1K, heat treatment was performed at a treatment temperature of 350° C. for treatment time of 60 minutes after the deposition of the SiNₓ film or after the oxygen plasma treatment. The heat treatment was performed under an atmospheric pressure condition in an atmosphere of an N₂ gas at 4 slm and an O₂ gas at 1 slm.

The TiNₓ film was deposited to a thickness of 5 nm by a metal CVD method.

Cross-sectional STEM images of Sample 1A to Sample 1K fabricated in the above manner were taken, and the thickness of the oxide film on a surface of the W film in each sample was measured. Note that the cross-sectional STEM images were taken by “HD-2700” produced by Hitachi High-Tech Corporation.

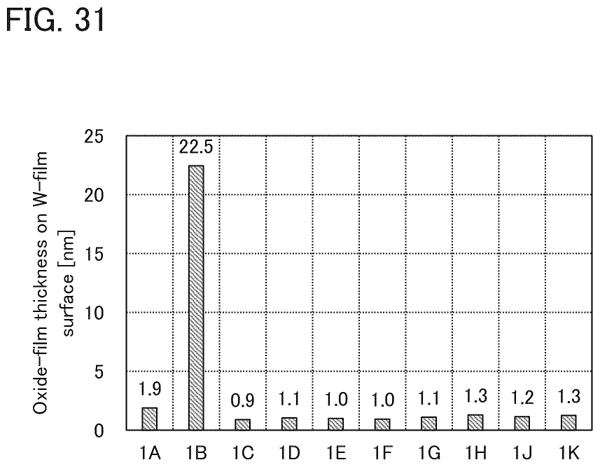

FIG. 31 shows the thickness measurement results of the oxide films on the W-film surfaces in Sample 1A to Sample 1K. In FIG. 31, the horizontal axis represents the sample and the vertical axis represents the oxide-film thickness on the W-film surface [nm].

As shown in FIG. 31, the oxide-film thickness on the W-film surface of Sample 1B is significantly large (22.5 nm), and the oxide-film thicknesses on the W-film surfaces of the other samples, Sample 1C to Sample 1K, are smaller than that of Sample 1A and less than or equal to 1.5 nm. That is, in the samples provided with the SiNₓ film, the oxide-film thickness on the W-film surface is smaller than that of the sample not provided with the SiNₓ film and not subjected to heat treatment. Among Sample 1C to Sample 1K, Samples 1C and 1D had the smallest SiNₓ-film thickness; the measured thickness of the SiNₓ film was 1.3 nm while the target thickness was 0.5 nm in each of Samples 1C and 1D. Form the above, it is demonstrated that formation of the oxide film on the W-film surface due to heat treatment can be inhibited by providing a SiNₓ film with a thickness greater than or equal to 0.5 nm, preferably greater than or equal to 1 nm.

Furthermore, the oxygen (¹⁶O) concentrations of Sample 1A to Sample 1H were evaluated with a SIMS analysis apparatus. Note that SIMS analysis was performed with a quadrupole mass spectrometer (ADEPT1010) manufactured by ULVAC-PHI, Inc.

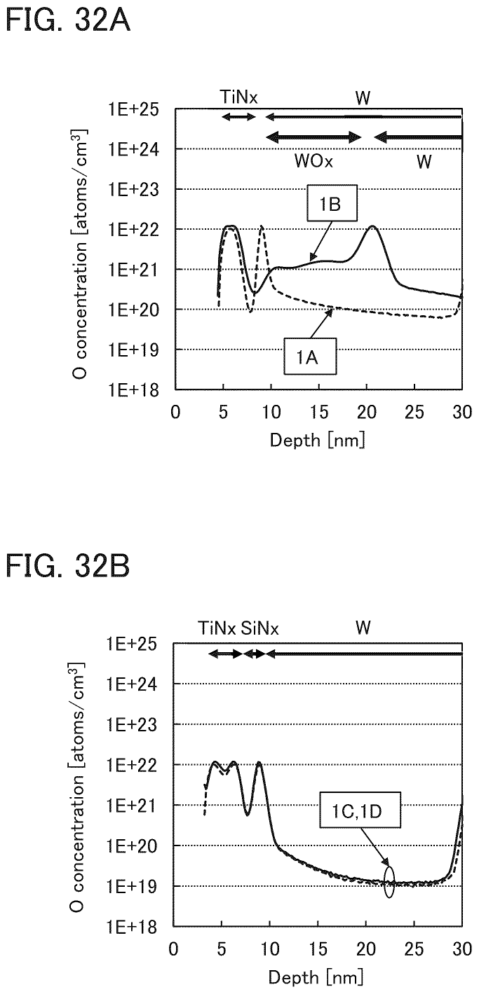

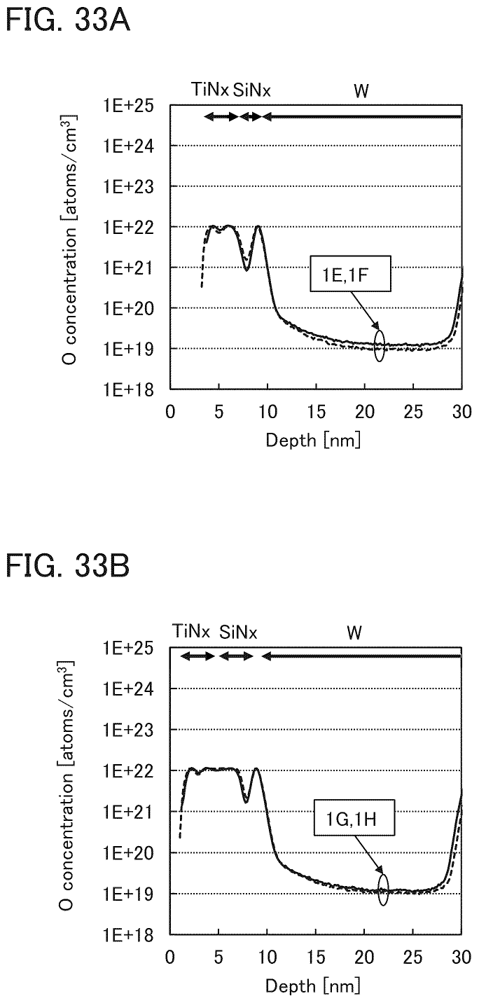

FIG. 32A to FIG. 33B show the SIMS analysis results. FIG. 32A shows the O concentration profiles in the depth direction of Sample 1A and Sample 1B. In FIG. 32A, the horizontal axis represents the depth [nm] from the top surface of the sample and the vertical axis represents the O concentration [atoms/cm³] in the film. Furthermore, the profile of Sample 1A is denoted by a dashed line, and the profile of Sample 1B is denoted by a solid line. Similarly, a dashed line and a solid line in FIG. 32B denote the profile of Sample 1C and the profile of Sample 1D, respectively; a dashed line and a solid line in FIG. 33A denote the profile of Sample 1E and the profile of Sample 1F, respectively; and a dashed line and a solid line in FIG. 33B denote the profile of Sample 1G and the profile of Sample 1H, respectively. Furthermore, a TiNₓ film, a SiNₓ film, and a W film are described in an upper portion in each of FIG. 32A to FIG. 33B to be associated with the horizontal axis.

As shown in FIG. 32A, in Sample 1B subjected to the heat treatment and not provided with a SiNₓ film, the oxygen concentration in the W film was higher than that in Sample 1A, and an approximately 10-nm-thick tungsten oxide film (WOₓ film) was formed on the surface of the W film, which is indicated by the graph. Compared with FIG. 32B to FIG. 33B, FIG. 32A shows that Sample 1A has a higher oxygen concentration in the W film. This result is due to the above-described oxygen plasma treatment.

As shown in FIG. 32B to FIG. 33B, the profiles were substantially aligned with each other between Sample 1C and Sample 1D, between Sample 1E and Sample 1F, and between Sample 1G and Sample 1H. In other words, in the sample provided with the SiNₓ film, an increase in the oxygen concentration in the W film was not observed even when heat treatment was performed. Thus, as in the measurement results of the oxide-film thickness on the W-film surface, it was found that the formation of the oxide film on the W-film surface due to heat treatment can be inhibited by providing a SiNₓ film with a thickness greater than or equal to 0.5 nm, preferably greater than or equal to 1 nm.

This example can be combined with the embodiments and the other example as appropriate.

### Example 2

This example will describe the fabrication of a structure body including the oxide 230 through the processing illustrated in FIG. 10A to FIG. 15D and the observation results of a cross section of the structure body with a STEM.

In this example, a sample as illustrated in FIG. 9B was prepared and subjected to the processing illustrated in FIG. 10A to FIG. 15D. In the sample, an island-shaped stack was provided over a hafnium oxide film (hereinafter referred to as a HfOₓ film) over a silicon substrate, and a silicon nitride film (hereinafter referred to as a SiNₓ_1 film) and a silicon oxide film (hereinafter referred to as a SiOₓ_2 film) were stacked in this order to cover the island-shaped stack. Here, the island-shaped stack is a stacked film in which a silicon oxide film (hereinafter referred to as a SiOₓ_1 film), an In—Ga—Zn oxide film (hereinafter referred to as an IGZO film), a tantalum nitride film (hereinafter referred to as a TaNₓ film), a tungsten film (hereinafter referred to as a W film), and a stacked film of silicon nitride and silicon oxide (hereinafter referred to as a SiNₓ\SiOₓ film) are stacked in this order.

Here, the HfOₓ film corresponds to the insulator 222. The SiOₓ_1 film corresponds to the insulator 224. The IGZO film corresponds to a stacked film of the oxide 230a and the oxide 230b. The TaNₓ film corresponds to the conductor 242_1. The W film corresponds to the conductor 242_2. The SiNₓ\SiOₓ film corresponds to the insulator 271. The SiNₓ_1 film corresponds to the insulator 275. The SiOₓ_2 film corresponds to the insulator 280.

Next, a method for processing a sample including the above structure body is described.

Note that in the above structure body, the HfOₓ film was deposited by an ALD method to a thickness of 20 nm. The SiOₓ_1 film was deposited by a sputtering method to a thickness of 20 nm. The IGZO film was deposited by a sputtering method to have a stacked film of a 10-nm-thick IGZO (132) film and a 15-nm-thick IGZO (111) film. The IGZO film (132) was deposited using a target with In:Ga:Zn=1:3:2 [atomic ratio], and the IGZO film (111) was deposited using a target with In:Ga:Zn=1:1:1.2 [atomic ratio]. The TaNₓ film was deposited by a sputtering method to a thickness of 5 nm. The W film was deposited by a sputtering method to a thickness of 15 nm. The SiNₓ\SiOₓ film was formed by successively depositing the SiNₓ film to a thickness of 5 nm and the SiOₓ film to a thickness of 10 nm by a sputtering method. The SiNₓ_1 film was deposited by a PEALD method to a thickness of 5 nm. The SiOₓ_2 film was a film deposited by a sputtering method.

First, an SOC film, an SOG film, and a positive resist film were formed in this order over the SiOₓ_2 film. The resist film was irradiated with an electron beam, whereby a resist mask having an opening was formed. Dry etching treatment was performed using the resist mask having an opening, so that the SOC film and the SOG film were processed to have an opening.

Next, dry etching treatment was performed using the SOC film and the SOG film having an opening, so that the SiOₓ_2 film and the SiNₓ_1 film were processed to have an opening.

Next, dry etching treatment was performed using the SOC film having an opening, so that the SiNₓ\SiOₓ film was processed to have an opening. Here, the dry etching treatment was performed using an ICP etching apparatus. As for the etching conditions, a CHF₃ gas at 67 sccm and an O₂ gas at 13 sccm were used as an etching gas, the pressure was 0.67 Pa, the ICP power was 3000 W, the bias power was 25 W, and the substrate temperature was −10° C.

Moreover, dry etching treatment was performed successively without exposure to the air. By the treatment, the W film was divided. Here, the dry etching treatment was performed using an ICP etching apparatus. The etching conditions were set such that the etching selectivity of the W film to the TaNₓ film was sufficiently secured. Specifically, the conditions were such that the bias power was 25 W and the oxygen gas flow rate ratio was 0.484 (where a CF₄ gas was at 44 sccm, a Cl₂ gas was at 36 sccm, and an O₂ gas was at 75 sccm). The other conductions were such that the pressure was 0.67 Pa, the ICP power was 1000 W, and the substrate temperature was −10° C.

Furthermore, without exposure to the air, successively, oxygen plasma treatment was performed, so that the SOC film was removed. In this manner, a structure body having an opening, which corresponds to FIG. 10A to FIG. 10D, was formed.

Next, as in the structure of FIG. 11A to FIG. 11D, a SiNₓ_2 film (corresponding to the insulating film 255A) was formed to cover the above-described structure body. The SiNₓ_2 film was deposited by a PEALD method to a thickness of 9 nm.

Next, as in the structure of FIG. 12A to FIG. 12D, anisotropic dry etching treatment was performed to form a sidewall-shaped SiNₓ_2 film. Here, the dry etching treatment was performed using an ICP etching apparatus. As for the etching conditions, a CHF₃ gas at 67 sccm and an O₂ gas at 13 sccm were used as an etching gas, the pressure was 0.67 Pa, the ICP power was 500 W, the bias power was 25 W, and the substrate temperature was −10° C.

Moreover, dry etching treatment was performed successively without exposure to the air. By the treatment, the TaNₓ film was divided. Here, the dry etching treatment was performed using an ICP etching apparatus. The etching conditions were such that a Cl₂ gas at 80 sccm and an Ar gas at 20 sccm were used as an etching gas, the pressure was 0.51 Pa, the ICP power was 1000 W, and the substrate temperature was −10° C. Note that the bias power was 100 W at first and changed into 10 W in the middle.

Furthermore, without exposure to the air, oxygen plasma treatment was performed successively to remove impurities such as Cl attached to the IGZO film by the above dry etching treatment. In this manner, a structure body having an opening, which corresponds to FIG. 14A to FIG. 14D, was formed.

Next, heat treatment was performed at a treatment temperature of 350° C. for treatment time of 60 minutes. The heat treatment was performed under an atmospheric pressure conditions in an atmosphere of an N₂ gas at 4 slm and an O₂ gas at 1 slm.

Next, as in the structure of FIG. 15A to FIG. 15D, an aluminum oxide film (hereinafter referred to as an AlOₓ film) was formed to cover the above-described structure body. The AlOₓ film was deposited by a thermal ALD method to a thickness of 1 nm. The AlOₓ film corresponds to at least part of the insulating film 250A.

After the formation of the AlOₓ film, a TiNₓ film was deposited to protect the sample.

A cross-sectional STEM image of the sample fabricated in the above manner was taken, at an acceleration voltage of 200 kV using “HD-2700” produced by Hitachi High-Tech Corporation.

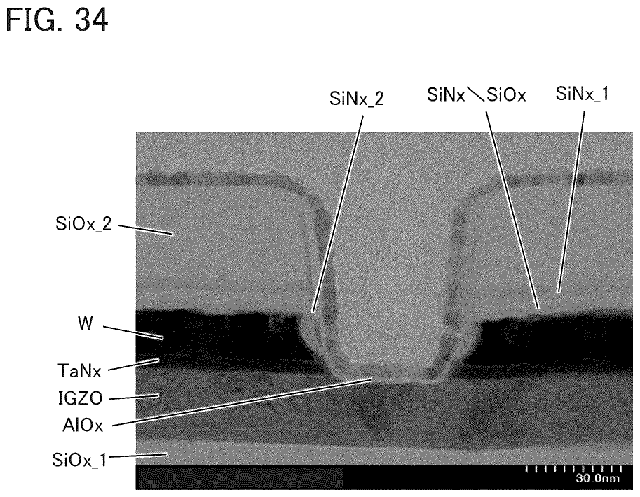

The cross-sectional STEM image of the sample is shown in FIG. 34. As shown in FIG. 34, an oxide film with an excessive thickness was not observed on the side surface of the W film in the sample of this example. The sidewall-shaped SiNₓ_2 film was formed in contact with a side surface of the SiOₓ_2 film, a side surface of the SiNₓ_1 film, a side surface of the SiNₓ\SiOₓ film, and a side surface of the W film. Furthermore, a recess with a curved shape was observed on the side surface of the W film. A SiNₓ_2 film was formed to fill the recess.

From the above, it was found that the formation of the oxide film with an excessive thickness on the side surface of the W film is inhibited, even when heat treatment is performed in an atmosphere containing oxygen, by providing a SiNₓ_2 film in contact with the side surface of the W film.

Thus, by performing the processing in the above manner, the source electrode and the drain electrode in an OS transistor can have a stacked-layer structure of a TaNₓ film with high oxidation resistance and a W film with high conductivity. When the SiNₓ_2 film is provided in contact with the inner side of the W film, oxygen can be supplied to the oxide semiconductor film by heat treatment while oxidation of the W film is prevented. Thus, the transistors can have favorable electrical characteristics and higher reliability. In addition, a variation in electrical characteristics of transistors formed over the same substrate can be reduced. When the SiNₓ_2 film having a sidewall shape is formed by anisotropic etching, the number of masks and the number of steps can be reduced.

This example can be combined with the embodiments and the other example as appropriate.

### Example 3

This example will describe the fabrication of semiconductor devices including the transistor 200 illustrated in FIG. 1A to FIG. 1D (hereinafter, referred to as Sample 3A), the observation results of a cross-sectional STEM image thereof, and the evaluation results of electrical characteristics thereof. In this example, Sample 3A was fabricated by the method illustrated in FIG. 6A to FIG. 18D.

First, the sample structure is described. As illustrated in FIG. 1A to FIG. 1D, Sample 3A includes the insulator 215 positioned over a substrate (not illustrated); the insulator 216 over the insulator 215; the conductor 205 (the conductor 205a and the conductor 205b) provided to be embedded in the insulator 216; the insulator 221 over the insulator 216 and the conductor 205; the insulator 222 over the insulator 221; the insulator 224 over the insulator 222; the oxide 230 (the oxide 230a and the oxide 230b) over the insulator 224; the conductor 242a (the conductor 242a1 and the conductor 242a2) and the conductor 242b (the conductor 242b1 and the conductor 242b2) over the oxide 230; the insulator 271a over the conductor 242a; the insulator 271b over the conductor 242b; the insulator 250 (the insulator 250a, the insulator 250b, and the insulator 250c) over the oxide 230; and the conductor 260 (the conductor 260a and the conductor 260b) over the insulator 250. Furthermore, the insulator 275 is provided over the insulators 271a and 271b, and the insulator 280 is provided over the insulator 275. In addition, the insulator 255 is provided between the insulator 250 and the conductor 242a2, the conductor 242b2, the insulator 271a, the insulator 271b, the insulator 275, and the insulator 280. The insulator 255, the insulator 250, and the conductor 260 are embedded in an opening provided in the insulator 280 and the insulator 275. The insulator 282 is provided over the insulator 280 and the conductor 260, and the insulator 283 is provided over the insulator 282.

The insulator 215 is a stacked film of a 60-nm-thick silicon nitride film and a 40-nm-thick aluminum oxide film over the silicon nitride film. The silicon nitride film and the aluminum oxide film were each deposited by a sputtering method. The insulator 216 is a silicon oxide film deposited by a sputtering method.

The conductor 205 is a stacked film of the conductor 205a and the conductor 205b and is provided to be embedded in the opening of the insulator 216. The conductor 205a is a tantalum nitride film deposited by a sputtering method. The conductor 205b is a titanium nitride film and a tungsten film over the titanium nitride film deposited by a CVD method.

The insulator 222 is a 3-nm-thick silicon nitride film deposited by a PEALD method.

The insulator 222 is a 17-nm-thick hafnium oxide film deposited by a thermal ALD method.

The insulator 224 is a 20-nm-thick silicon oxide film deposited by a sputtering method.

As the oxide 230a, 10-nm-thick In—Ga—Zn oxide deposited by a sputtering method was used. In the deposition of the oxide 230a, a target with In:Ga:Zn=1:3:2 [atomic ratio] was used.

As the oxide 230b, 15-nm-thick In—Ga—Zn oxide deposited by a sputtering method was used. For the formation of the oxide 230b, a target with In:Ga:Zn=1:1:1.2 [atomic ratio] was used.

Each of the conductor 242a1 and the conductor 242b1 is a 5-nm-thick tantalum nitride film deposited by a sputtering method. Each of the conductor 242a2 and the conductor 242b2 is a 15-nm-thick tungsten film deposited by a sputtering method.

Each of the insulator 271a and the insulator 271b is a stacked film of a 5-nm-thick silicon nitride film and a 10-nm-thick silicon oxide film over the silicon nitride film. The silicon nitride film and the silicon oxide film were each deposited by a sputtering method.

The insulator 275 is a 5-nm-thick silicon nitride film deposited by a sputtering method. The insulator 280 is a silicon oxide film deposited by a sputtering method.

The insulator 255, the insulator 250, and the conductor 260 are provided to be embedded in an opening provided in the insulator 280 and the insulator 275. The insulator 255 is a silicon nitride film deposited by a PEALD method.

The insulator 250 is a stacked film of the insulator 250a, the insulator 250b, and the insulator 250c. The insulator 250a is a 1-nm-thick aluminum oxide film deposited by a thermal ALD method. The insulator 250b is a 3-nm-thick silicon oxide film deposited by a PEALD method. The insulator 250c is a 3-nm-thick silicon nitride film deposited by a PEALD method.

The conductor 260 is a stacked film of the conductor 260a and the conductor 260b. The conductor 260a is a titanium nitride film deposited by a CVD method. The conductor 260b is a tungsten film deposited by a CVD method.

The insulator 282 is a 10-nm-thick aluminum oxide film deposited by a sputtering method. The insulator 283 is a 20-nm-thick silicon nitride film deposited by a sputtering method.

The opening in the insulator 280, the opening in the insulator 275, the insulator 271a, the insulator 271b, the conductor 242a2, and the conductor 242b2 were formed by the method illustrated in FIG. 10A to FIG. 10D.

For example, the insulator 271a and the insulator 271b were formed by dry etching treatment. Here, the dry etching treatment was performed using an ICP etching apparatus. As for the etching conditions, a CHF₃ gas at 67 sccm and an O₂ gas at 13 sccm were used as an etching gas, the pressure was 0.67 Pa, the ICP power was 3000 W, the bias power was 25 W, and the substrate temperature was −10° C.

Furthermore, the conductor 242a2 and the conductor 242b2 were successively formed without exposure to the air using the same apparatus. As for the etching conditions, a CF₄ gas at 44 sccm, a Cl₂ gas at 36 sccm, and an O₂ gas at 75 sccm were used as an etching gas, the pressure was 0.67 Pa, the ICP power was 1000 W, the bias power was 100 W, and the substrate temperature was −10° C.

The insulator 255, the conductor 242a1, and the conductor 242b1 were formed by the method illustrated in FIG. 12A to FIG. 14D.

For example, the insulator 255 was formed by anisotropic dry etching treatment. Here, the dry etching treatment was performed using an ICP etching apparatus. As for the etching conditions, a CHF₃ gas at 67 sccm and an O₂ gas at 13 sccm were used as an etching gas, the pressure was 0.67 Pa, the ICP power was 500 W, the bias power was 25 W, and the substrate temperature was −10° C.

Furthermore, the conductor 242a1 and the conductor 242b1 were successively formed without exposure to the air using the same apparatus. The etching conditions were such that a Cl₂ gas at 80 sccm and an Ar gas at 20 sccm were used as an etching gas, the pressure was 0.51 Pa, the ICP power was 1000 W, and the substrate temperature was −10° C. Note that the bias power was 100 W at first and changed into 10 W in the middle.

Furthermore, heat treatment was performed after the formation of the conductor 242a1 and the conductor 242b1 illustrated in FIG. 14D. The heat treatment was performed in a mixed atmosphere of an N₂ gas at a flow rate of 4 slm and an O₂ gas at a flow rate of 1 slm at 350° C. under atmospheric pressure for one hour.

After the insulating film to be the insulator 250b was deposited, microwave treatment was performed. In the microwave treatment, an argon gas at 150 sccm and an oxygen gas at 50 sccm were used as treatment gases, the power was 4000 W, the pressure was 400 Pa, the treatment temperature was 250° C., and the treatment time was 600 seconds.

Sample 3A fabricated in the above manner is a TEG (Test Element Group) including transistors each having a channel length of 30 nm and a channel width of 30 nm and transistors each having a channel length of 60 nm and a channel width of 60 nm in design values. In Sample 3A, nine elements (transistors) each having a channel length of 30 nm and a channel width of 30 nm and nine elements (transistors) each having a channel length of 60 nm and a channel width of 60 nm were fabricated.

First, a cross-sectional STEM image of the transistor with a channel length of 30 nm and a channel width of 30 nm in Sample 3A was taken at an acceleration voltage of 200 kV using “HD-2700” produced by Hitachi High-Tech Corporation.

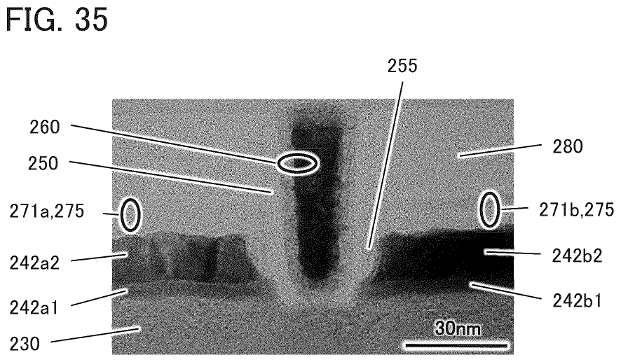

A cross-sectional STEM image of Sample 3A is shown in FIG. 35. Here, FIG. 35 is a bright-field STEM image in a cross section of the transistor with a channel length of 30 nm and a channel width of 30 nm in Sample 3A, in the channel length direction. As shown in FIG. 35, the sidewall-shaped insulator 255 is in contact with the side surfaces of the insulator 280, the insulator 275, the insulator 271a, the insulator 271b, the conductor 242a2, and the conductor 242b2. The insulator 255 is also in contact with the top surfaces of the conductor 242a2 and the conductor 242b2. Furthermore, it is found that an oxide film with an excessive thickness is not formed on the side surfaces of the conductor 242a2 and the conductor 242b2 on the insulator 250 side.

Next, electrical characteristics of the nine elements (transistors) each having a channel length of 60 nm and a channel width of 60 nm and the nine elements (transistors) each having a channel length of 30 nm and a channel width of 30 nm, which were formed in Sample 3A, were evaluated. For the evaluation of the electrical characteristics, I_{d}-V_{g} characteristics (drain current-gate voltage characteristics) of each element were measured using a semiconductor parameter analyzer manufactured by Keysight Technologies. As the measurement conditions of the I_{d}-V_{g} characteristics, the drain potential V_{d} was 1.2 V, the source potential Vₛ was 0 V, the bottom gate potential V_{bg} was 0 V, and the top gate potential V_{g} was swept from −4.0 V to 4.0 V in increments of 0.1 V.

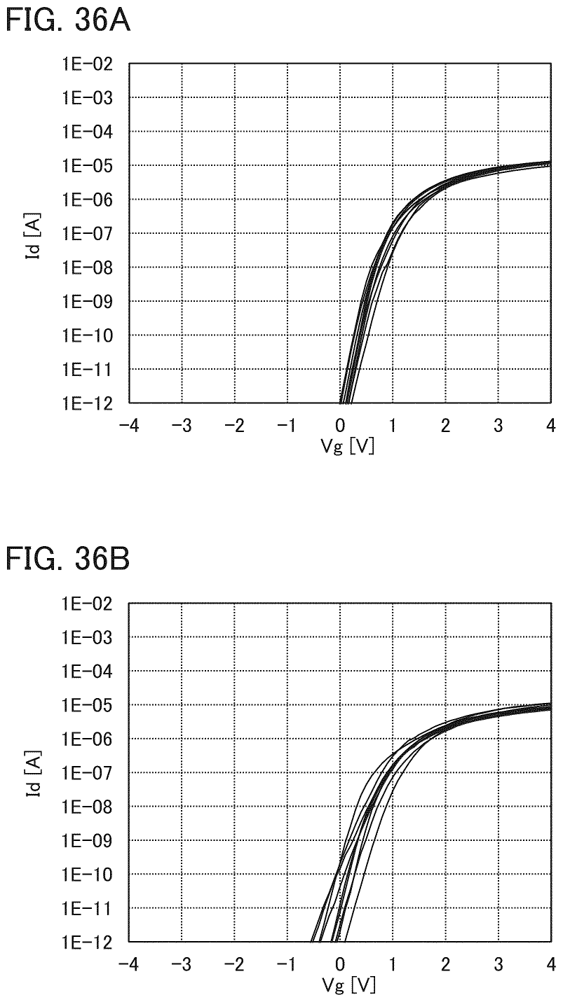

FIG. 36A to FIG. 36B show the measurement results of the I_{d}-V_{g} characteristics. FIG. 36A shows the measurement results of the nine elements (transistors) each having a channel length of 60 nm and a channel width of 60 nm, and FIG. 36B shows the measurement results of the nine elements (transistors) with a channel length of 30 nm and a channel width of 30 nm. In each of FIG. 36A to FIG. 36B, the horizontal axis represents top gate voltage V_{g} [V] and the vertical axis represents drain current I_{d} [A].

As shown in FIG. 36A, the transistors with a channel length of 60 nm and a channel width of 60 nm exhibit favorable electrical characteristics, and a variation in the electrical characteristics is small. In addition, the transistors with a channel length of 30 nm and a channel width of 30 nm exhibit favorable electrical characteristics while having a slight variation in the electrical characteristics as shown in FIG. 36B.

Here, it is considered that the structure, as shown in FIG. 35, where the insulator 255 with a high barrier property against oxygen is provided in contact with the side surfaces of the conductor 242a and the conductor 242b was able to inhibit excessive oxidation of the side surfaces of the conductor 242a2 and the conductor 242b2 having high conductivity. Moreover, the structure enables supplying oxygen to the oxide 230 through heat treatment as well as preventing oxidation of the conductor 242a2 and the conductor 242b2, thereby enabling a reduction in the amount of oxygen vacancies in the oxide 230. Then, it is probable that the formation of VoH by bonding hydrogen to the oxygen vacancy was able to be inhibited. Consequently, it is presumed that a variation in the electrical characteristics of the transistors in the substrate plane was reduced.

Accordingly, a semiconductor device including transistors with favorable electrical characteristics and a small variation in electrical characteristics can be provided.

This example can be combined with the embodiments and the other example as appropriate.

### REFERENCE NUMERALS

ADDR: signal, BL[1]: wiring, BL[j]: wiring, BL[n]: wiring, BL_A: wiring, BL_B: wiring, BL: wiring, BW: signal, CE: signal, CLK: signal, EN_data: signal, GBL_A: wiring, GBL_B: wiring, GBL: wiring, GW: signal, MUX: selection signal, PL[1]: wiring, PL[i]: wiring, PL[m]: wiring, PL: wiring, RDA: signal, RE: selection signal, VHH: wiring, VLL: wiring, VPC: intermediate potential, WAKE: signal, WDA: signal, WE: control signal, WL[1]: wiring, WL[i]: wiring, WL[m]: wiring, WL: wiring, 10[1,1]: memory cell, 10[i,j]: memory cell, 10[m,n]: memory cell, 10_A: memory cell, 10_B: memory cell, 10: memory cell, 11a: transistor, 11b: transistor, 11c: transistor, 11: transistor, 12a: capacitor, 12: capacitor, 20[1]: memory array, 20[2]: memory array, 20[5]: memory array, 20[m]: memory array, 20: memory array, 21: driver circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: functional layer, 51_A: functional circuit, 51_B: functional circuit, 51: functional circuit, 52_a: transistor, 52_b: transistor, 52: transistor, 53_a: transistor, 53_b: transistor, 53: transistor, 54_a: transistor, 54_b: transistor, 54: transistor, 55_a: transistor, 55_b: transistor, 55: transistor, 70[1]: repeating unit, 70: repeating unit, 71_A: precharge circuit, 71_B: precharge circuit, 72_A: switch circuit, 72_B: switch circuit, 73: write/read circuit, 81_1: transistor, 81_3: transistor, 81_4: transistor, 81_6: transistor, 82_1: transistor, 82_2: transistor, 82_3: transistor, 82_4: transistor, 83_A: switch, 83_B: switch, 83_C: switch, 83_D: switch, 153: conductor, 154: insulator, 160a: conductor, 160b: conductor, 160: conductor, 200: transistor, 205a: conductor, 205b: conductor, 205: conductor, 207: conductor, 208: insulator, 209: conductor, 210: insulator, 212: insulator, 214: insulator, 215: insulator, 216: insulator, 221: insulator, 222: insulator, 224f: insulating film, 224: insulator, 230a: oxide, 230af: oxide film, 230b: oxide, 230bf: oxide film, 230: oxide, 240a: conductor, 240b: conductor, 240: conductor, 241: insulator, 242_1: conductor, 242_1f: conductive film, 242_2: conductor, 242_2f: conductive film, 242a: conductor, 242b: conductor, 250a: insulator, 250A: insulating film, 250Aa: insulating film, 250Ab: insulating film, 250Ac: insulating film, 250b: insulator, 250c: insulator, 250d: insulator, 250: insulator, 255a: insulator, 255A: insulating film, 255b: insulator, 255: insulator, 260a: conductor, 260A: conductive film, 260b: conductor, 260B: conductive film, 260: conductor, 261: conductor, 271a: insulator, 271b: insulator, 271f: insulating film, 271: insulator, 275: insulator, 280: insulator, 282: insulator, 283: insulator, 284: insulator, 285: insulator, 300A: memory device, 300: memory device, 310: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage

1. A semiconductor device comprising:
an oxide over a substrate;
a first conductor and a second conductor that are over the oxide and are separated from each other;
a third conductor in contact with a part of a top surface of the first conductor;
a fourth conductor in contact with a part of a top surface of the second conductor;
a first insulator that is over the third conductor and the fourth conductor and comprises an opening overlapping with a region between the third conductor and the fourth conductor;
a second insulator that is in the opening of the first insulator and in contact with another part of the top surface of the first conductor, another part of the top surface of the second conductor, a side surface of the third conductor, and a side surface of the fourth conductor;
a third insulator that is in the opening of the first insulator and in contact with a top surface of the oxide, a side surface of the first conductor, a side surface of the second conductor, and a side surface of the second insulator; and
a fifth conductor that is over the third insulator in the opening of the first insulator and comprises a region overlapping with the oxide with the third insulator therebetween,
wherein a distance between the first conductor and the second conductor is smaller than a distance between the third conductor and the fourth conductor.

2. The semiconductor device according to claim 1, wherein the first conductor and the second conductor each comprise a metal nitride.

3. The semiconductor device according to claim 1, wherein the first conductor and the second conductor each comprise tantalum nitride.

4. The semiconductor device according to claim 1,
wherein the first conductor and the second conductor each comprise tantalum nitride, and
wherein the third conductor and the fourth conductor each comprise tungsten.

5. The semiconductor device according to claim 1, wherein the second insulator comprises a nitride.

6. The semiconductor device according to claim 1, wherein the second insulator comprises silicon nitride.

7. The semiconductor device according to claim 6, wherein the second insulator comprises oxygen.

8. The semiconductor device according to claim 1, wherein the second insulator is in contact with a side surface of the first insulator.

9. The semiconductor device according to claim 1, wherein an upper portion of the second insulator has a tapered shape.

10. The semiconductor device according to claim 1, wherein a difference between the distance between the third conductor and the fourth conductor and the distance between the first conductor and the second conductor is equal to or substantially equal to twice a thickness of the second insulator.

11. The semiconductor device according to claim 1, wherein the side surface of the third conductor and the side surface of the fourth conductor each have a recess.

12. The semiconductor device according to claim 1, wherein a side surface of the opening of the first insulator is aligned or substantially aligned with the side surface of the third conductor and the side surface of the fourth conductor in a top view.

13. The semiconductor device according to claim 1, wherein the third insulator comprises an aluminum oxide film, a silicon oxide film over the aluminum oxide film, and a silicon nitride film over the silicon oxide film.

14. The semiconductor device according to claim 13, further comprising:
a fourth insulator, a fifth insulator, a sixth insulator, a seventh insulator, and an eighth insulator,
wherein the fourth insulator is below the oxide,
wherein the fifth insulator is in contact with a top surface of the fourth insulator,
wherein the sixth insulator is between the first insulator and each of the first conductor, the second conductor, the third conductor, and the fourth conductor, the oxide, and the fifth insulator,
wherein the seventh insulator is over the first insulator, the second insulator, the third insulator, and the fifth conductor,
wherein the eighth insulator is in contact with a top surface of the seventh insulator,
wherein the sixth insulator is in contact with the side surface of the second insulator and the top surface of the fourth insulator,
wherein the second insulator, the fourth insulator, the sixth insulator, and the eighth insulator each comprise a silicon nitride film,
wherein the fifth insulator comprises a hafnium oxide film, and
wherein the seventh insulator comprises an aluminum oxide film.

15. The semiconductor device according to claim 14, further comprising a sixth conductor below the fourth insulator,
wherein the sixth conductor comprises a region overlapping with the fifth conductor and the oxide.

16. A memory device comprising the semiconductor device according to claim 1, and a capacitor,
wherein one electrode of the capacitor is electrically connected to the third conductor of the semiconductor device.

17. A method for manufacturing a semiconductor device, comprising:
forming an oxide;
forming a first conductor over the oxide;
forming a second conductor over the first conductor;
forming a first insulator to cover the oxide, the first conductor, and the second conductor;
forming an opening in the first insulator;
removing a region of the second conductor overlapping with the opening to divide the second conductor into a third conductor and a fourth conductor;
forming a second insulator to cover the oxide and the first insulator;
processing the second insulator by anisotropic dry etching to form a third insulator in contact with a side surface of the first insulator, a side surface of the third conductor, and a side surface of the fourth conductor;
processing the first conductor with the third insulator as a mask by anisotropic dry etching to divide the first conductor into a fifth conductor and a sixth conductor;
performing heat treatment on the oxide in an atmosphere containing oxygen;
forming a fourth insulator to cover the oxide, the first insulator, and the third insulator;
forming a seventh conductor over the fourth insulator; and
processing the fourth insulator and the seventh conductor by CMP treatment to form a fifth insulator and an eighth conductor in the opening,
wherein silicon nitride is deposited by a PEALD method as the second insulator.
